(19) United States
(12) Patent Application Publication
(10) Pub. No.: US 2012/0206248 A1
(43) Pub. Date: Aug. 16, 2012

(54) FLEXURE ASSEMBLIES AND FIXTURES FOR HAPTIC FEEDBACK

(76) Inventor: Silmon James Biggs, Los Gatos, CA (US)

(21) Appl. No.: 13/502,233

(22) PCT Filed: Oct. 18, 2010
(86) PCT No.: PCT/US10/02773

§ 371 Date: May 3, 2012

Related U.S. Application Data
(60) Provisional application No. 61/253,007, filed on Oct. 19, 2009.

(51) Int. Cl. G08B 6/00; H02N 11/00; H05K 13/04; B32B 3/06

(52) U.S. Cl. 340/407.2; 156/70; 310/300; 29/592.1

(57) ABSTRACT

The present invention provides methods and devices directed to the use of flexure assemblies to assist components driven by actuators, including but not limited to electroactive polymer transducers for providing sensory feedback. The present invention may be employed in any type of user interface device including, but not limited to, touch pads, touch screens or key pads or the like for computer, phone, PDA, video game console, GPS system, kiosk applications, etc.

### RELATED APPLICATIONS

The present application is a non-provisional of U.S. Provisional Application No. 61/253,007 filed Oct. 19, 2.009 entitled “Flexure Assemblies and Fixtures for Haptic Feedback Devices” the entirety of which is incorporated by reference.

### FIELD OF THE INVENTION

The present invention is directed to the use of flexure assemblies to assist components driven by actuators, including but not limited to electroactive polymer transducers for providing sensory feedback.

### BACKGROUND

A tremendous variety of devices used today rely on actuators of one sort or another to convert electrical energy to mechanical energy. Conversely, many power generation applications operate by converting mechanical action into electrical energy. Employed to harvest mechanical energy in this fashion, the same type of actuator may be referred to as a generator. Likewise, when the structure is employed to convert physical stimulus such as vibration or pressure into an electrical signal for measurement purposes, it may be characterized as a sensor. Yet, the term “transducer” may be used to generically refer to any of the devices.

A number of design considerations favor the selection and use of advanced dielectric elastomer materials, also referred to as “electroactive polymers” (EAPs), for the fabrication of transducers. These considerations include potential force, power density, power conversion/consumption, size, weight, cost, response time, duty cycle, service requirements, environmental impact, etc. As such, in many applications, EAP technology offers an ideal replacement for piezoelectric, shape-memory alloy (SMA) and electromagnetic devices such as motors and solenoids.

Examples of EAP devices and their applications are described in U.S. Pat. Nos. 7,394,282; 7,378,783; 7,368,862; 7,362,032; 7,320,457; 7,259,503; 7,233,097; 7,224,106; 7,211,937; 7,199,501; 7,166,953; 7,064,472; 7,062,055; 7,052,594; 7,049,732; 7,034,432; 6,940,221; 6,911,764; 6,891,317; 6,882,086; 6,876,135; 6,812,624; 6,809,462; 6,806,621; 6,781,284; 6,768,246; 6,707,236; 6,664,718; 6,628,040; 6,586,859; 6,583,533; 6,545,384; 6,543,110; 6.376,971 and 6,343,129; and in U.S. Published Patent Application Nos. 2009/0001855; 2009/0154053; 2008/0180875; 2008/0157631; 2008/0116764; 2008/0022517; 2007/0230222; 2007/0200468; 2007/0200467; 2007/0200466; 2007/0200457; 2007/0200454; 2007/0200453; 2007/0170822; 2006/0238079; 2006/0208610; 2006/0208609; and 2005/0157893, and U.S. Ser. No. 12/358,142 filed on Jan. 22, 2009; PCT application No. PCT/US10/26829; PCT Publication Nos. WO 2009/067708; WO 2010/054010; and WO 2010/085575, the entireties of which are incorporated herein by reference.

An EAP transducer comprises two electrodes having deformable characteristics and separated by a thin elastomeric dielectric material. When a voltage difference is applied to the electrodes, the oppositely-charged electrodes attract each other thereby compressing the polymer dielectric layer therebetween. As the electrodes are pulled closer together, the dielectric polymer film becomes thinner (the z-axis component contracts) as it expands in the planar directions (along the x- and y-axes), i.e., the displacement of the film is in-plane. The EAP film may also be configured to produce movement in a direction orthogonal to the film structure (along the z-axis), i.e., the displacement of the film is out-of-plane. U.S. Published Patent Application No. 2005/0157893 discloses EAP film constructs which provide such out-of-plane displacement—also referred to as surface deformation or as thickness mode deflection.

The material and physical properties of the EAP film may be varied and controlled to customize the surface deformation undergone by the transducer. More specifically, factors such as the relative elasticity between the polymer film and the electrode material, the relative thickness between the polymer film and electrode material and/or the varying thickness of the polymer film and/or electrode material, the physical pattern of the polymer film and/or electrode material (to provide localized active and inactive areas), the tension or pre-strain placed on the EAP film as a whole, and the amount of voltage applied to or capacitance induced upon the film may be controlled and varied to customize the surface features of the film when in an active mode.

Numerous transducer-based applications exist which would benefit from the advantages provided by such EAP films. One such application includes the use of EAP films to produce haptic feedback (the communication of information to a user through forces applied to the user's body) in user interface devices. There are many known user interface devices which employ haptic feedback, typically in response to a force initiated by the user. Examples of user interface devices that may employ haptic feedback include keyboards, keypads, game controller, remote control, touch screens, computer mice, trackballs, stylus sticks, joysticks, etc. The user interface surface can comprise any surface that a user manipulates, engages, and/or observes regarding feedback or information from the device. Examples of such interface surfaces include, but are not limited to, a key (e.g., keys on a keyboard), a game pad or buttons, a display screen, etc.

The haptic feedback provided by these types of interface devices is in the form of physical sensations, such as vibrations, pulses, spring forces, etc., which a user senses either directly (e.g., via touching of the screen), indirectly (e.g., via a vibrational effect such a when a cell phone vibrates in a purse or bag) or otherwise sensed (e.g., via an action of a moving body that creates a pressure disturbance but does not generate an audio signal in the traditional sense).

Often, a user interface device with haptic feedback can be an input device that “receives” an action initiated by the user as well as an output device that provides haptic feedback indicating that the action was initiated. In practice, the position of some contacted or touched portion or surface, e.g., a button, of a user interface device is changed along at least one degree of freedom by the three applied by the user, where the force applied must reach some minimum threshold value in order for the contacted portion to change positions and to effect the haptic feedback. Achievement or registration of the change in position of the contacted portion results in a responsive force (e.g., spring-back, vibration, pulsing) which is also imposed on the contacted portion of the device acted upon by the user, which force is communicated to the user through his or her sense of touch.

One common example of a user interface device that employs a spring back, “bistable” or “bi-phase” type of haptic feedback is a button on a mouse, keyboard, touchscreen, or other interface device. The user interface surface does not move until the applied force reaches a certain threshold, at which point the button moves downward with relative ease and then stops—the collective sensation of which is defined as “clicking” the button. Alternatively, the surface moves with an increasing resistance force until some threshold is reached at which point the force profile changes (e.g., reduces). The user-applied force is substantially along an axis perpendicular to the button surface, as is the responsive (but opposite) force felt by the user. However, variations include application of the user applied force laterally or in-plane to the button surface.

In another example, when a user enters input on a touch screen the, screen confirms the input typically by a graphical change on the screen along with, without an auditory cue. A touch screen provides graphical feedback by way of visual cues on the screen such as color or shape changes. A touch pad provides visual feedback by means of a cursor on the screen. While above cues do provide feedback, the most intuitive and effective feedback from a finger actuated input device is a tactile one such as the detent of a keyboard key or the detent of a mouse wheel. Accordingly, incorporating haptic feedback on touch screens is desirable.

Haptic feedback capabilities are known to improve user productivity and efficiency, particularly in the context of data entry. It is believed by the inventors hereof that further improvements to the character and quality of the haptic sensation communicated to a user may further increase such productivity and efficiency. It would be additionally beneficial if such improvements were provided by a sensory feedback mechanism which is easy and cost-effective to manufacture, and does not add to, and preferably reduces, the space, size and/or mass requirements of known haptic feedback devices.

While the incorporation of EAP based transducers can improve the haptic interaction on such user interface devices, there remains a need to employ such EAP transducers without increasing the profile of the user interface device.

### SUMMARY OF THE INVENTION

The present invention includes devices, systems and methods involving electroactive transducers for sensory applications. In one variation, a user interface device having sensory feedback is provided. One benefit of the present invention is to provide the user of a user interface device with haptic feedback whenever an input is triggered by software or another signal generated by the device or associated components.

The methods and devices described herein seek to improve upon the structure and function of EAP-based transducers systems. The present disclosure discusses customized transducer constructs for use in various applications. The present disclosure also provides numerous devices and methods for driving EAP transducers as well as EAP transducer-based devices and systems for mechanical actuation, power generation and/or sensing.

These and other features, objects and advantages of the invention will become apparent to those persons skilled in the art upon reading the details of the invention as more fully described below.

EPAM cartridges that can be used with these designs include, but are not limited to, Planar, Diaphragm, Thickness Mode, and Passive Coupled devices (Hybrids)

The present disclosure includes a device for manipulation by a user and having an improved effect in response to an output signal. In one example, the device includes a base frame; at least one electroactive polymer actuator coupled to the base frame, the electroactive polymer actuator having an electroactive polymer film adapted to move in response to an activation signal being applied to the electroactive polymer transducer to provide the haptic feedback; an actuation frame coupled to the electroactive polymer film, such that movement of the electroactive polymer film causes movement of the actuation frame; and at least one mechanical flexure member coupling a portion of the base frame to a portion of the actuation frame such that the flexure member suspends the actuation frame relative to the base frame and allows relative movement between the base frame and the actuation frame. The mechanical flexure member can suspend the two components in any variety of ways that permit movement therebetween. For example, the components can be physically separated or in contact, so long as the components are able to move relative to each other.

In most cases, the devices according to the present disclosure will have a number of flexures or suspension assemblies. The flexures or suspension assemblies can be separate or coupled together depending upon the particular application.

In one example the device includes a user interface component, where the actuation frame is coupled to or forms a part of the user interface component. Examples of user interface components include a button, a key, a gamepad, a display screen, a touch screen, a computer mouse, a keyboard, and a gaming controller. However, the principles discussed herein can be employed in any number of devices that require moving parts.

Variations of the devices described herein can be configured so that the flexure member to limit relative movement between the base frame and the actuation frame in a plane parallel to the base frame. For example, portions of the flexure can be rigidly affixed to the base frame and to the actuation frame, such that an unconstrained third portion of the flexure being located between the first and second portions deflects in response to relative movement between the base frame and the actuation frame. In additional variations, a flexure member can be configured to have structural characteristics that limit or otherwise affect the movement of the joined components. For example, the unconstrained third portion of the flexure member can limit movement of an attached component thereby limiting movement of an electroactive polymer film that drives the component to less than a maximum displacement of the electroactive polymer film. In some variations, the actuation and/or base frames can include portions that are non-planar with the respective frames plane of movement where the portions are each affixed to one or more mechanical flexure members.

Variations of the devices described herein can include stop assemblies that prevent excessive movement of the components. For example, a stop assembly can include a projection that moves within a mating pocket or recess. The size difference between the projection and the slot/recess can determine the maximum displacement of the device. In one example, of a device having a stop assembly, the stop assembly can comprise a projection on either the base or actuation frame and a mating slot in the actuation or base frame respectively. The slot is configured to receive the projection and is sized larger than the projection to limit movement of the base frame.

The present disclosure also includes methods of manufacturing a feedback device. In one example, the method comprises affixing an electroactive polymer transducer to a first frame, where the electroactive polymer transducer includes an electroactive polymer film configured to displace upon the application of a voltage to provide the feedback; coupling the electroactive polymer film to a second frame; and suspending the first frame relative to the second frame by affixing the first frame to a first portion of a mechanical flexure member and affixing the second frame to a second portion of the mechanical flexure member. Where a third portion of the mechanical flexure member is unconstrained and deflects to allow relative movement of the first and second portions. The first or second frame can include or be part of a user interface component or surface such as a button, a key, a gamepad, a display screen, a touch screen, a computer mouse, a keyboard, and a gaming controller.

The method can include suspending the first frame relative to the second frame by affixing the first and second frames to a plurality of discrete mechanical flexures.

The present disclosure also includes methods for controlling displacement between moveable components in a device. One example of such a method includes providing a device having a first frame component suspended relative to a second frame component by a mechanical flexure which allows for relative movement between the first and second frame components, the first frame component and second frame component having a rest position and a displaced position; an electroactive polymer transducer having an electroactive polymer film configured to displace upon application of a voltage, where the electroactive polymer transducer is coupled to the first frame component and where the electroactive polymer film is coupled to the second frame component; activating the electroactive transducer to cause displacement of the electroactive polymer film, where displacement of the electroactive polymer film results movement of the first and second frame components to the displaced position creating a mechanical stress in the mechanical flexure; reducing the signal to the electroactive transducer to allow the stress in the mechanical flexure to assist returning the first frame component and second frame component towards the rest position while maintaining a suspension between the first and second frames.

The above method can include suspending the first frame relative component to the second frame component comprises affixing the first and second frames to a plurality of discrete mechanical flexures. As noted above, the first or second frame components can comprise or be part of a user interface component. Examples of the user interface component can include a button, a key, a gamepad, a display screen, a touch screen, a computer mouse, a keyboard, and a gaming controller.

The present invention may be employed in any type of user interface device including, but not limited to, touch pads, touch screens or key pads or the like for computer, phone, PDA, video game console, UPS system, kiosk applications, etc.

As for other details of the present invention, materials and alternate related configurations may be employed as within the level of those with skill in the relevant art. The same may hold true with respect to method-based aspects of the invention in terms of additional acts as commonly or logically employed. In addition, though the invention has been described in reference to several examples, optionally incorporating various features, the invention is not to be limited to that which is described or indicated as contemplated with respect to each variation of the invention. Various changes may be made to the invention described and equivalents (whether recited herein or not included for the sake of some brevity) may be substituted without departing from the true spirit and scope of the invention. Any number of the individual parts or subassemblies shown may be integrated in their design. Such changes or others may be undertaken or guided by the principles of design for assembly.

These and other features, objects and advantages of the invention will become apparent to those persons skilled in the art upon reading the details of the invention as more fully described below.

### BRIEF DESCRIPTION OF THE DRAWINGS

The invention is best understood from the following detailed description when read in conjunction with the accompanying drawings. To facilitate understanding, the same reference numerals have been used (where practical) to designate similar elements that are common to the drawings. Included in the drawings are the following:

FIGS. 1A and 1B illustrate some examples of a user interface that can employ haptic feedback when an EAP transducer is coupled to a display screen or sensor and a body of the device;

FIGS. 2A and 2B, show a sectional view of a user interface device including a display screen having a surface that reacts with haptic feedback to a user's input;

FIGS. 3A and 3B illustrate a sectional view of another variation of a user interface device having a display screen covered by a flexible membrane with active EAP formed into active gaskets;

FIG. 4 illustrates a sectional view of an additional variation of a user interface device having a spring biased EAP membrane located about an edge of the display screen;

FIG. 5 shows a sectional view of a user interface device where the display screen is coupled to a frame using a number of compliant gaskets and the driving force for the display is a number of EAP actuators diaphragms;

FIGS. 6A and 6B show sectional views of a user interface 230 having a corrugated EAP membrane or film coupled to a display;

FIGS. 7A and 7B illustrate a top perspective view of a transducer before and after application of a voltage in accordance with one embodiment of the present invention;

FIGS. 8A and 8B show exploded top and bottom perspective views, respectively, of a sensory feedback device for use in a user interface device;

FIG. 9A is a top planar view of an assembled electroactive polymer actuator of the present invention; FIGS. 9B and 9C are top and bottom planar views, respectively, of the film portion of the actuator of FIG. 8A and, in particular, illustrate the two-phase configuration of the actuator;

FIGS. 9D and 9E illustrate an example of arrays of electro active polymer transducer for placing across a surface of a display screen that is spaced from a frame of the device;

FIGS. 9F and 9G are an exploded view and assembled view, respectively, of an array of actuators for use in a user interface device as disclosed herein;

FIG. 10 illustrates a side view of the user interface devices with a human finger in operative contact with the contact surface of the device;

FIGS. 11A and 11B graphically illustrate the force-stroke relationship and voltage response curves, respectively, of the actuator of FIGS. 9A-9C When operated in a single-phase mode;

FIGS. 11C and 11D graphically illustrate the force-stroke relationship and voltage response curves, respectively, of the actuator of FIGS. 9A-9C when operated in a two-phase mode;

FIGS. 12A to 12C illustrate another variation of a two phase transducer;

FIG. 12D illustrates a graph of displacement versus time for the two phase transducer of FIGS. 12A to 12C;

FIG. 13 is a block diagram of electronic circuitry, including a power supply and control electronics, for operating the sensory feedback device;

FIGS. 14A and 14B show a partial cross sectional view of an example of a planar array of EAP actuators coupled to a user input device;

FIGS. 15A and 15B schematically illustrate an EAP transducer employed as an actuator which utilizes polymer surface features to provide work output when the transducer is activated;

FIGS. 16A and 16B are cross-sectional views of exemplary constructs of an actuator of the present invention;

FIGS. 17A-17D illustrate various steps of a process for making electrical connections within the subject transducers for coupling to a printed circuit board (PCB) or flex connector;

FIGS. 18A-18D illustrate various steps of a process for making electrical connections within the subject transducers for coupling to an electrical wire;

FIG. 19 is a cross-sectional view of a subject transducer having a piercing type of electrical contact;

FIGS. 20A and 20B are top views of a thickness mode transducer and electrode pattern, respectively, for application in a button-type actuator;

FIG. 21 illustrates a top cutaway view of a keypad employing an array of button-type actuators of FIGS. 6A and 6B;

FIG. 22 illustrates a top view of a thickness mode transducer for use in a novelty actuator in the form of a human hand;

FIG. 23 illustrates a top view of thickness mode transducer in a continuous strip configuration;

FIG. 24 illustrates a top view of a thickness mode transducer for application in a gasket-type actuator;

FIGS. 25A-25D are cross-sectional views of touch screens employing various type gasket-type actuators;

FIGS. 26A and 26B are cross-sectional views of another embodiment of a thickness mode transducer of the present invention in which the relative positions of the active and passive areas of the transducer are inversed from the above embodiments;

FIGS. 27A-27D illustrate an example of an electroactive inertial transducer;

FIG. 28A illustrates one example of a circuit to tune an audio signal to work within optimal haptic frequencies for electroactive polymer actuators;

FIG. 28B illustrates an example of a modified haptic signal filtered by the circuit of FIG. 28A;

FIGS. 28C and 28F illustrate additional circuits for producing signals for single and double phase electroactive transducers;

FIGS. 28E and 28F show an example of a device having one or more electroactive polymer actuators within the device body and coupled to an inertial mass;

FIGS. 29A to 29C show an example of electroactive polymer transducers when used in a user interface device where a portion of the transducer and/or user interface surface completes a switch to provide power to the transducer;

FIGS. 30A to 30B illustrate another example of an electroactive polymer transducers configured to form two switches for powering of the transducer;

FIGS. 31A to 31B illustrate various graph of delaying activation of an electroactive polymer transducer to produce a haptic effect that mimics a mechanical switch effect;

FIG. 32 illustrates an example of a circuit to drive an electroactive polymer transducer using a triggering signal (such as an audio signal) to deliver a stored waveform for producing a desired haptic effect;

FIGS. 33A and 33B illustrate another variation for driving an electroactive polymer transducer by providing two-phase activation with a single drive circuit;

FIG. 34A shows an example of a displacement curve showing residual motion after a haptic effect a triggered by the signal of FIG. 34B;

FIG. 34C shows an example of a displacement curve employing electronic dampening to reduce the showing residual motion effect where the haptic effect and dampening signal are illustrated in FIG. 34D;

FIG. 35 illustrates an example of an energy harvesting circuit for powering an electroactive polymer transducer;

FIGS. 36A and 36B illustrate an example of driving a haptic signal using a zero-crossing configuration from an audio signal;

FIG. 36C illustrates an example of driving a haptic signal based on an informational signal so that the data in the informational signal is recognizable from the haptic effect;

FIGS. 37A to 37C illustrate an example of various user interface devices for manipulation by a user and having an improved haptic effect in response to an output signal;

FIG. 37A to 38E shows a variation of a housing configured to enhance a haptic feedback force generated by an actuator;

FIGS. 39A to 39D illustrates a suspension assembly coupling moving components of a device driven by an electroactive polymer actuator;

FIG. 40A to 40D shows a schematic representation of a suspension assembly having a flexure member being displaced by moveable components of a feedback device;

FIG. 41 shows one example of a stop assembly for use with various embodiments described herein;

FIGS. 42A to 42F illustrate one example of assembling a suspension assembly with moving components for eventual placement into a device;

FIG. 43A illustrates an example of a power supply for a photoflash controller; and

FIG. 43B illustrates a second example circuit comprising a push-pull metal-oxide-semiconductor field-effect transistor (MOSFET) array with closed loop feedback.

Variation of the invention from that shown in the figures is contemplated.

### DETAILED DESCRIPTION OF THE INVENTION

The devices, systems and methods of the present invention are now described in detail with reference to the accompanying figures.

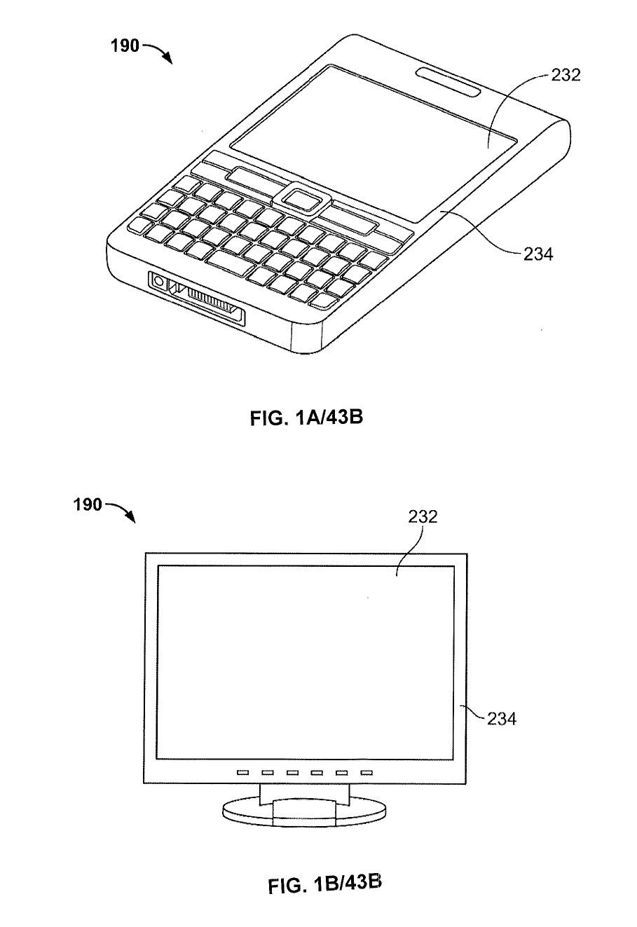

As noted above, devices requiring a user interface can be improved by the use of haptic feedback on the user screen of the device. FIGS. 1A and 1B illustrate simple examples of such devices 190. Each device includes a display screen 232 for which the user enters or views data. The display screen is coupled to a body or frame 234 of the device. Clearly, any number of devices are included within the scope of this disclosure regardless of whether portable (e.g., cell phones, computers, manufacturing equipment, etc.) or affixed to other non-portable structures (e.g., the screen of an information display panel, automatic teller screens, etc.) For purposes of this disclosure, a display screen can also include a touchpad type device where user input or interaction takes place on a monitor or location away from the actual touchpad (e.g., a lap-top computer touchpad).

A number of design considerations favor the selection and use of advanced dielectric elastomer materials, also referred to as “electroactive polymers” (EAPs), for the fabrication of transducers especially when haptic feedback of the display screen 232 is sought. These considerations include potential force, power density, power conversion/consumption, size, weight, cost, response time, duty cycle, service requirements, environmental impact, etc. As such, in many applications, EAP technology offers an ideal replacement for piezoelectric, shape-memory alloy (SMA) and electromagnetic devices such as motors and solenoids.

An EAP transducer comprises two thin film electrodes having elastic characteristics and separated by a thin elastomeric dielectric material. In some variations, the EAP transducer can comprise a non-elastic dielectric material. In any case, when a voltage difference is applied to the electrodes, the oppositely-charged electrodes attract each other thereby compressing the polymer dielectric layer therebetween. As the electrodes are pulled closer together, the dielectric polymer film becomes thinner (the z-axis component contracts) as it expands in the planar directions (the x- and y-axes components expand).

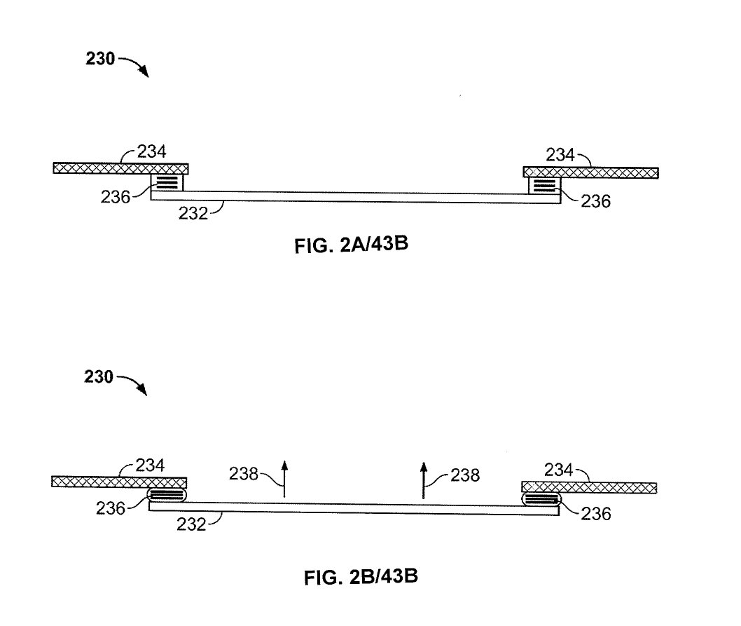

FIGS. 2A-2B, shows a portion of a user interface device 230 with a display screen 232 having a surface that is physically touched by the user in response to information, controls, or stimuli on the display screen. The display screen 234 can be any type of a touch pad or screen panel such as a liquid crystal display (LCD), organic light emitting diode (OLED) or the like. In addition, variations of interface devices 230 can include display screens 232 such as a “dummy” screen, where an image transposed on the screen (e.g., projector or graphical covering). The screen can include conventional monitors or even a screen with fixed information such as common signs or displays.

In any case, the display screen 232 includes a frame 234 (or housing or any other structure that mechanically connects the screen to the device via a direct connection or one or more ground elements), and an electroactive polymer (EAP) transducer 236 that couples the screen 232 to the frame or housing 234. As noted herein, the EAP transducers can be along an edge of the screen 232 or an array of EAP transducers can be placed in contact with portion of the screen 232 that are spaced away from the frame or housing 234.

FIGS. 2A and 2B illustrate a basic user interface device where an encapsulated EAP transducer 236 forms an active gasket. Any number of active gasket EAPs 236 can be coupled between the touch screen 232 and frame 234. Typically, enough active gasket EAPs 236 are provided to produce the desired haptic sensation. However, the number will often vary depending on the particular application. In a variation of the device, the touch screen 232 may either comprise a display screen or a sensor plate (where the display screen would be behind the sensor plate).

The figures show the user interface device 230 cycling the touch screen 232 between an inactive and active state. FIG. 2A shows the user interface device 230 where the touch screen 232 is in an inactive state. In such a condition, no field is applied to the EAP transducers 236 allowing the transducers to be at a resting state. FIG. 2B shows the user interface device 230 after some user input triggers the EAP transducer 236 into an active state where the transducers 236 cause the display screen 232 to move in the direction shown by arrows 238. Alternatively, the displacement of one or more EAP transducers 236 can vary to produce a directional movement of the display screen 232 (e.g., rather than the entire display screen 232 moving uniformly one area of the screen 232 can displace to a larger degree than another area). Clearly, a control system coupled to the user interface device 230 can be configured to cycle the EAPS 236 with a desired frequency and/or to vary the amount of deflection of the EAP 236.

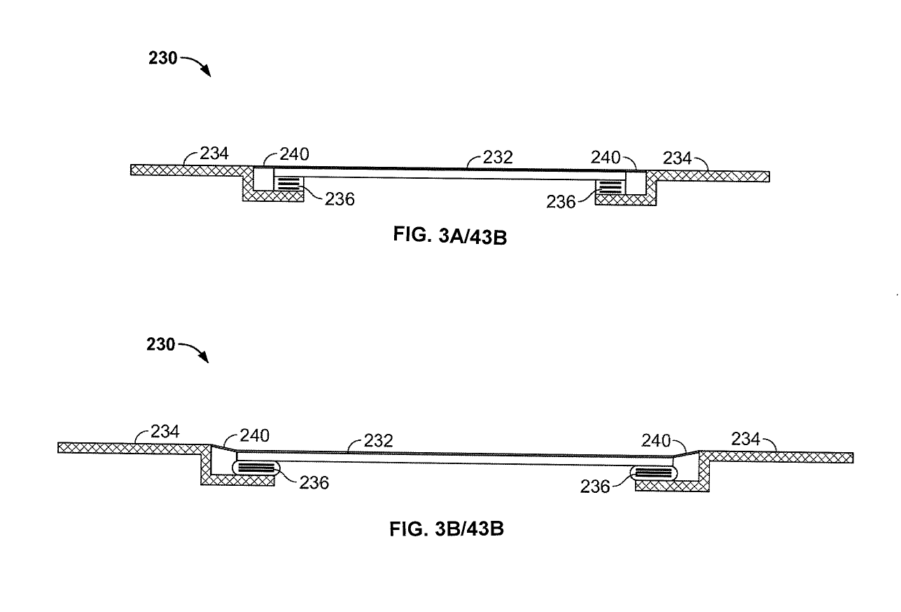

FIGS. 3A and 3B illustrate another variation of a user interface device 230 having a display screen 232 covered by a flexible membrane 240 that functions to protect the display screen 232. Again, the device can include a number of active gasket EAPs 236 coupling the display screen 232 to a base or frame 234. In response to a user input, the screen 232 along with the membrane 240 displaces when an electric field is applied to the EAPs 236 causing displacement so that the device 230 enters an active state.

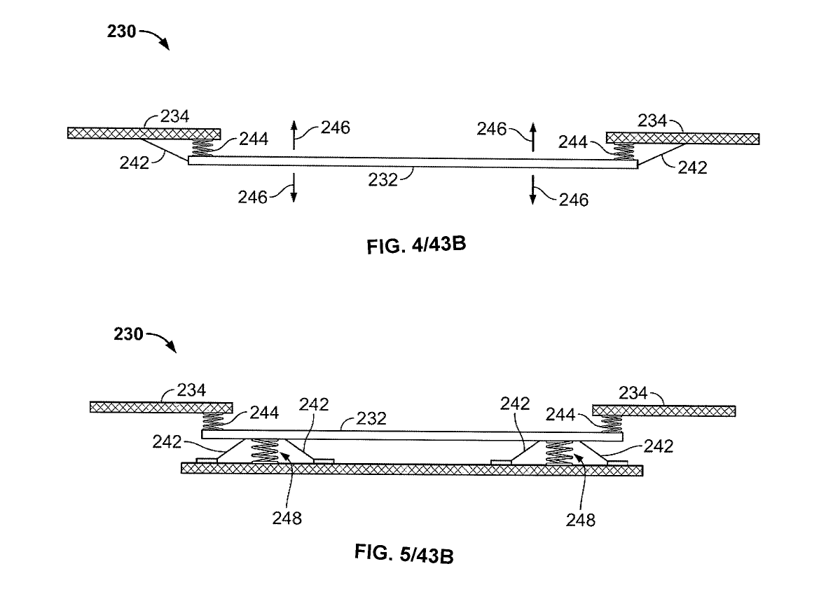

FIG. 4 illustrates an additional variation of a user interface device 230 having a spring biased EAP membrane 244 located about an edge of the display screen 232. The EAP membrane 244 can be placed about a perimeter of the screen or only in those locations that permit the screen to produce haptic feedback to the user. In this variation, a passive compliant gasket or spring 244 provides a force against the screen 232 thereby placing the EAP membranes 242 in a state of tension. Upon providing an electric field 242 to the membrane (again, upon a signal generated by a user input), the EAP membranes 242 relax to cause displacement of the screen 232. As noted by arrows 246, the user input device 230 can be configured to produce movement of the screen 232 in any direction relative to the bias provided by the gasket 244. In addition, actuation of less than all the EAP membranes 242 produces non-uniform movement of the screen 232.

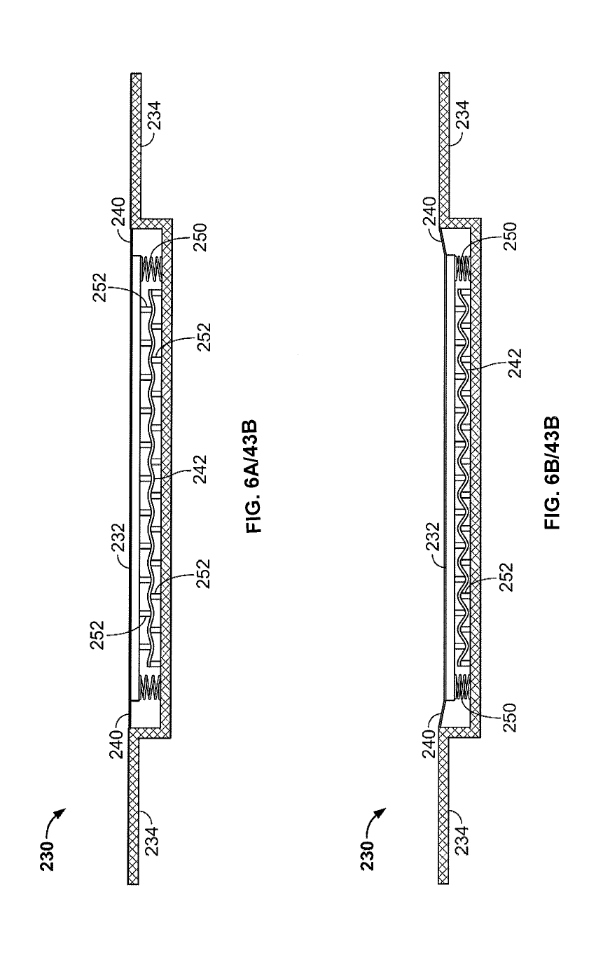

FIG. 5 illustrates yet another variation of a user interface device 230. In this example, the display screen 232 is coupled to a frame 234 using a number of compliant gaskets 244 and the driving force for the display 232 is a number of EAP actuators diaphragms 248. The EAP actuator diaphragms 248 are spring biased and upon application of an electric field can drive the display screen. As shown, the EAP actuator diaphragms 248 have opposing EAP membranes on either side of a spring. In such a configuration, activating opposite sides of the EAP actuator diaphragms 248 makes the assembly rigid at a neutral point. The EAP actuator diaphragms 248 act like the opposing bicep and triceps muscles that control movements of the human arm. Though not shown, as discussed in U.S. Ser. Nos. 11/085,798 and 11/085,804, the actuator diaphragms 248 can be stacked to provide two-phase output action and/or to amplify the output for use in more robust applications.

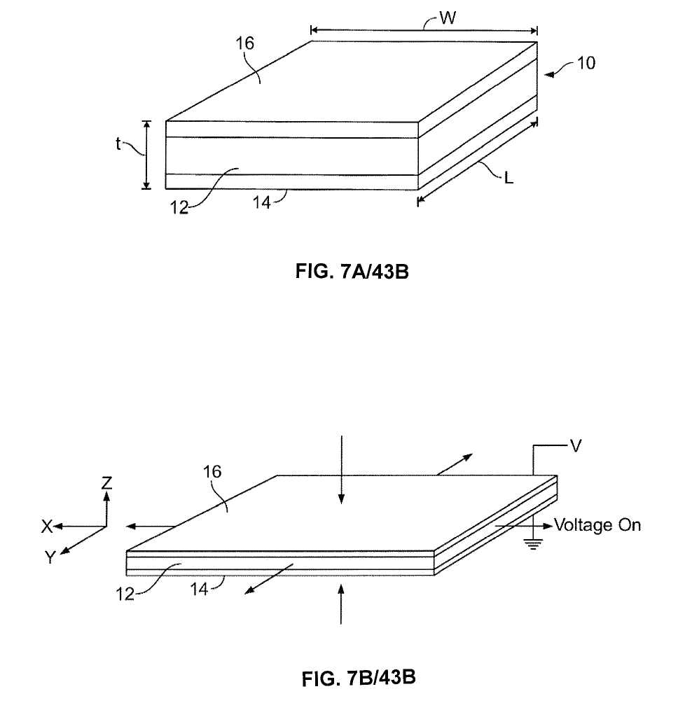

FIGS. 6A and 6B show another variation of a user interface 230 having an EAP membrane or film 242 coupled between a display 232 and a frame 234 at a number of points or ground elements 252 to accommodate corrugations or folds in the EAP film 242. As shown in FIG. 6B, the application of an electric field to the EAP film 242 causes displacement in the direction of the corrugations and deflects the display screen 232 relative to the frame 234. The user interface 232 can optionally include bias springs 250 also coupled between the display 232 and the frame 234 and/or a flexible protective membrane 240 covering a portion (or all) of the display screen 232.

It is noted that the figures discussed above schematically illustrate exemplary configurations of such tactile feedback devices that employ EAP films or transducers. Many variations are within the scope of this disclosure, for example, in variations of the device, the EAP transducers can be implemented to move only a sensor plate or element (e.g., one that is triggered upon user input and provides a signal to the EAP transducer) rather then the entire screen or pad assembly.

In any application, the feedback displacement of a display screen or sensor plate by the EAP member can be exclusively in-plane which is sensed as lateral movement, or can be out-of-plane (which is sensed as vertical displacement). Alternatively, the EAP transducer material may be segmented to provide independently addressable/movable sections so as to provide angular displacement of the plate element or combinations of other types of displacement. In addition, any number of EAP transducers or films (as disclosed in the applications and patent listed above) can be incorporated in the user interface devices described herein.

The variations of the devices described herein allows the entire sensor plate (or display screen) of the device to act as a tactile feedback element. This allows for extensive versatility. For example, the screen can bounce once in response to a virtual key stroke or, it can output consecutive bounces in response to a scrolling element such as a slide bar on the screen, effectively simulating the mechanical detents of a scroll wheel. With the use of a control system, a three-dimensional outline can be synthesized by reading the exact position of the user's finger on the screen and moving the screen panel accordingly to simulate the 3D structure. Given enough screen displacement, and significant mass of the screen, the repeated oscillation of the screen may even replace the vibration function of a mobile phone. Such functionality may be applied to browsing of text where a scrolling (vertically) of one line of text is represented by a tactile “bump”, thereby simulating detents in the context of video gaming, the present invention provides increased interactivity and finer motion control over oscillating vibratory motors employed in prior art video game systems. In the case of a touchpad, user interactivity and accessibility may be improved, especially for the visually impaired, by providing physical cues.

The EAP transducer may be configured to displace to an applied voltage, which facilitates programming of a control system used with the subject tactile feedback devices. For example, a software algorithm may convert pixel grayscale to EAP transducer displacement, whereby the pixel grayscale value under the tip of the screen cursor is continuously measured and translated into a proportional displacement by the EAP transducer. By moving a finger across the touchpad, one could feel or sense a rough 3D texture. A similar algorithm may be applied on a web page, where the border of an icon is fed back to the user as a bump in the page texture or a buzzing button upon moving a finger over the icon. To a normal user, this would provide an entirely new sensory experience while surfing the web, to the visually impaired this would add indispensable feedback.

EAP transducers are ideal for such applications for a number of reasons. For example, because of their light weight and minimal components. EAP transducers offer a very low profile and, as such, are ideal for use in sensory/haptic feedback applications.

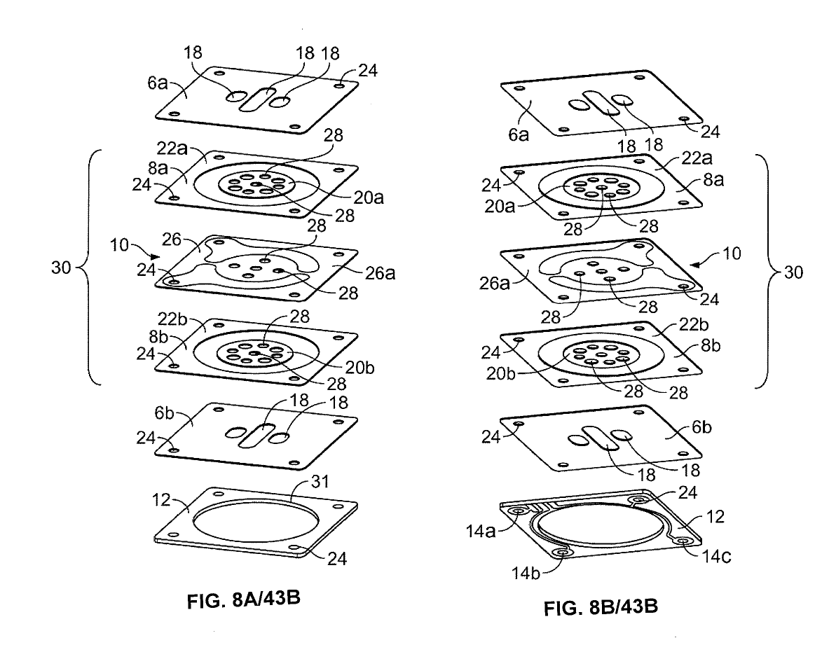

FIGS. 7A and 7B illustrate an example of an EAP film or membrane 10 structure. A thin elastomeric dielectric film or layer 12 is sandwiched between compliant or stretchable electrode plates or layers 14 and 16, thereby forming a capacitive structure or film. The length “l” and width “w” of the dielectric layer, as well as that of the composite structure, are much greater than its thickness “t”. Typically, the dielectric layer has a thickness in range from about 10 μm to about 100 μm, with the total thickness of the structure in the range from about 15 μm to about 10 cm. Additionally, it is desirable to select the elastic modulus, thickness, and/or the microgeometry of electrodes 14, 16 such that the additional stiffness they contribute to the actuator is generally less than the stiffness of the dielectric layer 12, which has a relatively low modulus of elasticity, i.e., less than about 100 MPa and more typically less than about 10 MPa, but is likely thicker than each of the electrodes. Electrodes suitable for use with these compliant capacitive structures are those capable of withstanding cyclic strains greater than about 1% without failure due to mechanical fatigue.

As seen in FIG. 7B, when a voltage is applied across the electrodes, the unlike charges in the two electrodes 14, 16 are attracted to each other and these electrostatic attractive forces compress the dielectric film 12 (along the Z-axis). The dielectric film 12 is thereby caused to deflect with a change in electric field. As electrodes 14, 16 are compliant, they change shape with dielectric layer 12. Generally speaking, deflection refers to any displacement, expansion, contraction, torsion, linear or area strain, or any other deformation of a portion of dielectric film 12. Depending on the architecture, e.g., a frame, in which capacitive structure 10 is employed (collectively referred to as a “transducer”), this deflection may be used to produce mechanical work. Various different transducer architectures are disclosed and described in the above-identified patent references.

With a voltage applied, the transducer film 10 continues to deflect until mechanical forces balance the electrostatic forces driving the deflection. The mechanical forces include elastic restoring forces of the dielectric layer 12, the compliance or stretching of the electrodes 14, 16 and any external resistance provided by a device and/or load coupled to transducer 10. The resultant deflection of the transducer 10 as a result of the applied voltage may also depend on a number of other factors such as the dielectric constant of the elastomeric material and its size and stiffness. Removal of the voltage difference and the induced charge causes the reverse effects.

In some cases, the electrodes 14 and 16 may cover a limited portion of dielectric film 12 relative to the total area of the film. This may be done to prevent electrical breakdown around the edge of the dielectric or achieve customized deflections in certain portions thereof. Dielectric material outside an active area (the latter being a portion of the dielectric material having sufficient electrostatic force to enable deflection of that portion) may be caused to act as an external spring force on the active area during deflection. More specifically, material outside the active area may resist or enhance active area deflection by its contraction or expansion.

The dielectric film 12 may be pre-strained. The pre-strain improves conversion between electrical and mechanical energy, i.e., the pre-strain allows the dielectric film 12 to deflect more and provide greater mechanical work. Pre-strain of a film may be described as the change in dimension in a direction after pre-straining relative to the dimension in that direction before pre-straining. The pre-strain may comprise elastic deformation of the dielectric film and be formed, for example, by stretching the film in tension and fixing one or more of the edges while stretched. The pre-strain may be imposed at the boundaries of the film or for only a portion of the film and may be implemented by using a rigid frame or by stiffening a portion of the film.

The transducer structure of FIGS. 7A and 7B and other similar compliant structures and the details of their constructs are more fully described in many of the referenced patents and publications disclosed herein.

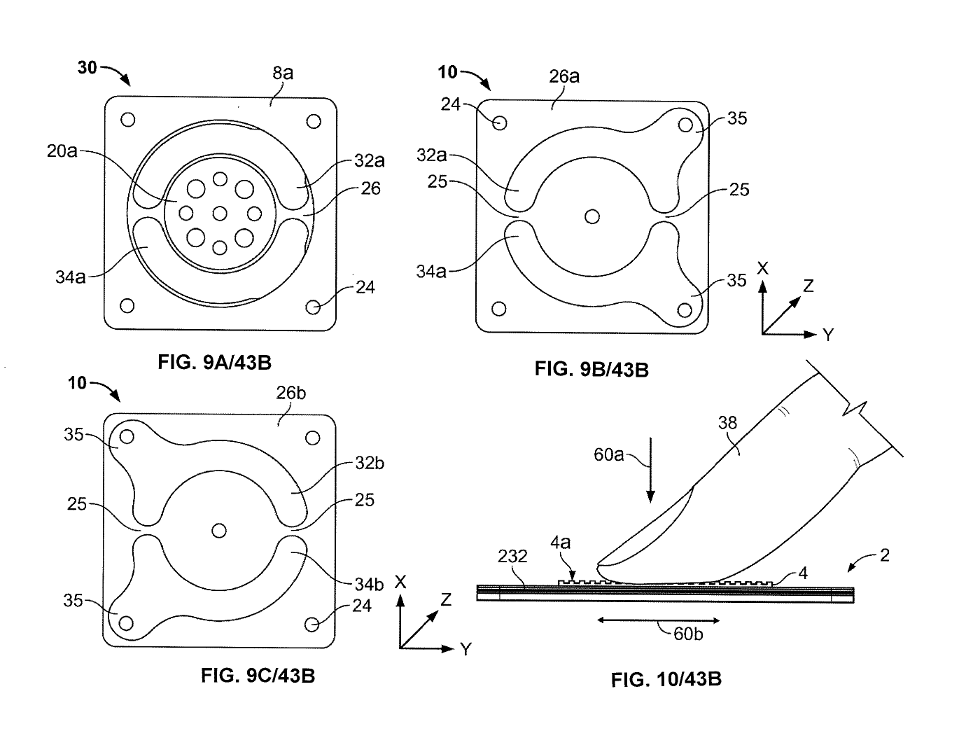

In addition to the EAP films described above, sensory or haptic feedback user interface devices can include EAP transducers designed to produce lateral movement. For example, various components including, from top to bottom as illustrated in FIGS. 8A and 8B, actuator 30 having an electroactive polymer (EAP) transducer 10 in the form of an elastic film which converts electrical energy to mechanical energy (as noted above). The resulting mechanical energy is in the form of physical “displacement” of an output member, here in the form of a disc 28.

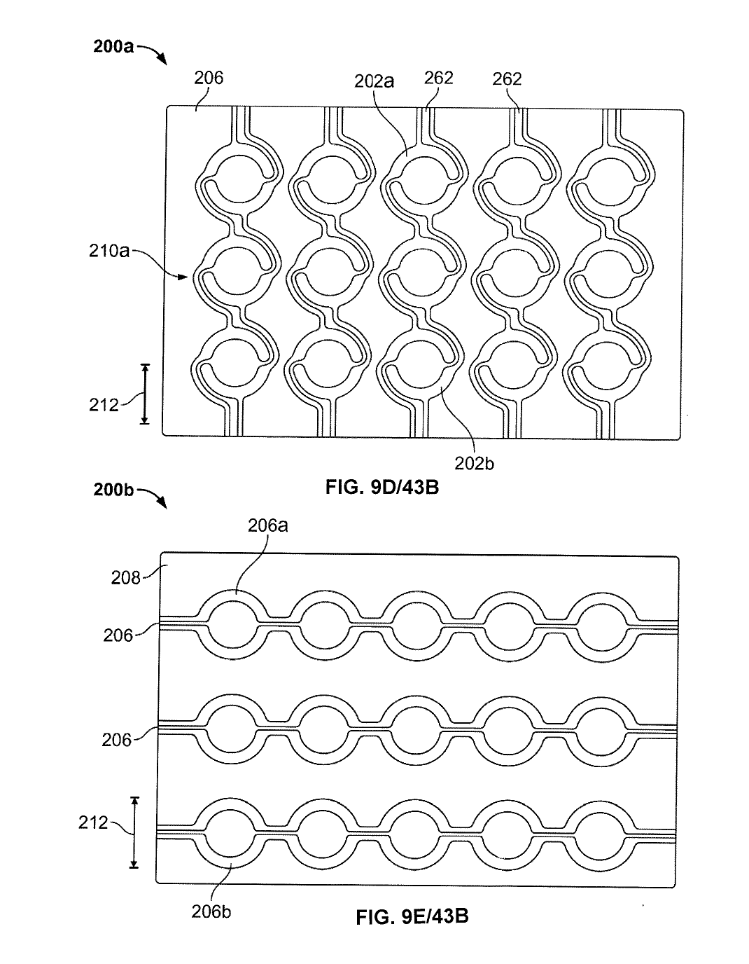

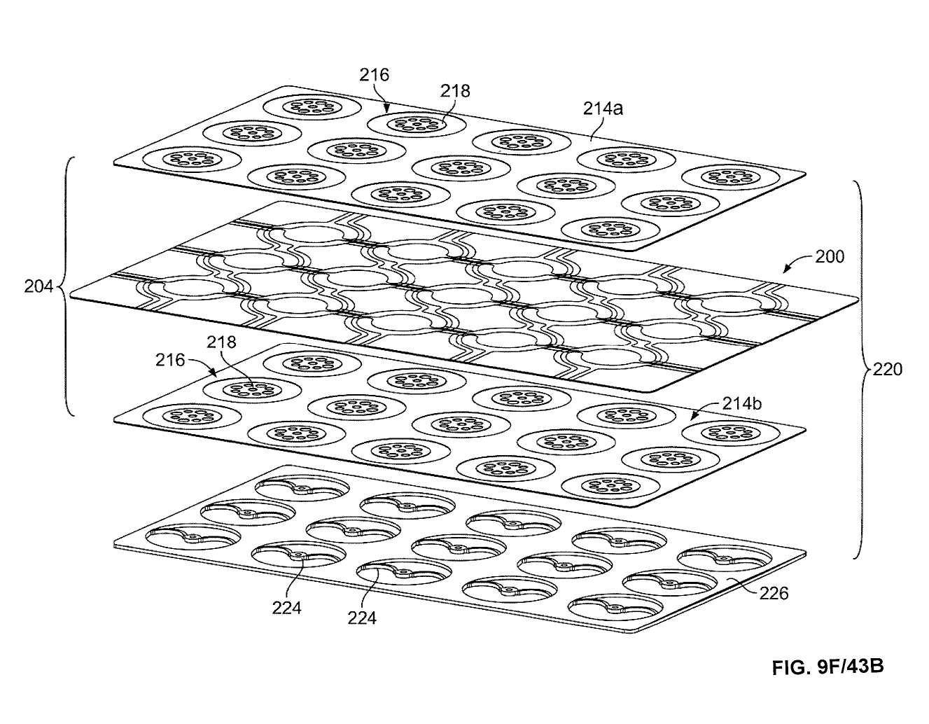

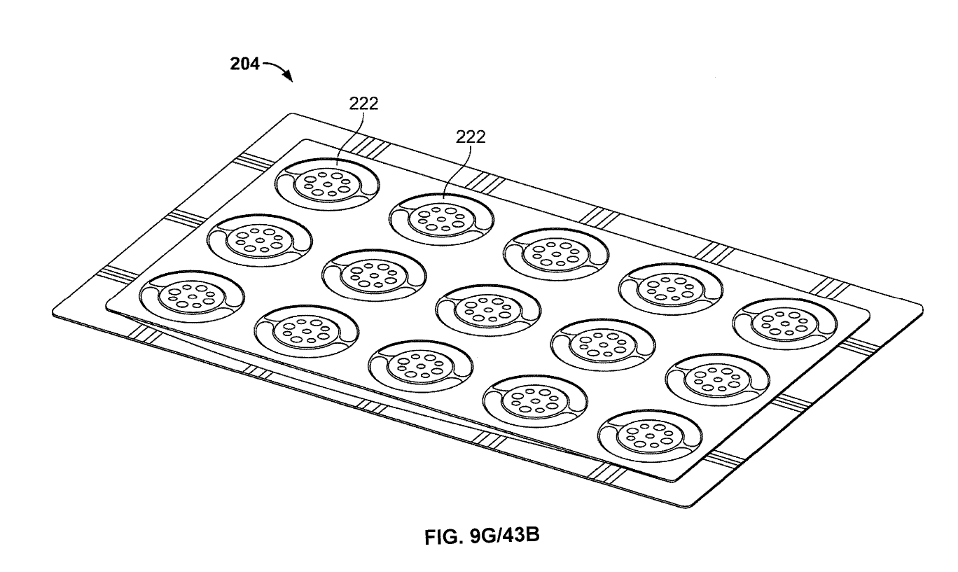

With reference to FIGS. 9A-9C, EAP transducer film 10 comprises two working pairs of thin elastic electrodes 32a, 32b and 34a, 34b where each working pair is separated by a thin layer of elastomeric dielectric polymer 26 (e.g., made of acrylate, silicone, urethane, thermoplastic elastomer, hydrocarbon rubber, fluororelastomer, or the like). When a voltage difference is applied across the oppositely-charged electrodes of each working pair (i.e., across electrodes 32a and 32b, and across electrodes 34a and 34b), the opposed electrodes attract each other thereby compressing the dielectric polymer layer 26 therebetween. As the electrodes are pulled closer together, the dielectric polymer 26 becomes thinner (i.e., the z-axis component contracts) as it expands in the planar directions (i.e., the x- and y-axes components expand) (see FIGS. 9B and 9C for axis references). Furthermore, like charges distributed across each electrode cause the conductive particles embedded within that electrode to repel one another, thereby contributing to the expansion of the elastic electrodes and dielectric films. The dielectric layer 26 is thereby caused to deflect with a change in electric field. As the electrode material is also compliant, the electrode layers change shape along with dielectric layer 26. Generally speaking, deflection refers to any displacement, expansion, contraction, torsion, linear or area strain, or any other deformation of a portion of dielectric layer 26. This deflection may be used to produce mechanical work.

In fabricating transducer 20, elastic film is stretched and held in a pre-strained condition by two or more opposing rigid frame sides 8a, 8b. In those variations employing a 4-sided frame, the film is stretched bi-axially. It has been observed that the pre-strain improves the dielectric strength of the polymer layer 26, thereby improving conversion between electrical and mechanical energy, i.e., the pre-strain allows the film to deflect more and provide greater mechanical work. Typically, the electrode material is applied after pre-straining the polymer layer, but may be applied beforehand. The two electrodes provided on the same side of layer 26, referred to herein as same-side electrode pairs, i.e., electrodes 32a and 34a on top side 26a of dielectric layer 26 (see FIG. 9B) and electrodes 32b and 34b on bottom side 26b of dielectric layer 26 (see FIG. 9C), are electrically isolated from each other by inactive areas or gaps 25. The opposed electrodes on the opposite sides of the polymer layer from two sets of working electrode pairs, i.e., electrodes 32a and 32b for one working electrode pair and electrodes 34a and 34b for another working electrode pair. Each same-side electrode pair preferably has the same polarity, while the polarity of the electrodes of each working electrode pair are opposite each other, i.e., electrodes 32a and 32b are oppositely charged and electrodes 34a and 34b are oppositely charged. Each electrode has an electrical contact portion 35 configured for electrical connection to a voltage source (not shown).

In the illustrated embodiment, each of the electrodes has a semi-circular configuration where the same-side electrode pairs define a substantially circular pattern for accommodating a centrally disposed, rigid output disc 20a, 20b on each side of dielectric layer 26. Discs 20a, 20b, the functions of which are discussed below, are secured to the centrally exposed outer surfaces 26a, 26b of polymer layer 26, thereby sandwiching layer 26 therebetween. The coupling between the discs and film may be mechanical or be provided by an adhesive bond. Generally, the discs 20a, 20b will be sized relative to the transducer frame 22a, 22b. More specifically, the ratio of the disc diameter to the inner annular diameter of the frame will be such so as to adequately distribute stress applied to transducer film 10. The greater the ratio of the disc diameter to the frame diameter, the greater the force of the feedback signal or movement but with a lower linear displacement of the disc. Alternately, the lower the ratio, the lower the output force and the greater the linear displacement.

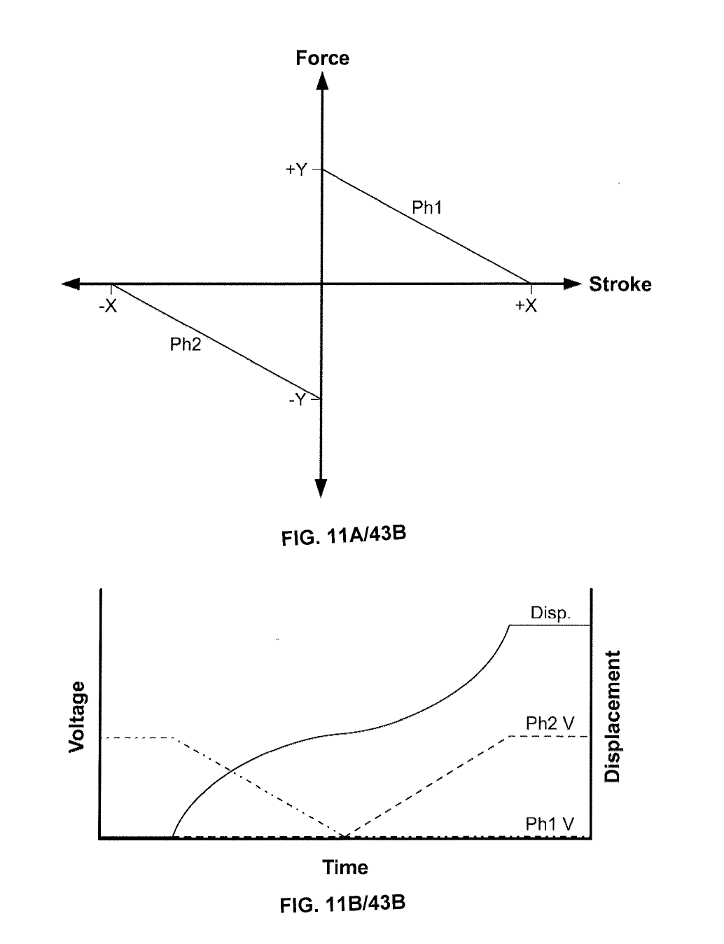

Depending upon the electrode configurations, transducer 10 can be capable of functioning in either a single or a two-phase mode. In the manner configured, the mechanical displacement of the output component, i.e., the two coupled discs 20a and 20b, of the subject sensory feedback device described above is lateral rather than vertical. In other words, instead of the sensory feedback signal being a force in a direction perpendicular to the display surface 232 of the user interface and parallel to the input force (designated by arrow 60a in FIG. 10) applied by the user's finger 38 (but in the opposing or upward direction), the sensed feedback or output force (designated by double-head arrow 60b in FIG. 10) of the sensory/haptic feedback devices of the present invention is in a direction parallel to the display surface 232 and perpendicular to input force 60a. Depending on the rotational alignment of the electrode pairs about an axis perpendicular to the plane of transducer 10 and relative to the position of the display surface 232 mode in which the transducer is operated (i.e., single phase or two phase), this lateral movement may be in any direction or directions within 360°. For example, the lateral feedback motion may be from side to side or up and down (both are two-phase actuations) relative to the forward direction of the user's finger (or palm or grip, etc.). While those skilled in the art will recognize certain other actuator configurations which provide a feedback displacement which is transverse or perpendicular to the contact surface of the haptic feedback device, the overall profile of a device so configured may be greater than the aforementioned design.

FIGS. 9D-9G illustrate an example of an array of electro-active polymers that can be placed across the display screen of the device. In this example, voltage and ground sides 200a and 200b, respectively, of an EAP film array 200 (see FIG. 9F) for use in an array of EAP actuators for use in the tactile feedback devices of the present invention. Film array 200 includes an electrode array provided in a matrix configuration to increase space and power efficiency and simplify control circuitry. The high voltage side 200a of the EAP film array provides electrode patterns 202 running in vertically (according to the view point illustrated in FIG. 9D) on dielectric film 208 materials. Each pattern 202 includes a pair of high voltage lines 202a, 20M. The opposite or ground side 200b of the EAP film array provides electrode patterns 206 running transversally relative to the high voltage electrodes, i.e., horizontally.

Each pattern 206 includes a pair of ground lines 206a, 206b. Each pair of opposing high voltage and ground lines (202a, 206a and 20M, 206h) provides a separately activatable electrode pair such that activation of the opposing electrode pairs provides a two-phase output motion in the directions illustrated by arrows 212. The assembled EAP film array 200 (illustrating the intersecting pattern of electrodes on top and bottom sides of dielectric film 208) is provided in FIG. 9F within an exploded view of an array 204 of EAP transducers 222, the latter of which is illustrated in its assembled form in FIG. 9G. EAP film array 200 is sandwiched between opposing frame arrays 214a, 214b, with each individual frame segment 216 within each of the two arrays defined by a centrally positioned output disc 218 within an open area. Each combination of frame/disc segments 216 and electrode configurations form an EAP transducer 222. Depending on the application and type of actuator desired, additional layers of components may be added to transducer array 204. The transducer array 220 may be incorporated in whole to a user interface array, such as a display screen, sensor surface, or touch pad, for example.

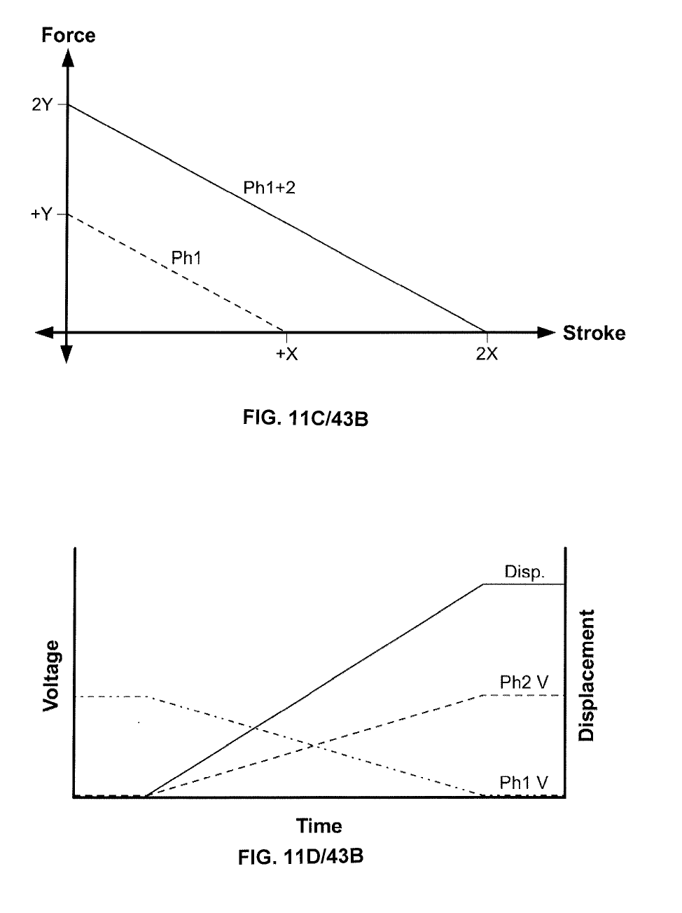

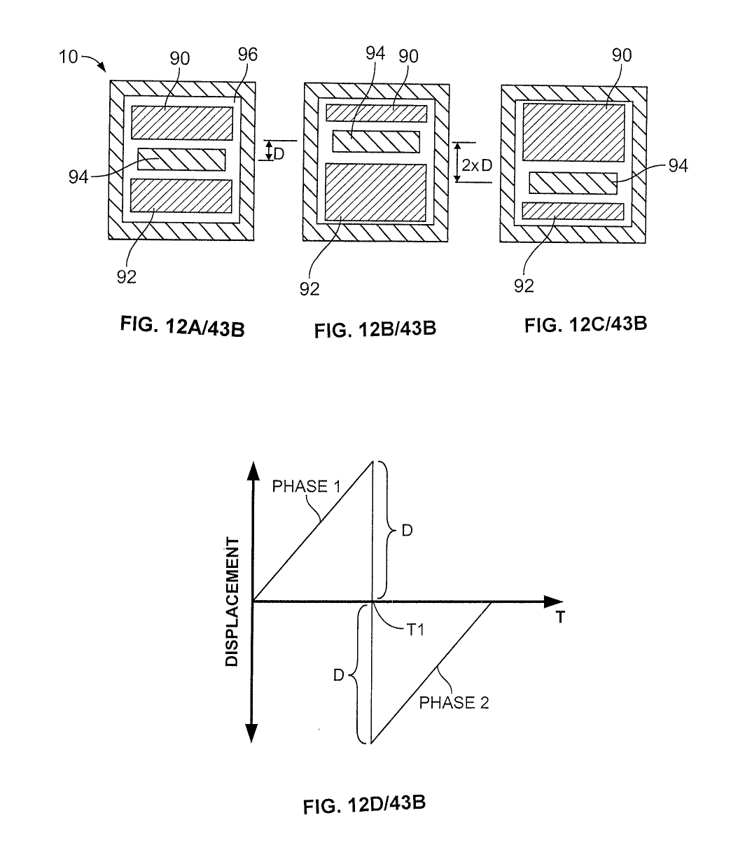

When operating sensory/haptic feedback device 2 in single-phase mode, only one working pair of electrodes of actuator 30 would be activated at any one time. The single-phase operation of actuator 30 may be controlled using a single high voltage power supply. As the voltage applied to the single-selected working electrode pair is increased, the activated portion (one hail) of the transducer film will expand, thereby moving the output disc 20 in-plane in the direction of the inactive portion of the transducer film. FIG. 11A illustrates the force-stroke relationship of the sensory feedback signal (i.e., output disc displacement) of actuator 30 relative to neutral position when alternatingly activating the two working electrode pairs in single-phase mode. As illustrated, the respective forces and displacements of the output disc are equal to each other but in opposite directions. FIG. 11B illustrates the resulting non-linear relationship of the applied voltage to the output displacement of the actuator when operated in this single-phase mode. The “mechanical” coupling of the two electrode pairs by way of the shared dielectric film may be such as to move the output disc in opposite directions. Thus, when both electrode pairs are operated, albeit independently of each other, application of a voltage to the first working electrode pair (phase 1) will move the output disc 20 in one direction, and application of a voltage to the second working electrode pair (phase 2) will move the output disc 20 in the opposite direction. As the various plots of FIG. 11B reflect, as the voltage is varied linearly, the displacement of the actuator is non-linear. The acceleration of the output disk during displacement can also be controlled through the synchronized operation of the two phases to enhance the haptic feedback effect. The actuator can also be partitioned into more than two phases that can be independently activated to enable more complex motion of the output disk.

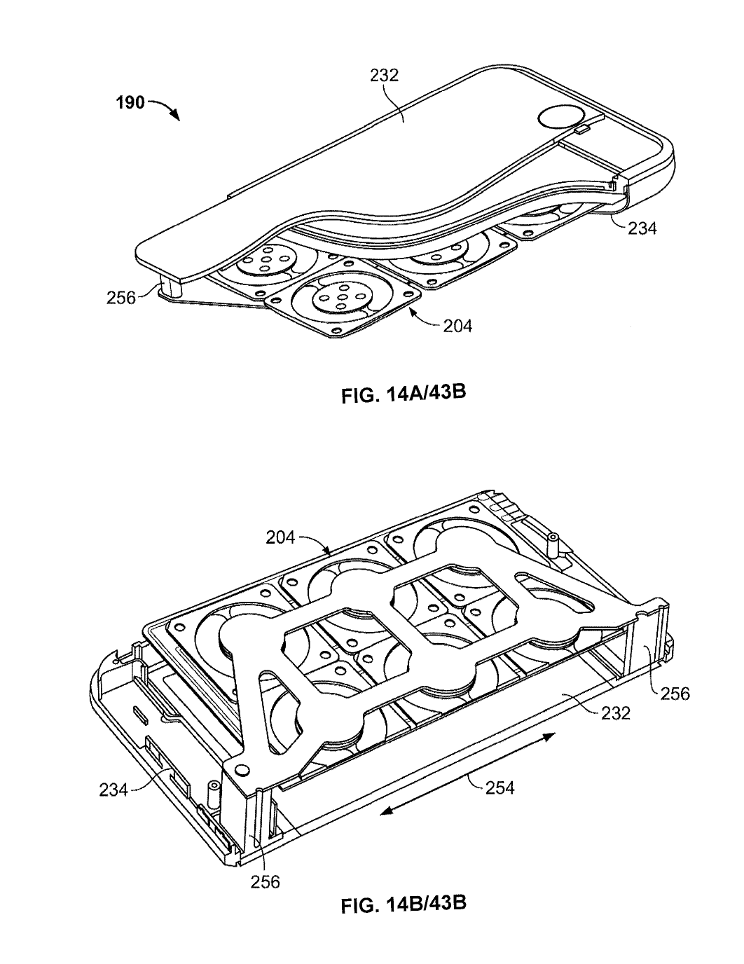

To effect a greater displacement of the output member or component, and thus provide a greater sensory feedback signal to the user, actuator 30 is operated in a two-phase mode, i.e., activating both portions of the actuator simultaneously. FIG. 11C illustrates the force-stroke relationship of the sensory feedback signal of the output disc when the actuator is operated in two-phase mode. As illustrated, both the force and stroke of the two portions 32, 34 of the actuator in this mode are in the same direction and have double the magnitude than the force and stroke of the actuator when operated in single-phase mode. FIG. 11D illustrates the resulting linear relationship of the applied voltage to the output displacement of the actuator when operated in this two-phase mode. By connecting the mechanically coupled portions 32, 34 of the actuator electrically in series and controlling their common node 55, such as in the manner illustrated in the block diagraph 40 of FIG. 13, the relationship between the voltage of the common node 55 and the displacement (or blocked three) of the output member (in whatever configuration) approach a linear correlation. In this mode of operation, the non-linear voltage responses of the two portions 32, 34 of actuator 30 effectively cancel each other out to produce a linear voltage response. With the use of control circuitry 44 and switching assemblies 46a, 46h, one for each portion of the actuator, this linear relationship allows the performance of the actuator to be fine-tuned and modulated by the use of varying types of waveforms supplied to the switch assemblies by the control circuitry. Another advantage of using circuit 40 is the ability to reduce the number of switching circuits and power supplies needed to operate the sensory feedback device. Without the use of circuit 40, two independent power supplies and four switching assemblies would be required. Thus, the complexity and cost of the circuitry are reduced while the relationship between the control voltage and the actuator displacement are improved, i.e., made more linear. Another advantage is that during 2-phase operation, the actuator obtains synchronicity, which eliminates delays that could reduce performance.

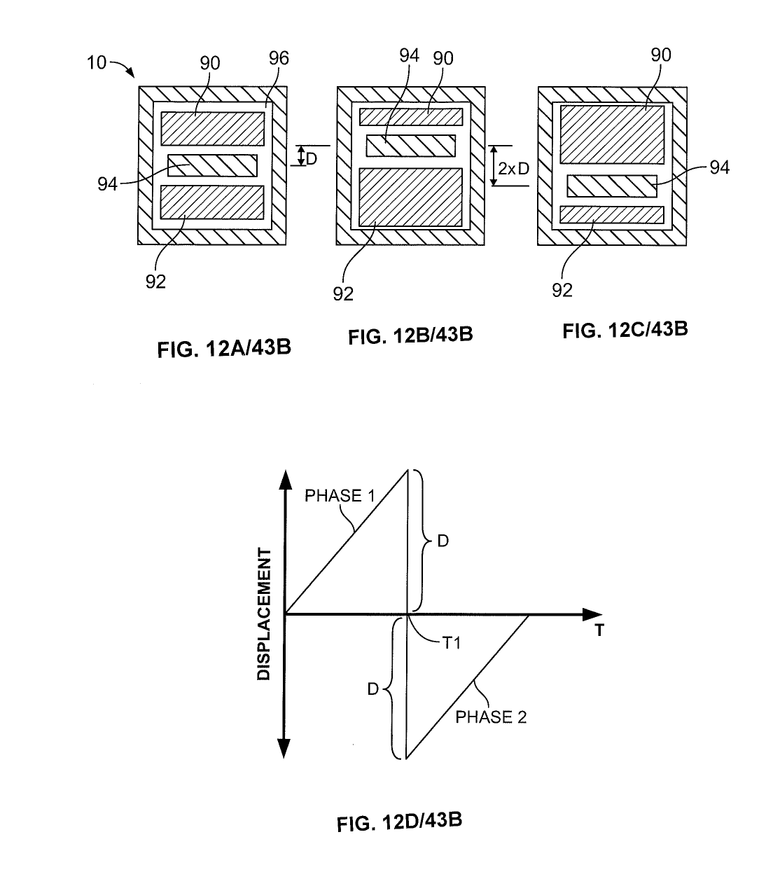

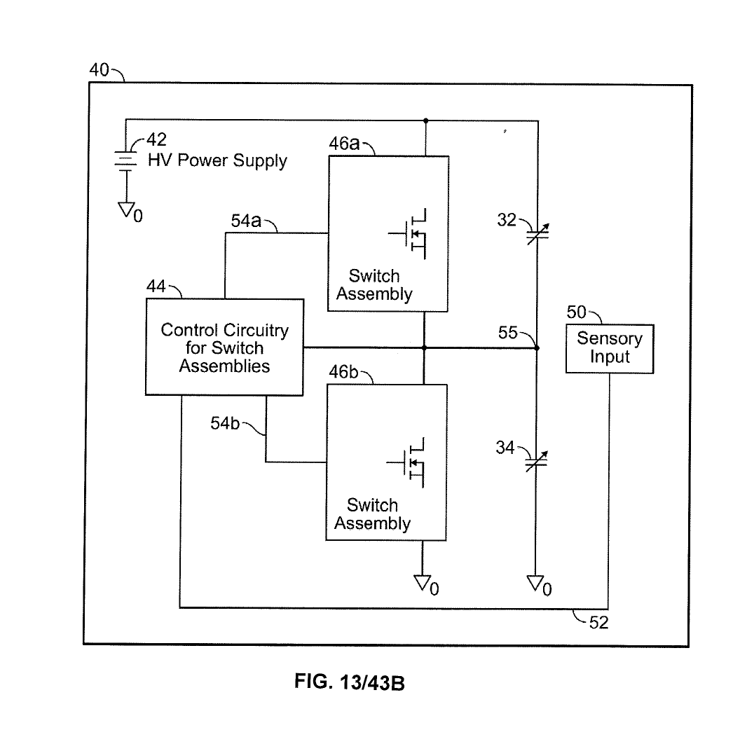

FIGS. 12A to 12C illustrate another variation of a 2-phase electroactive polymer transducer. In this variation, the transducer 10 comprises a first pair of electrodes 90 about the dielectric film 96 and a second pair of electrodes 92 about the dielectric film 96 where the two pairs of electrodes 90 and 92 are on opposite sides of a bar or mechanical member 94 that facilitates coupling to another structure to transfer movement. As shown in FIG. 12A, both electrodes 90 and 92 are at the same voltage (e.g., both being at a zero voltage). In the first phase, as illustrated in FIG. 12B, one pair of electrodes 92 is energized to expand the film and move the bar 94 by a distance D. The second pair of electrodes 90 is compressed by nature of being connected to the film but is at a zero voltage. FIG. 12C shows a second phase in which the voltage of the first pair of electrodes 92 is reduced or turned off while voltage is applied to the second pair of electrodes 90 is energized. This second phase is synchronized with the first phase so that the displacement is 2 times D. FIG. 12D illustrates the displacement of the transducer 10 of FIGS. 12A to 12C over time. As shown, Phase 1 occurs as the bar 94 is displaced by amount D when the first electrode 92 is energized for Phase 1. At time T1 the beginning of Phase 2 occurs and the opposite electrode 90 is energized in synchronization with the reduction of the voltage of the first electrode 92. The net displacement of the bar 94 over the two phases is 2×D.

Various types of mechanisms may be employed to communicate the input force 60a from the user to effect the desired sensory feedback 60b (see FIG. 10). For example, a capacitive or resistive sensor 50 (see FIG. 13) may be housed within the user interface pad 4 to sense the mechanical force exerted on the user contact surface input by the user. The electrical output 52 from sensor 50 is supplied to the control circuitry 44 that in turn triggers the switch assemblies 46a, 46b to apply the voltage from power supply 42 to the respective transducer portions 32, 34 of the sensory feedback device in accordance with the mode and waveform provided by the control circuitry.

Another variation of the present invention involves the hermetic sealing of the EAP actuators to minimize any effects of humidity or moisture condensation that may occur on the EAP film. For the various embodiments described below, the EAP actuator is sealed in a barrier film substantially separately from the other components of the tactile feedback device. The barrier film or casing may be made of, such as foil, which is preferably heat scaled or the like to minimize the leakage of moisture to within the sealed film. Portions of the barrier film or casing can be made of a compliant material to allow improved mechanical coupling of the actuator inside the casing to a point external to the casing. Each of these device embodiments enables coupling of the feedback motion of the actuator's output member to the contact surface of the user input surface, e.g., keypad, while minimizing any compromise in the hermetically sealed actuator package.

Various exemplary means for coupling the motion of the actuator to the user interface contact surface are also provided. Regarding methodology, the subject methods may include each of the mechanical and/or activities associated with use of the devices described. As such, methodology implicit to the use of the devices described forms part of the invention. Other methods may fbcus on fabrication of such devices.

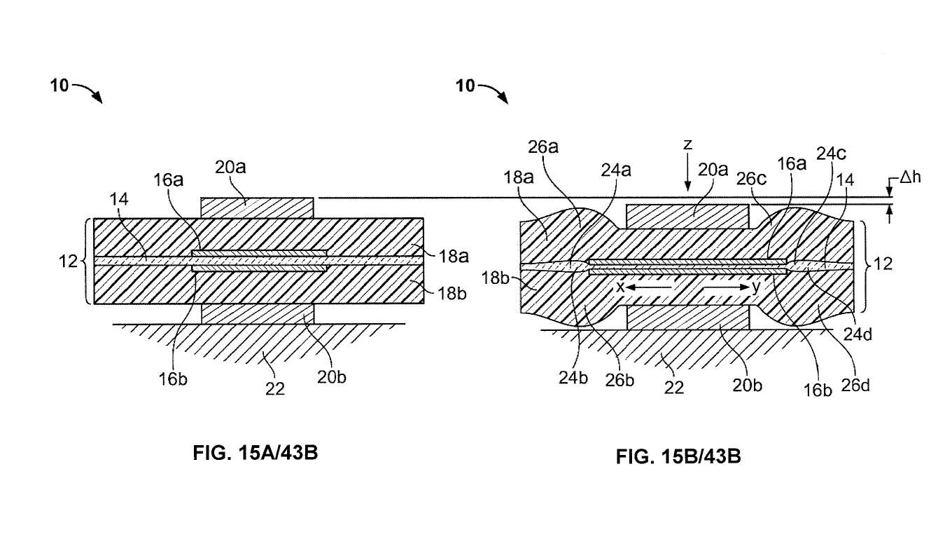

FIG. 14A shows an example of a planar array of LAP actuators 204 coupled to a user input device 190. As shown, the array of EAP actuators 204 covers a portion of the screen 232 and is coupled to a frame 234 of the device 190 via a stand off 256. In this variation, the stand off 256 permits clearance for 1, movement of the actuators 204 and screen 232. In one variation of the device 190 the array of actuators 204 can be multiple discrete actuators or an array of actuators behind the user interface surface or screen 232 depending upon the desired application. FIG. 14B shows a bottom view of the device 190 of FIG. 14A. As shown by arrow 254 the EAP actuators 204 can allow for movement of the screen 232 along an axis either as an alternative to, or in combination with movement in a direction normal to the screen 232.

The transducer/actuator embodiments described thus far have the passive layer(s) coupled to both the active (i.e., areas including overlapping electrodes) and inactive regions of the EAP transducer film. Where the transducer/actuator has also employed a rigid output structure, that structure has been positioned over areas of the passive layers that reside above the active regions. Further, the active/activatable regions of these embodiments have been positioned centrally relative to the inactive regions. The present invention also includes other transducer/actuator configurations. For example, the passive layer(s) may cover only the active regions or only the inactive regions. Additionally, the inactive regions of the EAP film may be positioned centrally to the active regions.

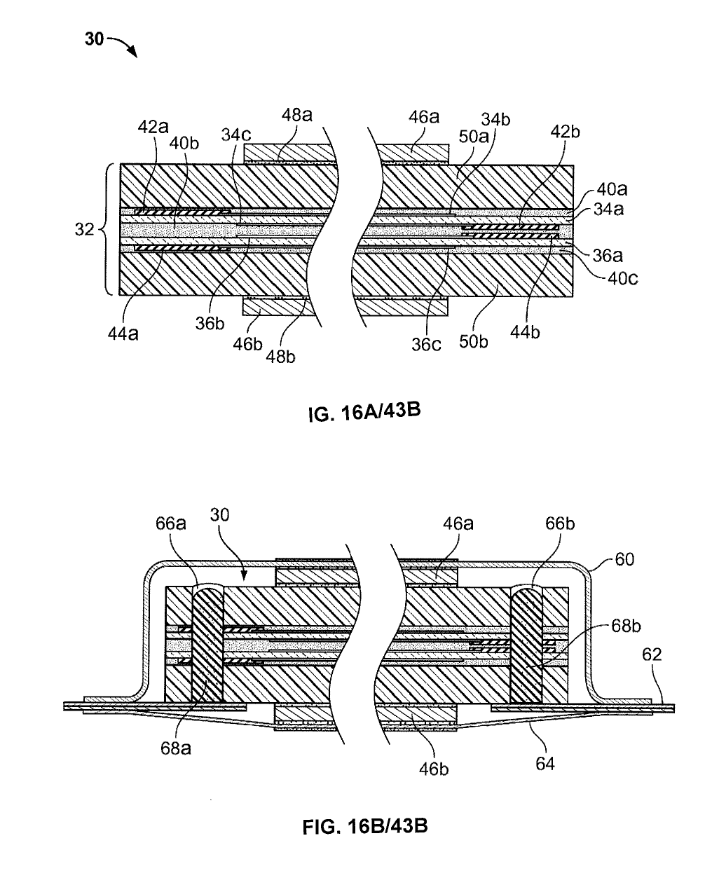

Referring to FIGS. 15A and 15B, a schematic representation is provided of a surface deformation EAP actuator 10 for converting electrical energy to mechanical energy in accordance with one embodiment of the invention. Actuator 10 includes EAP transducer 12 having a thin elastomeric dielectric polymer layer 14 and top and bottom electrodes 16a, 16b attached to the dielectric 14 on portions of its top and bottom surfaces, respectively. The portion of transducer 12 comprising the dielectric and at least two electrodes is referred to herein as an active area. Any of the transducers of the present invention may have one or more active areas.

When a voltage difference is applied across the overlapping and oppositely-charged electrodes 16a, 16b (the active area), the opposed electrodes attract each other thereby compressing the portion of the dielectric polymer layer 14 therebetween. As the electrodes 16a, 16b are pulled closer together (along the z-axis), the portion of the dielectric layer 14 between them becomes thinner as it expands in the planar directions (along the x- and y-axes). For incompressible polymers, i.e., those having a substantially constant volume under stress, or for otherwise compressible polymers in a frame or the like, this action causes the compliant dielectric material outside the active area (i.e., the area covered by the electrodes), particularly perimetrically about, i.e., immediately around, the edges of the active area, to be displaced or bulge out-of-plane in the thickness direction (orthogonal to the plane defined by the transducer film). This bulging produces dielectric surface features 24a-d. While out-of-plane surface features 24 are shown relatively local to the active area, the out-of-plane is not always localized as shown. In some cases, if the polymer is pre-strained, then the surface features 24a-b are distributed over a surface area of the inactive portion of the dielectric material.

To amplify the vertical profile and/or visibility of surface features of the subject transducers, an optional passive layer may be added to one or both sides of the transducer film structure where the passive layer covers all or a portion of the EAP film surface area. In the actuator embodiment of FIGS. 15A and 15B, top and bottom passive layers 18a, 181 are attached to the top and bottom sides, respectively, of the EAP film 12. Activation of the actuator and the resulting surface features 17a-d of dielectric layer 12 are amplified by the added thickness of passive layers 18a, 18b, as denoted by reference numbers 26a-d in FIG. 15B.

In addition to the elevated polymer/passive layer surface features 26a-d, the EAP film 12 may be configured such that the one or both electrodes 16a, 16b are depressed below the thickness of the dielectric layer. As such, the depressed electrode or portion thereof provides an electrode surface feature upon actuation of the EAP film 12 and the resulting deflection of dielectric material 14. Electrodes 16a, 16c may be patterned or designed to produce customized transducer film surface features which may comprise polymer surface features, electrode surface features and/or passive layer surface features.

In the actuator embodiment 10 of FIGS. 15A and 15B, one or more structures 20a, 20b are provided to facilitate coupling the work between the compliant passive slab and a rigid mechanical structure and directing the work output of the actuator. Here, top structure 20a (which may be in the form of a platform, bar, lever, rod, etc.) acts as an output member while bottom structure 20b serves to couple actuator 10 to a fixed or rigid structure 22, such as ground. These output structures need not be discrete components but, rather, may be integrated or monolithic with the structure which the actuator is intended to drive. Structures 20a, 20b also serve to define the perimeter or shape of the surface features 26a-d formed by the passive layers 18a, 18b. In the illustrated embodiment, while the collective actuator stack produces an increase in thickness of the actuator's inactive portions, as shown in FIG. 15B, the net change in height Δh undergone by the actuator upon actuation is negative.

The EAP transducers of the present invention may have any suitable construct to provide the desired thickness mode actuation. For example, more than one EAP film layer may be used to fabricate the transducers for use in more complex applications, such as keyboard keys with integrated sensing capabilities where an additional EAP film layer may be employed as a capacitive sensor.

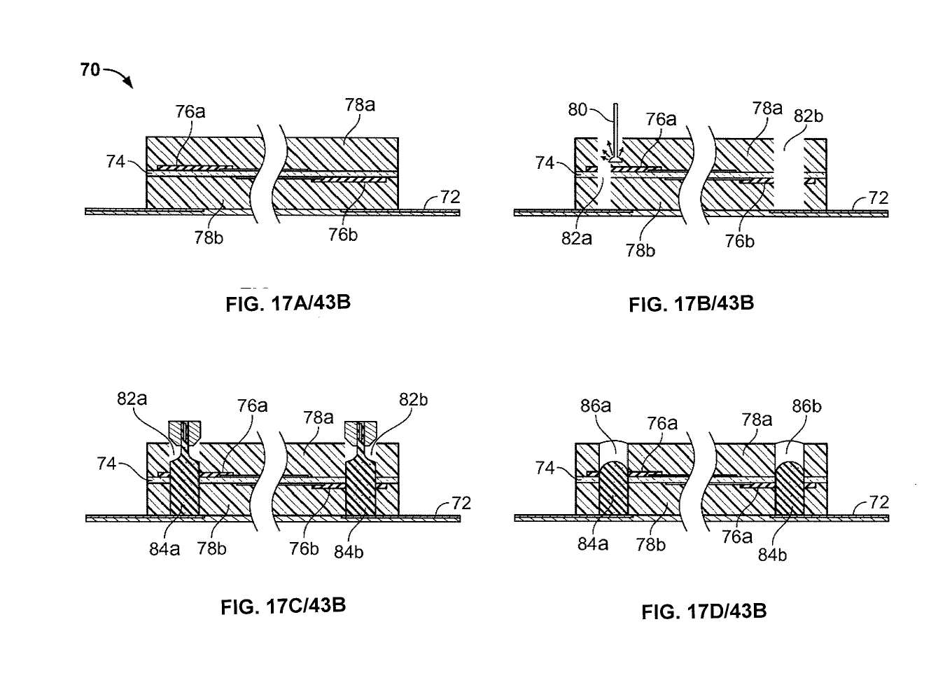

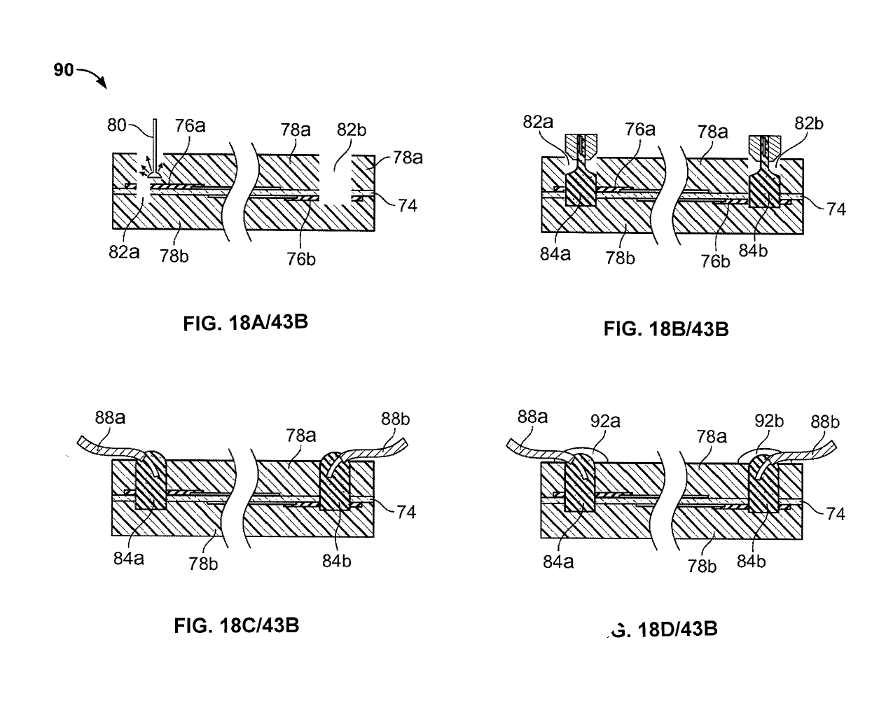

FIG. 16A illustrates such an actuator 30 employing a stacked transducer 32 having a double EAP film layer 34 in accordance with the present invention. The double layer includes two dielectric elastomer films with the top film 34a sandwiched between top and bottom electrodes 34b, 34c, respectively, and the bottom film 36a sandwiched between top and bottom electrodes 36b, 36e, respectively. Pairs of conductive traces or layers (commonly referred to as “bus bars”) are provided to couple the electrodes to the high voltage and ground sides of a source of power (the latter not shown). The bus bars are positioned on the “inactive” portions of the respective EAR films (i.e., the portions in which the top and bottom electrodes do not overlap). Top and bottom bus bars 42a, 42b are positioned on the top and bottom sides, respectively, of dielectric layer 34a, and top and bottom bus bars 44a, 44b positioned on the top and bottom sides, respectively, of dielectric layer 36a. The top electrode 34b of dielectric 34a and the bottom electrode 36e of dielectric 36a, i.e., the two outwardly facing electrodes, are commonly polarized by way of the mutual coupling of bus bars 42a and 44a through conductive elastomer via 68a (shown in FIG. 16B), the formation of which is described in greater detail below with respect to FIGS. 17A-17D. The bottom electrode 34c of dielectric 34a and the top electrode 36b of dielectric 36a, i.e., the two inwardly facing electrodes, are also commonly polarized by way of the mutual coupling of bus bars 42b and 44b through conductive elastomer via 68b (shown in FIG. 16B). Potting material 66a, 66b is used to seal via 68a, 68b. When operating the actuator, the opposing electrodes of each electrode pair are drawn together when a voltage is applied. For safety purposes, the ground electrodes may be placed on the outside of the stack to ground any piercing object before it reaches the high voltage electrodes, thus eliminating a shock hazard. The two EAP film layers may be adhered together by film-to-film adhesive 40b. The adhesive layer may optionally include a passive or slab layer to enhance performance. A top passive layer or slab 50a and a bottom passive layer 52b are adhered to the transducer structure by adhesive layer 40a and by adhesive layer 40e. Output bars 46a, 46b may be coupled to top and bottom passive layers, respectively, by adhesive layers 48a, 48b, respectively.

The actuators of the present invention may employ any suitable number of transducer layers, where the number of layers may be even or odd. In the latter construct, one or more common ground electrode and bus bar may be used. Additionally, where safety is less of an issue, the high voltage electrodes may be positioned on the outside of the transducer stack to better accommodate a particular application.

To be operational, actuator 30 must be electrically coupled to a source of power and control electronics (neither are shown). This may be accomplished by way of electrical tracing or wires on the actuator or on a PCB or a flex connector 62, which couples the high voltage and ground vias 68a, 68b to a power supply or an intermediate connection. Actuator 30 may be packaged in a protective barrier material to seal it from humidity and environmental contaminants. Here, the protective barrier includes top and bottom covers 60, 64 that are preferably sealed about PCB/flex connector 62 to protect the actuator from external forces and strains and/or environmental exposure. In some embodiments, the protective barrier maybe impermeable to provide a hermetic seal. The covers may have a somewhat rigid form to shield actuator 30 against physical damage or may be compliant to allow room for actuation displacement of the actuator 30. In one specific embodiment, the top cover 60 is made of formed foil and the bottom cover 64 is made of a compliant foil, or vice versa, with the two covers then heat-sealed to board/connector 62. Many other packaging materials such as metalized polymer films, PVDC, Aclar, styrenic or olefinic copolymers, polyesters and polyolefins can also be used. Compliant material is used to cover the output structure or structures, here bar 46b, which translate actuator output.

The conductive components/layers of the stacked actuator/transducer structures of the present invention, such as actuator 30 just described, are commonly coupled by way of electrical vias (68a and 68b in FIG. 163) formed through the stacked structure. FIGS. 17a-19 illustrate various methods of the present invention for forming the vias.

Formation of the conductive vias of the type employed in actuator 30 of FIG. 16B is described with reference to FIGS. 17A-17D. Either before or after lamination of actuator 70 (here, constructed from a single-film transducer with diametrically positioned bus bars 76a, 76b placed on opposite sides of the inactive portions of dielectric layer 74, collectively sandwiched between passive layers 78a, 78b) to a PCB/flex connector 72, the stacked transducer/actuator structure 70 is laser drilled 80 through its entire thickness to PCB 72 to form the via holes 82a, 82b, as illustrated in FIG. 17B. Other methods for creating the via holes can also be used such as mechanically drilling, punching, molding, piercing, and coring. The via holes are then filled by any suitable dispensing method, such as by injection, with a conductive material, e.g., carbon particles in silicone, as shown in FIG. 17C. Then, as shown in FIG. 17D, the conductively filled vias 84a, 84b are optionally potted 86a, 86b with any compatible nonconductive material, e.g., silicone, to electrically isolate the exposed end of the vias. Alternatively, a non-conductive tape may be placed over the exposed vias.

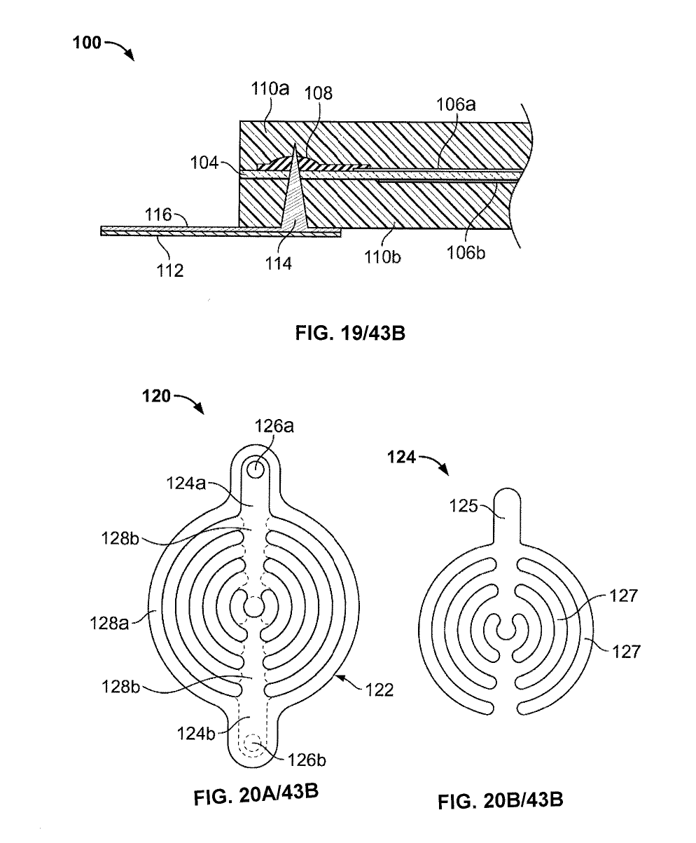

Standard electrical wiring may be used in lieu of a PCB or flex connector to couple the actuator to the power supply and electronics. Various steps of forming the electrical vias and electrical connections to the power supply with such embodiments are illustrated in FIGS. 18A-18D with like components and steps to those in FIGS. 17A-17D having the same reference numbers. Here, as shown in FIG. 18A, via holes 82a, 82b need only be drilled to a depth within the actuator thickness to the extent that the bus bars 84a, 84b are reached. The via holes are then filled with conductive material, as shown in FIG. 18B, after which wire leads 88a, 88b are inserted into the deposited conductive material, as shown in FIG. 18C. The conductively filled vias and wire leads may then be potted over, as shown in FIG. 18D.

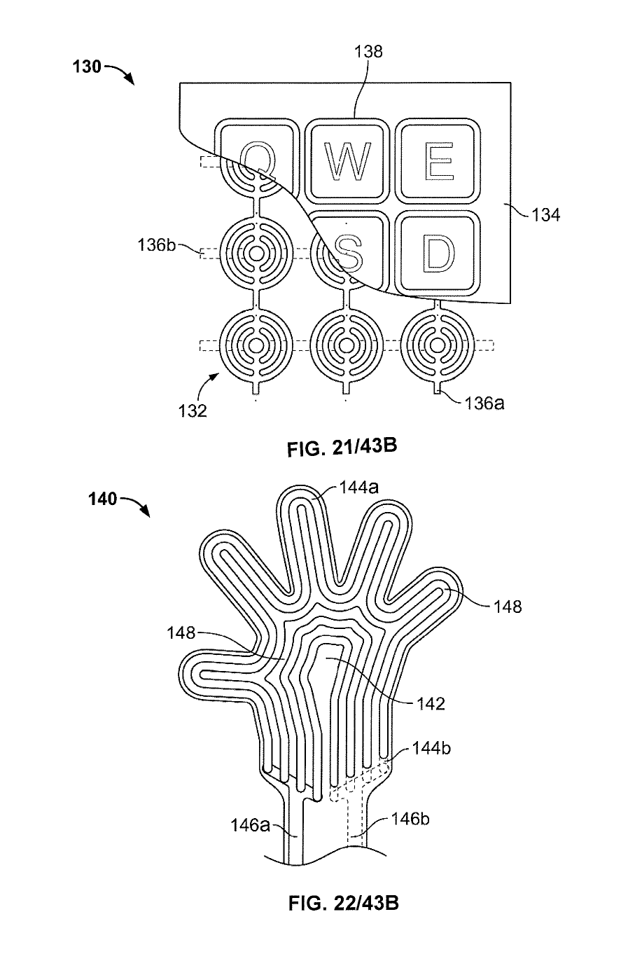

FIG. 19 illustrates another manner of providing conductive vias within the transducers of the present invention. Transducer 100 has a dielectric film comprising a dielectric layer 104 having portions sandwiched between electrodes 106a, 106b, which in turn are sandwiched between passive polymer layers 110a, 110b. A conductive bus bar 108 is provided on an inactive area of the EAP film. A conductive contact 114 having a piercing configuration is driven, either manually or otherwise, through one side of the transducer to a depth that penetrates the bus bar material 108 is conductive trace 116 extends along PCB/flex connector 112 from the exposed end of piercing contact 114. This method of forming vias is particularly efficient as it eliminates the steps of drilling the via holes, filling the via holes, placing a conductive wire in the via holes and potting the via holes.

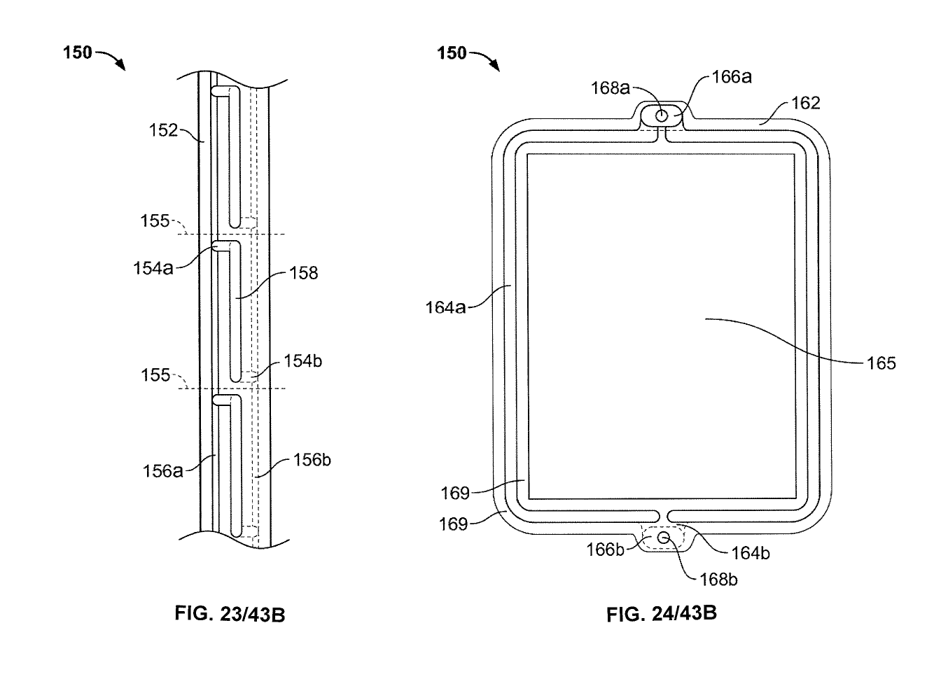

The EAP transducers of the present invention are usable in a variety of actuator applications with any suitable construct and surface feature presentation. FIGS. 20A-24 illustrate exemplary thickness mode transducer/actuator applications.

FIG. 20A illustrates a thickness mode transducer 120 having a round construct which is ideal for button actuators for use in tactile or haptic feedback applications in which a user physically contacts a device, e.g., keyboards, touch screens, phones, etc. Transducer 120 is formed from a thin elastomeric dielectric polymer layer 122 and top and bottom electrode patterns 124a, 124b (the bottom electrode pattern is shown in phantom), best shown in the isolated view in FIG. 20B. Each of the electrode patterns 124 provides a stem portion 125 with a plurality of oppositely extending finger portions 127 forming a concentric pattern. The stems of the two electrodes are positioned diametrically to each other on opposite sides of the round dielectric layer 122 where their respective finger portions are in appositional alignment with each other to produce the pattern shown in FIG. 20A. While the opposing electrode patterns in this embodiment are identical and symmetrical to each other, other embodiments are contemplated where the opposing electrode patterns are asymmetric, in shape and/or the amount of surface area which they occupy. The portions of the transducer material in which the two electrode materials do not overlap define the inactive portions 128a, 128b of the transducer. An electrical contact 126a, 126b is provided at the base of each of the two electrode stem portions for electrically coupling the transducer to a source of power and control electronics (neither are shown). When the transducer is activated, the opposing electrode fingers are drawn together, thereby compressing dielectric material 122 therebetween with the inactive portions 128a, 128b of the transducer bulging to form surface features about the perimeter of the button and/or internally to the button as desired.

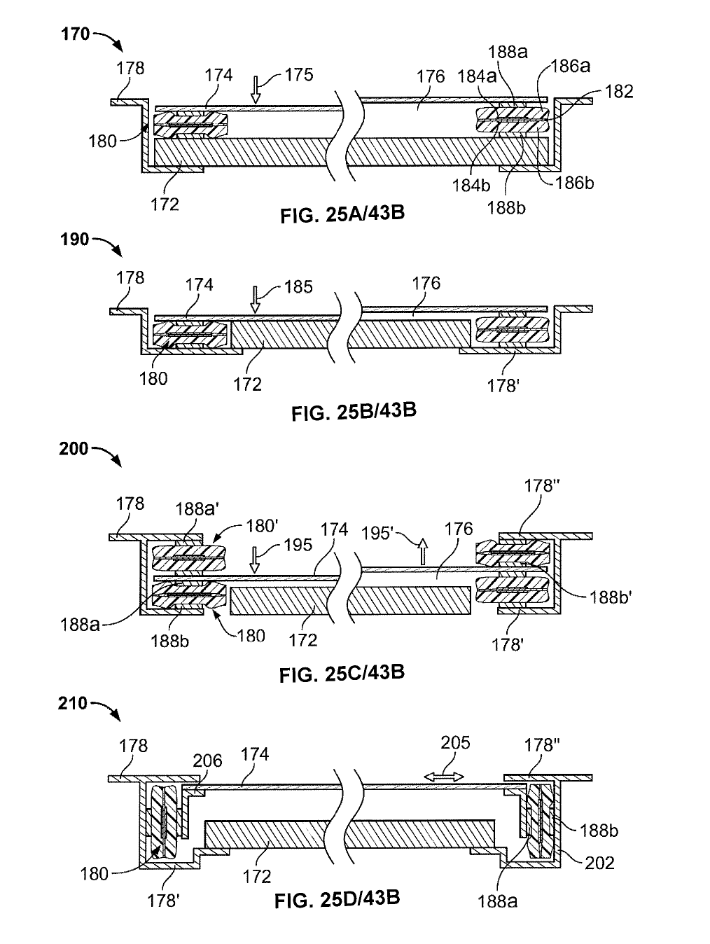

The button actuator may be in the form of a single input or contact surface or may be provided in an array format having a plurality of contact surfaces. When constructed in the form of arrays, the button transducers of FIG. 20A are ideal for use in keypad actuators 130, as illustrated in FIG. 21, for a variety of user interface devices, e.g., computer keyboards, phones, calculators, etc. Transducer array 132 includes a top array 136a of interconnected electrode patterns and bottom array 136b (shown in phantom) of electrode patterns with the two arrays opposed with each other to produce the concentric transducer pattern of FIG. 20A with active and inactive portions as described. The keyboard structure may be in the faun of a passive layer 134 atop transducer array 132. Passive layer 134 may have its own surface features, such as key border 138, which may be raised in the passive state to enable the user to tactilely align his/her fingers with the individual key pads, and/or further amplify the bulging of the perimeter of the respective buttons upon activation. When a key is pressed, the individual transducer upon which it lays is activated, causing the thickness mode bulging as described above, to provide the tactile sensation back to the user. Any number of transducers may be provided in this manner and spaced apart to accommodate the type and size of keypad 134 being used. Examples of fabrication techniques for such transducer arrays are disclosed in U.S. patent application Ser. No. 12/163,554 filed on Jun. 27, 2008 entitled ELECTROACTIVE POLYMER TRANSDUCERS FOR SENSORY FEEDBACK APPLICATIONS, which is incorporated by reference in its entirety.

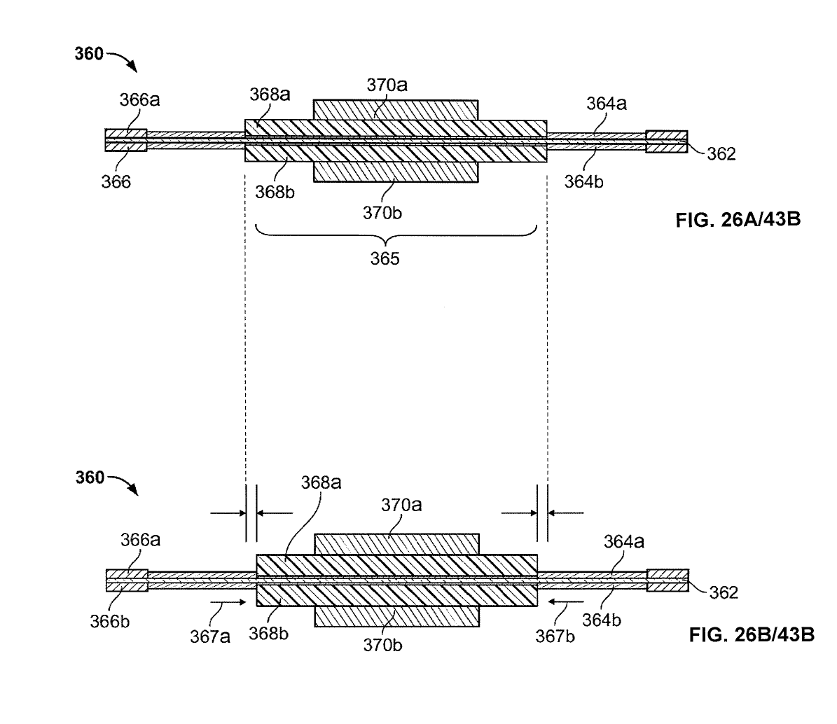

Those skilled in the art will appreciate that the thickness mode transducers of the present invention need not be symmetrical and may take on any construct and shape. The subject transducers may be used in any imaginable novelty application, such as the novelty hand device 140 illustrated in FIG. 22. Dielectric material 142 in the form of a human hand is provided having top and bottom electrode patterns 144a, 144b (the underside pattern being shown in phantom) in a similar hand shape. Each of the electrode patterns is electrically coupled to a bus bar 146a, 146b, respectively, which in turn is electrically coupled to a source of power and control electronics (neither are shown). Here, the opposing electrode patterns are aligned with or atop each other rather than interposed, thereby creating alternating active and inactive areas. As such, instead of creating raised surface features on only the internal and external edges of the pattern as a whole, raised surface features are provided throughout the hand profile, i.e., on the inactive areas. It is noted that the surface features in this exemplary application may offer a visual feedback rather than a tactile feedback. It is contemplated that the visual feedback may be enhanced by coloring, reflective material, etc.

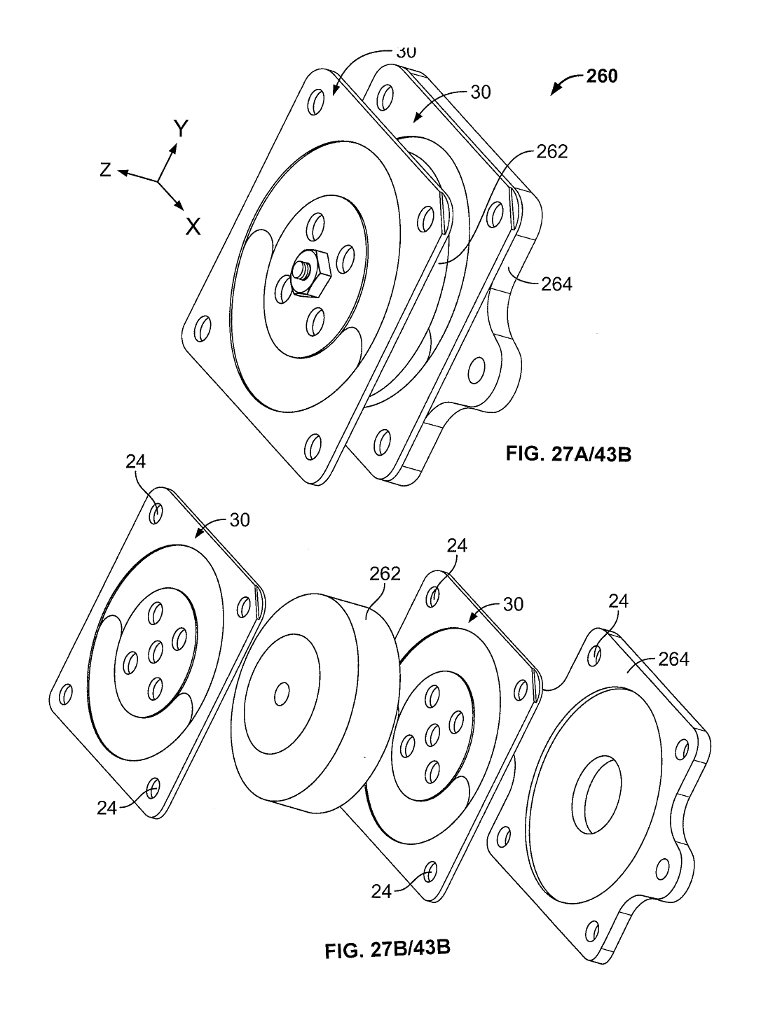

The transducer film of the present invention may be efficiently mass produced, particularly where the transducer electrode pattern is uniform or repeating, by commonly used web-based manufacturing techniques. As shown in FIG. 23, the transducer film 150 may be provided in a continuous strip format having continuous top and bottom electrical buses 156a, 156b deposited or formed on a strip of dielectric material 152. Most typically, the thickness mode features are defined by discrete (i.e., not continuous) but repeating active regions 158 formed by top and bottom electrode patterns 154a, 154b electrically coupled to the respective bus bars 156a, 156b; the size, length, shape and pattern of which may be customized for the particular application. However, it is contemplated that the active region(s) may be provided in a continuous pattern. The electrode and bus patterns may be formed by known web-based manufacturing techniques, with the individual transducers then singulated, also by known techniques such as by cutting strip 150 along selected singulation lines 155. It is noted that where the active regions are provided continuously along the strip, the strip is required to be cut with a high degree of precision to avoid shorting the electrodes. The cut ends of these electrodes may require potting or otherwise may be etched back to avoid tracking problems. The cut terminals of buses 156a, 156b are then coupled to sources of power/control to enable actuation of the resulting actuators.

Either prior to or after singulation, the strip or singulated strip portions, may be stacked with any number of other transducer film strips/strip portions to provide a multi-layer structure. The stacked structure may then be laminated and mechanically coupled, if so desired, to rigid mechanical components of the actuator, such an output bar or the like.

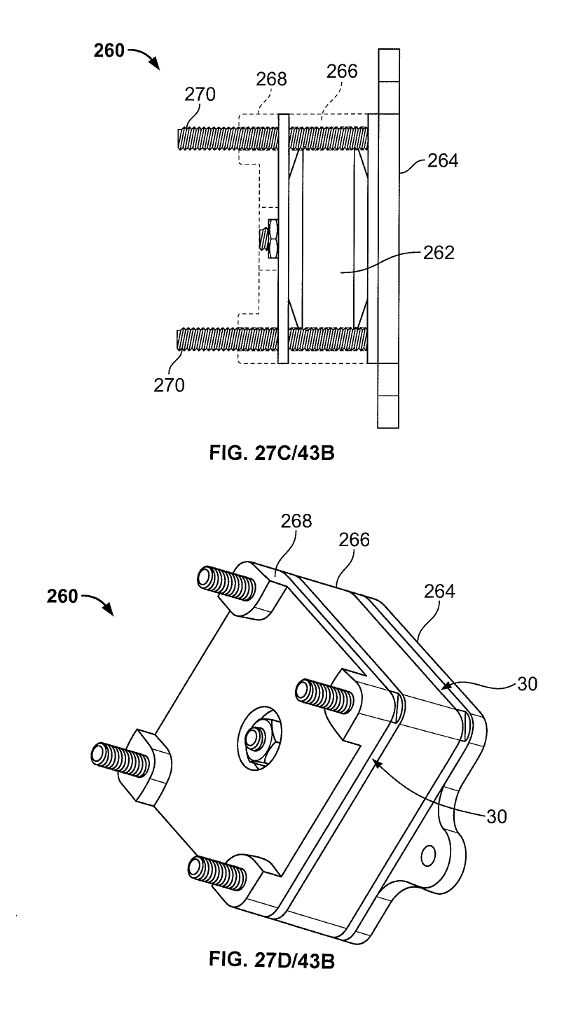

FIG. 24 illustrates another variation of the subject transducers in which a transducer 160 formed by a strip of dielectric material 162 with top and bottom electrodes 164a, 164b on opposing sides of the strip arranged in a rectangular pattern thereby framing an open area 165. Each of the electrodes terminates in an electrical bus 166a, 166b, respectively, having an electrical contact point 168a, 168b for coupling to a source of power and control electronics (neither being shown). A passive layer (not shown) that extends across the enclosed area 165 may be employed on either side of the transducer film, thereby forming a gasket configuration, for both environmental protection and mechanical coupling of the output bars (also not shown). As configured, activation of the transducer produces surface features along the inside and outside perimeters 169 of the transducer strip and a reduction in thickness of the active areas 164a 164b. It should be noted that the gasket actuator need not be a continuous, single actuator. One or more discrete actuators can also be used to line the perimeter of an area which may be optionally sealed with non-active compliant gasket material

Other gasket-type actuators are disclosed in U.S. patent application Ser. No. 12/163,554, referenced above. These types of actuators are suitable for sensory (e.g., haptic or vibratory) feedback applications such as with touch sensor plates, touch pads and touch screens for application in handheld multimedia devices, medical instrumentation, kiosks or automotive instrument panels, toys and other novelty products, etc.

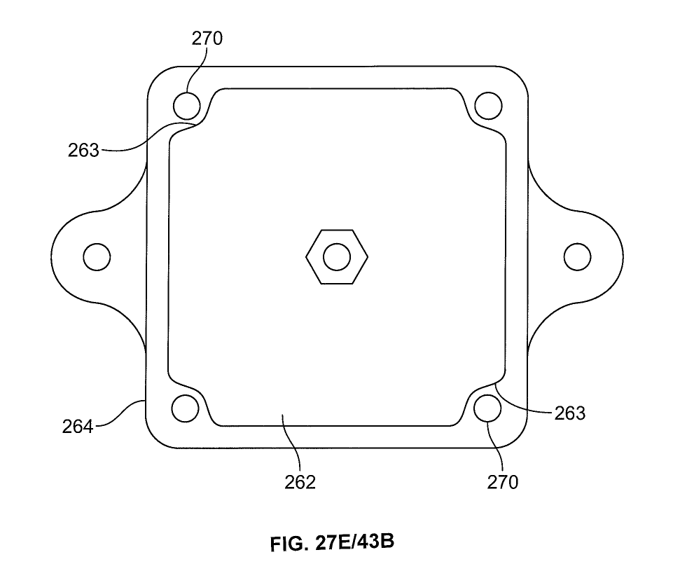

FIGS. 25A-25D are cross-sectional views of touch screens employing variations of a thickness mode actuator of the present invention with like reference numbers referencing similar components amongst the four figures. Referring to FIG. 25A, the touch screen device 170 may include a touch sensor plate 174, typically made of a glass or plastic material, and, optionally, a liquid crystal display (LCD) 172. The two are stacked together and spaced apart by EAP thickness mode actuator 180 defining an open space 176 therebetween. The collective stacked structure is held together by frame 178. Actuator 180 includes the transducer film formed by dielectric film layer 182 sandwiched centrally by electrode pair 184a, 184b. The transducer film is in turn sandwiched between top and bottom passive layers 186a, 186b and further held between a pair of output structures 188a, 188b which are mechanically coupled to touch plate 174 and LCD 172, respectively. The right side of FIG. 25A shows the relative position of the LCD and touch plate when the actuator is inactive, while the left side of FIG. 25A shows the relative positions of the components when the actuator is active, i.e., upon a user depressing touch plate 174 in the direction of arrow 175. As is evident from the left side of the drawing, when actuator 180 is activated, the electrodes 184a, 184b are drawn together thereby compressing the portion of dielectric film 182 therebetween while creating surface features in the dielectric material and passive layers 186a, 186b outside the active area, which surface features are further enhanced by the compressive force caused by output blocks 188a, 188b. As such, the surface features provide a slight force on touch plate 174 in the direction opposite arrow 175 which gives the user a tactile sensation in response to depressing the touch plate.

Touch screen device 190 of FIG. 25B has a similar construct to that of FIG. 25A with the difference being that LCD 172 wholly resides within the internal area framed by the rectangular (or square, etc.) shaped thickness mode actuator 180. As such, the spacing 176 between LCD 172 and touch plate 174 when the device is in an inactive state (as demonstrated on the right side of the figure) is significantly less than in the embodiment of FIG. 25A, thereby providing a lower profile design. Further, the bottom output structure 188b of the actuator rests directly on the back wall 178 of frame 178, irrespective of the structural differences between the two embodiments, device 190 functions similarly to device 170 in that the actuator surface features provide a slight tactile force in the direction opposite arrow 185 in response to depressing the touch plate.

The two touch screen devices just described are single phase devices as they function in a single direction. Two (or more) of the subject gasket-type actuators may be used in tandem to produce a two phase (bi-directional) touch screen device 200 as in. FIG. 25C. The construct of device 200 is similar to that of the device of FIG. 25B but with the addition of a second thickness mode actuator 180 which sits atop touch plate 174. The two actuators and touch plate 174 are held in stacked relation by way of frame 178 which has an added inwardly extending top shoulder 178″. As such, touch plate 174 is sandwiched directly between the innermost output blocks 188a, 188b′ of actuators 180, 180′, respectively, while the outermost output blocks 188b, 188a′ of actuators 180′, respectively, buttress the frame members 178′ and 178″, respectively. This enclosed gasket arrangement keeps dust and debris out of the optical path within space 176. Here, the left side of the figure illustrates bottom actuator 180 in an active state and top actuator 180′ in a passive state in which sensor plate 174 is caused to move towards LCD 172 in the direction of arrow 195. Conversely, the right side of the figure illustrates bottom actuator 180 in a passive state and top actuator 180′ in an active state in which sensor plate 174 is caused to move away from LCD 172 in the direction of arrow 195′.

FIG. 25D illustrates another two phase touch sensor device 210 but with a pair of thickness mode strip actuators 180 oriented with the electrodes orthogonal to the touch sensor plate. Here, the two phase or bi-directional movement of touch plate 174 is in-plane as indicated by arrow 205. To enable such in-plane motion, the actuator 180 is positioned such that the plane of its EAP film is orthogonal to those of LCD 172 and touch plate 174. To maintain such a position, actuator 180 is held between the sidewall 202 of frame 178 and an inner frame member 206 upon which rests touch plate 174. While inner frame member 206 is affixed to the output block 188a of actuator 180, it and touch plate 174 are “floating” relative to outer frame 178 to allow for the in-plane or lateral motion. This construct provides a relatively compact, low-profile design as it eliminates the added clearance that would otherwise be necessary for two-phase out-of-plane motion by touch plate 174. The two actuators work in opposition for two-phase motion. The combined assembly of plate 174 and brackets 206 keep the actuator strips 180 in slight compression against the sidewall 202 of frame 178. When one actuator is active, it compresses or thins further while the other actuator expands due to the stored compressive force. This moves the plate assembly toward the active actuator. The plate moves in the opposite direction by deactivating the first actuator and activating the second actuator.

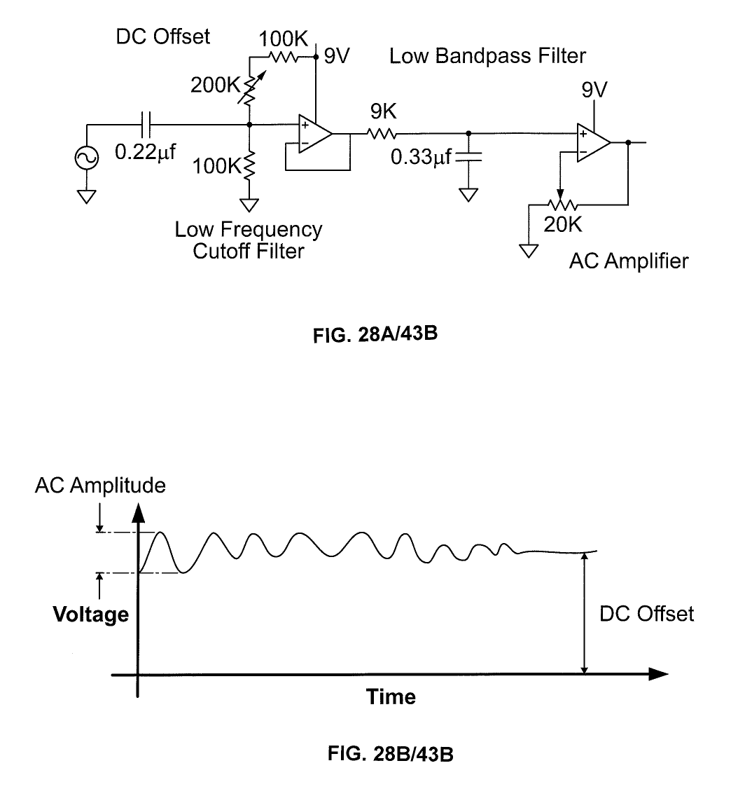

FIGS. 26A and 26B illustrate variation in which an inactive area of a transducer is positioned internally or centrally to the active region(s), i.e., the central portion of the EAP film is devoid of overlapping electrodes. Thickness mode actuator 360 includes EAP transducer film comprising dielectric layer 362 sandwiched between electrode layers 364a, 354b in which a central portion 365 of the film is passive and devoid of electrode material. The EAP film is held in a taut or stretched condition by at least one of top and bottom frame members 366a, 366b, collectively providing a cartridge configuration. Covering at least one of the top and bottom sides of the passive portion 365 of the film are passive layers 368a, 368b with optional rigid constraints or output members 370a, 370b mounted thereon, respectively. With the EAP film constrained at its perimeter by cartridge frame 366, when activated (see FIG. 26B), the compression of the EAP film causes the film material to retract inward, as shown by arrows 367a, 367b, rather than outward as with the above-described actuator embodiments. The compressed EAP film impinges on the passive material 368a, 368b causing its diameter to decrease and its height to increase. This change in configuration applies outward forces on output members 370a, 370b, respectively. As with the previously described actuator embodiments, the passively coupled film actuators may be provided in multiples in stacked or planar relationships to provide multi-phase actuation and/or to increase the output force and/or stroke of the actuator.

Performance may be enhanced by prestraining the dielectric film and/or the passive material. The actuator may be used as a key or button device and may be stacked or integrated with sensor devices such as membrane switches. The bottom output member or bottom electrode can be used to provide sufficient pressure to a membrane switch to complete the circuit or can complete the circuit directly if the bottom output member has a conductive layer. Multiple actuators can be used in arrays for applications such as keypads or keyboards.

The various dielectric elastomer and electrode materials disclosed in U.S. Patent Application Publication No. 2005/0157893 are suitable for use with the thickness mode transducers of the present invention. Generally, the dielectric elastomers include any substantially insulating, compliant polymer, such as silicone rubber and acrylic, that deforms in response to an electrostatic force or whose deformation results in a change in electric field. In designing or choosing an appropriate polymer, one may consider the optimal material, physical, and chemical properties. Such properties can be tailored by judicious selection of monomer (including any side chains), additives, degree of cross-linking, crystallinity, molecular weight, etc.

Electrodes described therein and suitable for use include structured electrodes comprising metal traces and charge distribution layers, textured electrodes, conductive greases such as carbon greases or silver greases, colloidal suspensions, high aspect ratio conductive materials such as conductive carbon black, carbon fibrils, carbon nanotubes, graphene and metal nanowires, and mixtures of ionically conductive materials. The electrodes may be made of a compliant material such as elastomer matrix containing carbon or other conductive particles. The present invention may also employ metal and semi inflexible electrodes.

Exemplary passive layer materials for use in the subject transducers include but are not limited to silicone, styrenic or olefinic copolymer, polyurethane, acrylate, rubber, a soft polymer, a soft elastomer (gel), soft polymer foam, or a polymer/gel hybrid, for example. The relative elasticity and thickness of the passive layer(s) and dielectric layer are selected to achieve a desired output (e.g., the net thickness or thinness of the intended surface features), where that output response may be designed to be linear (e.g., the passive layer thickness is amplified proportionally to the that of the dielectric layer when activated) or non-linear (e.g., the passive and dielectric layers get thinner or thicker at varying rates).

Regarding methodology, the subject methods may include each of the mechanical and/or activities associated with use of the devices described. As such, methodology implicit to the use of the devices described forms part of the invention. Other methods may focus on fabrication of such devices.

As for other details of the present invention, materials and alternate related configurations may be employed as within the level of those with Skill in the relevant art. The same may hold true with respect to method-based aspects of the invention in terms of additional acts as commonly or logically employed. In addition, though the invention has been described in reference to several examples, optionally incorporating various features, the invention is not to be limited to that which is described or indicated as contemplated with respect to each variation of the invention. Various changes may be made to the invention described and equivalents (whether recited herein or not included fhr the sake of some brevity) may be substituted without departing from the true spirit and scope of the invention. Any number of the individual parts or subassemblies shown may be integrated in their design. Such changes or others may be undertaken or guided by the principles of design for assembly.

In another variation, the cartridge assembly or actuator 360 can be suited for use in providing a haptic response in a vibrating button, key, touchpad, mouse, or other interface. In such an example, coupling of the actuator 360 employs a noncompressible output geometry. This variation provides an alternative from a bonded center constraint of an electroactive polymer diaphragm cartridge by using a non-compressible material molded into the output geometry.

In an electroactive polymer actuator with no center disc, actuation changes the condition of the Passive Film in the center of the electrode geometry, decreasing both the stress and the strain (force and displacement). This decrease occurs in all directions in the plane of the film, not just a single direction. Upon the discharge of the electroactive polymer, the Passive film then returns to an original stress and strain energy state. An electroactive polymer actuator can be constructed with a non-compressible material (one that has a substantially constant volume under stress). The actuator 360 is assembled with a non compressible output pad 368a 368b bonded to the passive film area at the center of the actuator 360 in the inactive region 365, replacing the center disk. This configuration can be used to transfer energy by compressing the output pad at its interface with the passive portion 365. This swells the output pad 368a and 368b to create actuation in the direction orthogonal to the flat film. The non compressible geometry can be further enhanced by adding constraints to various surfaces to control the orientation of its change during actuation. For the above example, adding a non-compliant stiffener to constrain the top surface of the output pad prevents that surface from changing its dimension, focusing the geometry change to desired dimensions of the output pad.

The variation described above can also allow coupling of biaxial stress and strain state changes of electroactive polymer Dielectric Elastomer upon actuation; transfers actuation orthogonal to direction of actuation; design of non compressible geometry to optimize performance. The variations described above can include various transducer platforms, including: diaphragm, planar, inertial 10 drive, thickness mode, hybrid (combination of planar & thickness mode described in the attached disclosure), and even roll—for any haptic feedback (mice, controllers, screens, pads, buttons, keyboards, etc.) These variations might move a specific portion of the user contact surface, e.g. a touch screen, keypad, button or key cap, or move the entire device.

Different device implementations may require different EAP platforms. For example, in one example, strips of thickness mode actuators might provide out-of-plane motion for touch screens, hybrid or planar actuators to provide key click sensations for buttons on keyboards, or inertial drive designs to provide rumbler feedback in mice and controllers.

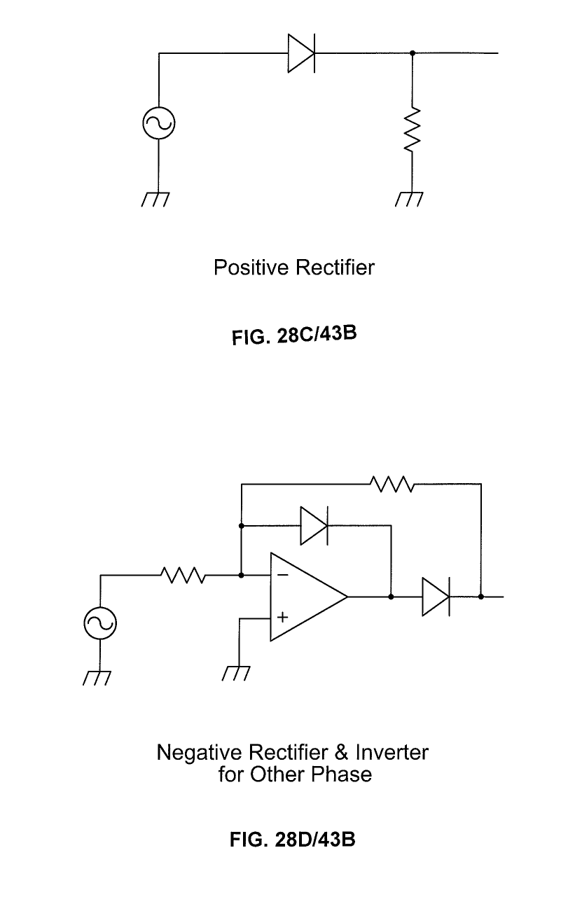

FIG. 27A illustrates another variation of a transducer for providing haptic feedback with various user interface devices. In this variation, a mass or weight 262 is coupled to an electroactive polymer actuator 30. Although the illustrated polymer actuator comprises a film cartridge actuator, alternative variations of the device can employ a spring biased actuator as described in the EAP patents and applications disclosed above.

FIG. 27B illustrates an exploded view of the transducer assembly of FIG. 27A. As illustrated the inertial transducer assembly 260 includes a mass 262 sandwiched between two actuators 30. However, variations of the device include one or more actuators depending upon the intended application on either side of the mass. As illustrated, the actuator(s) is/are coupled to the inertial mass 262 and secured via a base-plate or flange. Actuation of the actuators 30 causes movement of the mass in an x-y orientation relative to the actuator. In additional variations, the actuators can be configured to provide a normal or z axis movement of the mass 262.

FIG. 27C illustrates a side view of the inertial transducer assembly 260 of FIG. 27A. In this illustration, the assembly is shown with a center housing 266 and a top housing 268 that enclose the actuators 30 and inertial mass 262. Also, the assembly 260 is shown with fixation means or fasteners 270 extending through openings or vias 24 within the housing and actuators. The vias 24 can serve multiple functions. For example, the vias can be for mounting purposes only. Alternatively, or in combination, the vias can electrically couple the actuator to a circuit board, flex circuit or mechanical ground. FIG. 27D illustrates a perspective view of the inertial transducer assembly 260 of FIG. 27C where the inertial mass (not shown) is located within a housing assembly 264, 266, and 268). The parts of the housing assembly can serve multiple functions. For example, in addition to providing mechanical support and mounting and attachment features, they can incorporate features that serve as mechanical hard stops to prevent excessive motion of the inertial mass in x, y, and/or z directions which could damage the actuator cartridges. For example, the housing can include raised surfaces to limit excessive movement of the inertial mass. In the illustrated example, the raised surfaces can comprise the portion of the housing that contains the vias 24. Alternatively, the vias 24 can be placed selectively so that any fastener 270 located therethrough functions as an effective stop to limit movement of the inertial mass.

Housing assemblies can 264 and 266 can also be designed with integrated lips or extensions that cover the edges of the actuators to prevent electrical shock on handling. Any and all of these parts can also be integrated as part of the housing of a larger assembly such as the housing of a consumer electronic device. For example, although the illustrated housing is shown as a separate component that is to be secured within a user interface device, alternate variations of the transducer include housing assemblies that are integral or part of the housing of the actual user interface device. For instance, a body of a computer mouse can be configured to serve as the housing for the inertial transducer assembly.

The inertial mass 262 can also serve multiple functions. While it is shown as circular in FIGS. 27A and 27B to, variations of the inertial mass can be fabricated to have a more complex shape such that it has integrated features that serve as mechanical hard stops that limit its motion in x, y, and/or z directions. For example. FIG. 27E illustrates a variation of an inertial transducer assembly with an inertial mass 262 having a shaped surface 263 that engage a stop or other feature of the housing 264. In the illustrated variation, the surface 263 of the inertial mass 262 engages fasteners 270. Accordingly, the displacement of the inertial mass 262 is limited to the gap between the Shaped surface 263 and the stop or fastener 270. The mass of the weight can be chosen to tailor the resonant frequency of the total assembly, and the material of construction can be any dense material but is preferably chosen to minimize the required volume and cost. Suitable materials include metals and metal alloys such as copper, steel, tungsten, aluminum, nickel, chrome and brass, and polymer/metal composites materials, resins, fluids, gels, or other materials can be used.

Filter Sound Drive Waveform for Electroactive Polymer Haptics

Another variation of the inventive methods and devices described herein involves driving the actuators in a manner to improve feedback. In one such example the haptic actuator is driven by a sound signal. Such a configuration eliminates the need for a separate processor to generate waveforms to produce different types of haptic sensations. Instead, haptic devices can employ one or more circuits to modify an existing audio signal into a modified haptic signal, e.g. filtering or amplifying different portions of the frequency spectrum. Therefore, the modified haptic signal then drives the actuator. In one example, the modified haptic signal drives the power supply to trigger the actuator to achieve different sensory effects. This approach has the advantages of being automatically correlated with and synchronized to any audio signal which can reinforce the feedback from the music or sound effects in a haptic device such as a gaming controller or handheld gaming console.

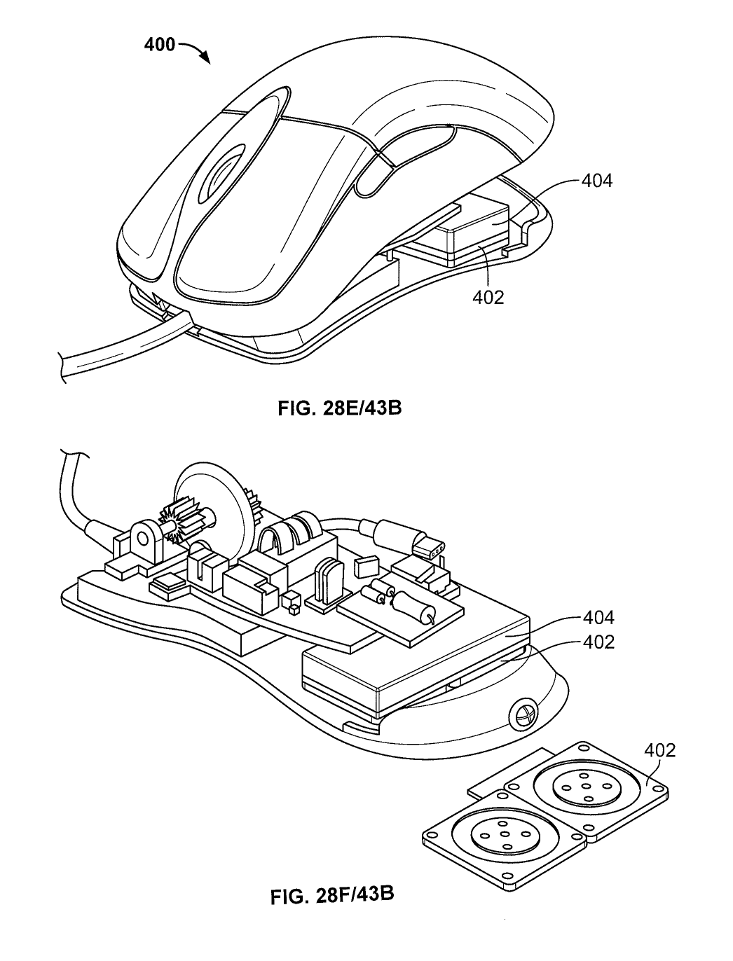

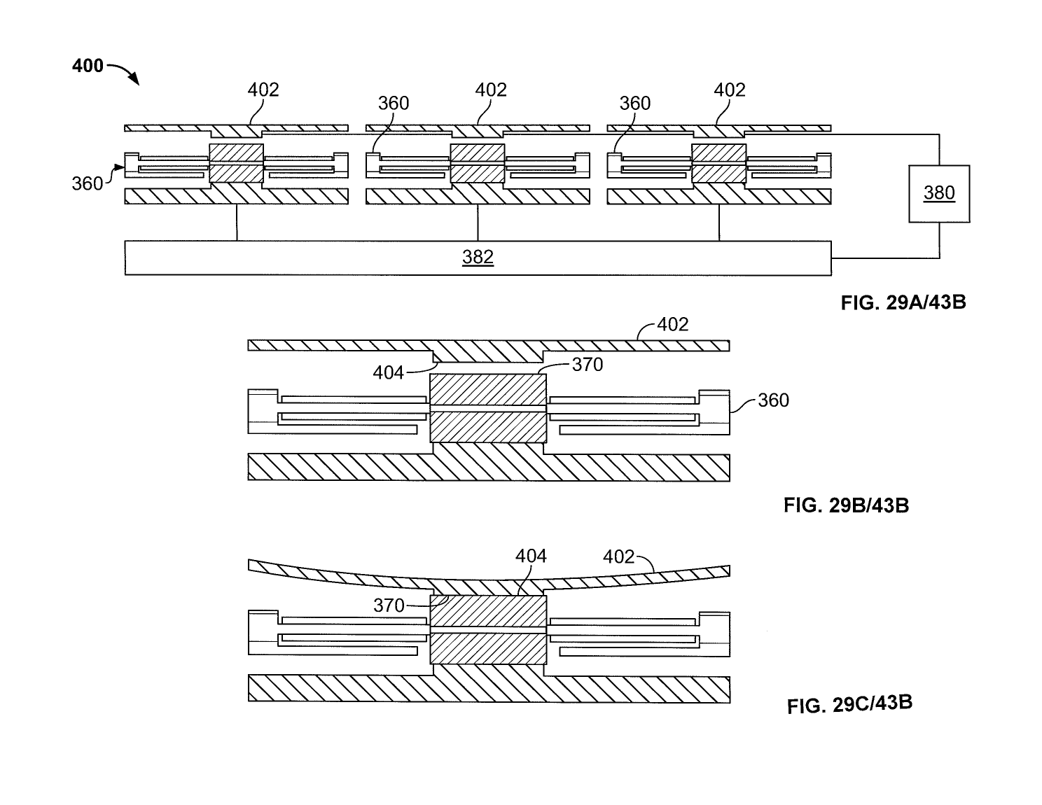

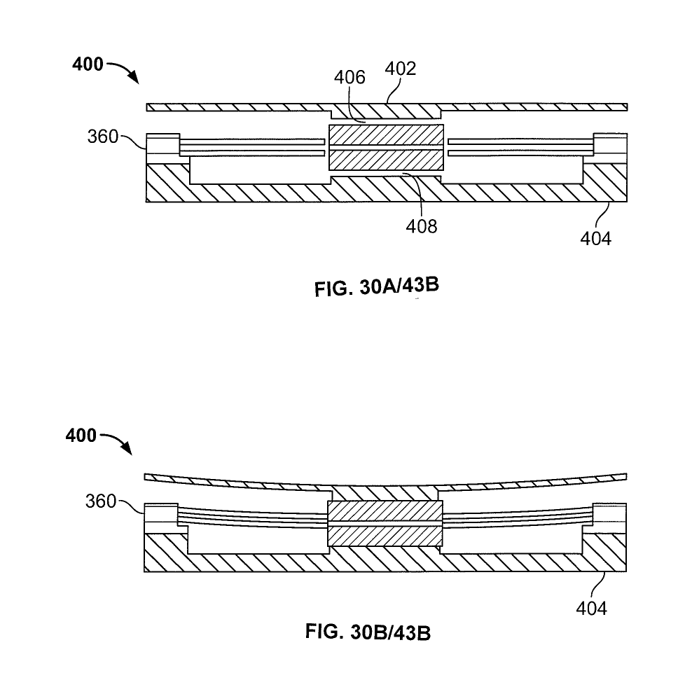

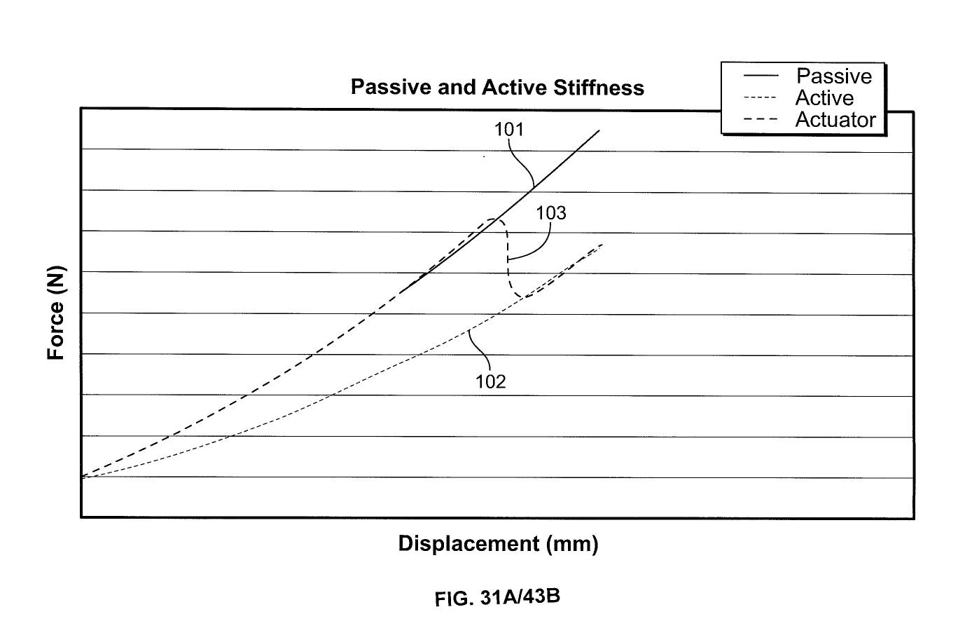

FIG. 28A illustrates one example of a circuit to tune an audio signal to work within optimal haptic frequencies for electroactive polymer actuators. The illustrated circuit modifies the audio signal by amplitude cutoff, DC offset adjustment, and AC waveform peak-to-peak magnitude adjustment to produce a signal similar to that shown in FIG. 28B. In certain variations, the electroactive polymer actuator comprises a two phase electroactive polymer actuator and where altering the audio signal comprises filtering a positive portion of an audio waveform of the audio signal to drive a first phase of the electroactive polymer transducer, and inverting a negative portion of the audio waveform of the audio signal to drive a second phase of the electroactive polymer transducer to improve performance of the electroactive polymer transducer. For example, a source audio signal in the form of a sine wave can be converted to a square wave (e.g., via clipping), so that the haptic signal is a square wave that produces maximum actuator force output.

In another example, the circuit can include one or more rectifiers to filter the frequency of an audio signal to use all or a portion of an audio waveform of the audio signal to drive the haptic effect. FIG. 28C illustrates one variation of a circuit designed to filter a positive portion of an audio waveform of an audio signal. This circuit can be combined, in another variation, with the circuit shown in FIG. 28D for actuators having two phases. As shown, the circuit of FIG. 28C can filter positive portions of an audio waveform to drive one phase of the actuator while the circuit shown in FIG. 28D can invert a negative portion of an audio waveform to drive the other phase of the two-phase haptic actuator. The result is that the two phase actuator will have a greater actuator performance.

In another implementation, a threshold in the audio signal can be used to trigger the operation of a secondary circuit which drives the actuator. The threshold can be defined by the amplitude, the frequency, or a particular pattern in the audio signal. The secondary circuit can have a fixed response such as an oscillator circuit set to output a particular frequency or can have multiple responses based on multiple defined triggers. In some variations, the responses can be pre-determined based upon a particular trigger. In such a case, stored response signals can be provided in upon a particular trigger. In this manner, instead of modifying the source signal, the circuit triggers a pre-determined response depending upon one or more characteristics of the source signal. The secondary circuit can also include a timer to output a response of limited duration.

Many systems could benefit from the implementation of haptics with capabilities for sound, (e.g. computers, Smartphones, PDAs, electronic games) In this variation, filtered sound serves as the driving waveform for electroactive polymer haptics. The sound files normally used in these systems can be filtered to include only the optimal frequency ranges for the haptic feedback actuator designs. FIGS. 28E and 28F illustrate one such example of a device 400, in this case a computer mouse, having one or more electroactive polymer actuators 402 within the mouse body 400 and coupled to an inertial mass 404.

Current systems operate at optimal frequencies of <200 Hz. A sound waveform, such as the sound of a shotgun blast, or the sound of a door closing, can be low pass filtered to allow only the frequencies from these sounds that are <200 Hz to be used. This filtered waveform is then supplied as the input waveform to the EPAM power supply that drives the haptic feedback actuator. If these examples were used in a gaming controller, the sound of the shotgun blast and the closing door would be simultaneous to the haptic feedback actuator, supplying an enriched experience to the game player.

In one variation use of an existing sound signal can allow for a method of producing a haptic effect in a user interface device simultaneously with the sound generated by the separately generated audio signal. For example, the method can include routing the audio signal to a filtering circuit; altering the audio signal to produce a haptic drive signal by filtering a range of frequencies below a predetermined frequency; and providing the haptic drive signal to a power supply coupled to an electroactive polymer transducer such that the power supply actuates the electroactive polymer transducer to drive the haptic effect simultaneously to the sound generated by the audio signal.

The method can further include driving the electroactive polymer transducer to simultaneously generate both a sound effect and a haptic response.

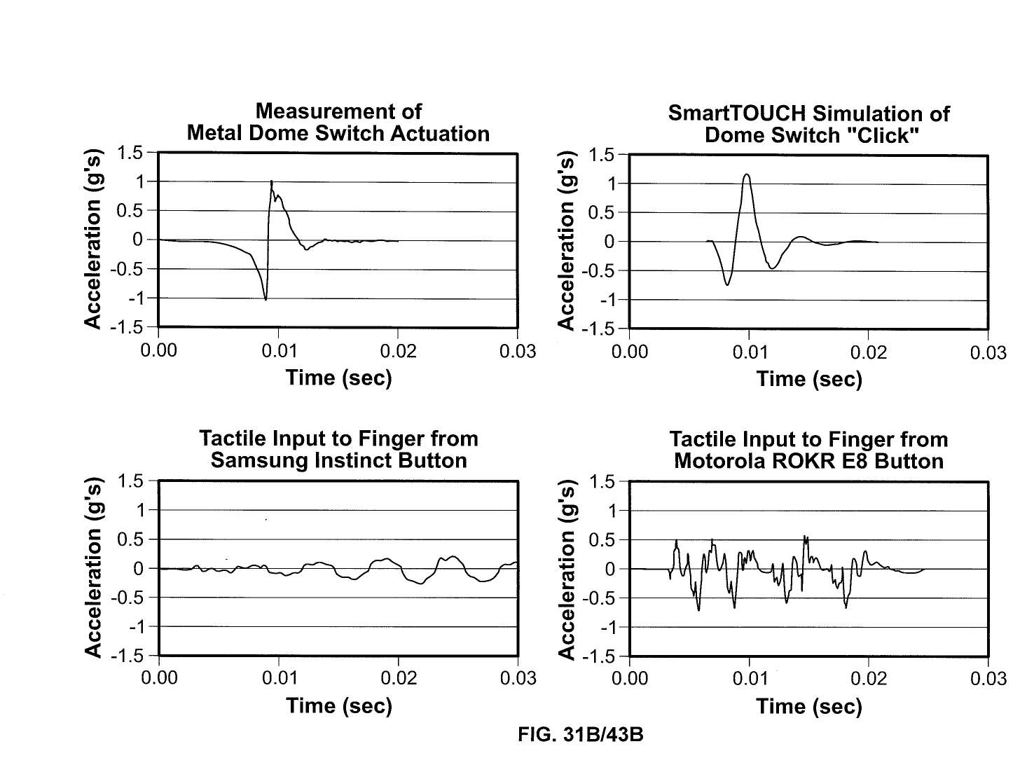

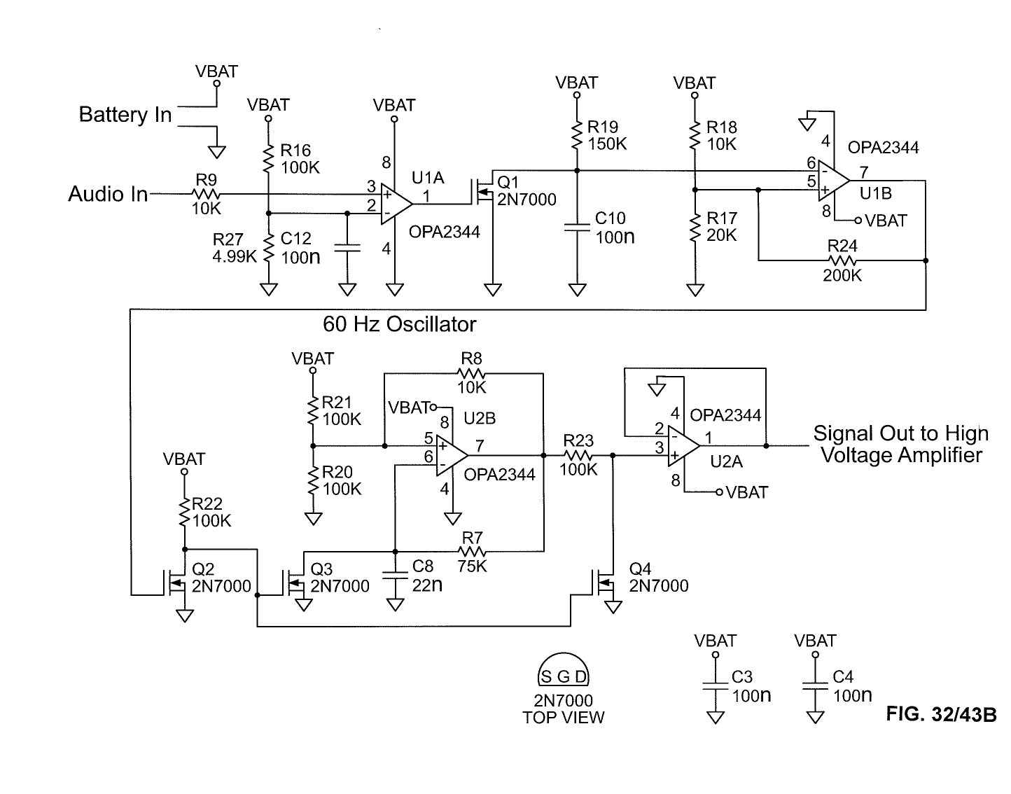

FIGS. 29A to 30B illustrate another variation of driving one or more transducers by using a structure of the transducer to power the transducer so that in a normal (preactivated) state, the transducers remain unpowered. The description below can be incorporated into any design described herein. The devices and methods for driving the transducers are especially useful when attempting to reduce a profile of the body or chassis of a user interface device.

In a first example, a user interface device 400 includes one or more electroactive polymer transducers or actuators 310 that can be driven to produce a haptic effect at a user interface surface 402 without requiring complex switching mechanisms. Instead, the multiple transducers 360 are powered by one or more power supplies 380. In the illustrated example, the transducers 360 are thickness mode transducers as described above as well as in the applications previously incorporated by reference. However, the concepts presented for this variation can be applied to a number of different transducer designs.

As shown, the actuators 360 can be stacked in a layer including an open circuit comprising high voltage power supply 380 with one or more ground bus lines 382 serving as a connection to each transducer 360. However, the device 400 is configured so that in a standby state, each actuator 360 remains unpowered because the circuit forming the power supply 380 remain as open.

FIG. 29B shows a single user interface surface 420 with a transducer 360 as shown in FIG. 29A. In order to complete the complete the connection between the bus lines 382 and power supply 380, the user interface surface 402 includes one or more conductive surfaces 404. In this variation, the conductive surface 404 comprises a bottom surface of the user interface 402. The transducer 360 will also include an electrically conductive surface on an output member 370 or other portion of the transducer 360.

In order to actuate the transducer 360, as shown in FIG. 29C, when the user interface surface 402 is deflected into the transducer 360 the two conductive portions are electrically coupled to close the circuit. This action completes the circuit of the power supply 380. In addition, depressing the user interface surface 402 not only closes the gap with the transducer 360, it also can be used to close a switch with device 400 so that the device 400 recognizes that the surface 402 is actuated.

One benefit to this configuration is that not all of the transducers 360 are powered. Instead, only those transducers in which the respective user interface surface completed the circuit are powered. This configuration minimizes power consumption and can eliminate cross-talk between the actuators 360 in an array. This construction allows for extremely thin keypads and keyboards as it eliminates the need for a metallic or elastic dome type switch that is commonly used for such devices.

FIGS. 30A and 30B illustrate another variation of a user interface device 400 having an electroactive polymer transducer 360 configured as an embedded switch. In the variation shown in FIG. 30A, there is first gap 406 between transducer 360 and the user interface surface 402 and a second gap 408 between the transducer 360 and the chassis 404. In this variation, depressing the user interface surface 402, as shown in FIG. 30B, closes a first switch or establishes a closed circuit between the user interface surface 402 and the transducer 360. Closing of this circuit allows routing of power to the electroactive polymer transducer 360 from a high voltage power supply (not shown in FIG. 30A). Continued depression of the user interface surface 402 drives the transducer 360 into contact with an additional switch located on a chassis 404 of the device 401). The latter connection enables input to the device 400 enabling a high voltage power supply to actuate the transducer 360 to produce a haptic sensation or tactile feedback at the user interface surface 402. Upon release the connection between the transducer 350 and chassis 404 opens (establishing gap 408). This action cuts off the signal to the device 400 effectively turning off the high voltage power supply and prevents the actuator from producing any haptic effect. Continued release of the user interface surface 402 separates the user interface surface 402 from the transducer 360 to establish gap 406. The opening of this latter switch effectively disconnects the transducer 360 from the power supply.

In the variations described above, the user interface surface can comprise one or more keys of a keyboard (e.g., a QWERTY keyboard, or other type of input keyboard or pad). Actuation of the EPAM provides button click tactile feedback, which replaces the key depression of current dome keys. However, the configuration can be employed in any user interface device, including but not limited to: a keyboard, a touch screen, a computer mouse, a trackball, a stylus, a control panel, or any other device that would benefit from a haptic feedback sensation.

In another variation of the configuration described above, the closing of one or more gaps could close an open low-voltage circuit. The low-voltage circuit would then trigger a switch to provide power to the high voltage circuit. In this way, high voltage power is provided across the high voltage circuit and to the transducer only when the transducer is used to complete the circuit. So long as the low voltage circuit remains open, the high voltage power supply remains uncoupled and the transducers remain unpowered.

The use of the cartridges can allow for imbedding electrical switches into the overall design of the user interface surface and can eliminate the need to use traditional dome switches to activate the input signal for the interface device (i.e., so the device recognizes the input of the key), as well as activate the haptic signals for the keys (i.e., to generate a haptic sensation associated with selection of the key). Any number of switches can be closed with each key depression where such a configuration is customizable within the constraints of the design.

The imbedded actuator switches can route each haptic event by configuring the key so that each depression completes a circuit with a power supply that powers the actuator. This configuration simplifies the electronics requirements for the keyboard. The high voltage power required to drive the haptics for each key can be supplied by a single high voltage power supply for the entire keyboard. However, any number of power supplies can be incorporated into the design.

The EPAM cartridges that can be used with these designs includes Planar. Diaphragm, Thickness Mode, and Passive Coupled devices (Hybrids)

In another variation, the embedded switch design also allows for mimicking of a bi-stable switch such as a traditional dome type switch (e.g., a rubber dome or metal flexure switch). In one variation, the user interface surface deflects the electroactive polymer transducer as described above. However, the activation of the electroactive polymer transducer is delayed. Therefore, continued deflection of the electroactive polymer transducer increases a resistance force that is felt by the user at the user interface surface. The resistance is caused by deformation of the electroactive polymer film within the transducer. Then, either after a pre-determined deflection or duration of time after the transducer is deflected, the electroactive polymer transducer is activated such that the resistance felt by the user at the user interface surface is varied (typically reduced). However, the displacement of the user interface surface can continue. Such a delay in activation of the electroactive polymer transducer mimics the bistable performance traditional dome or flexure switches.

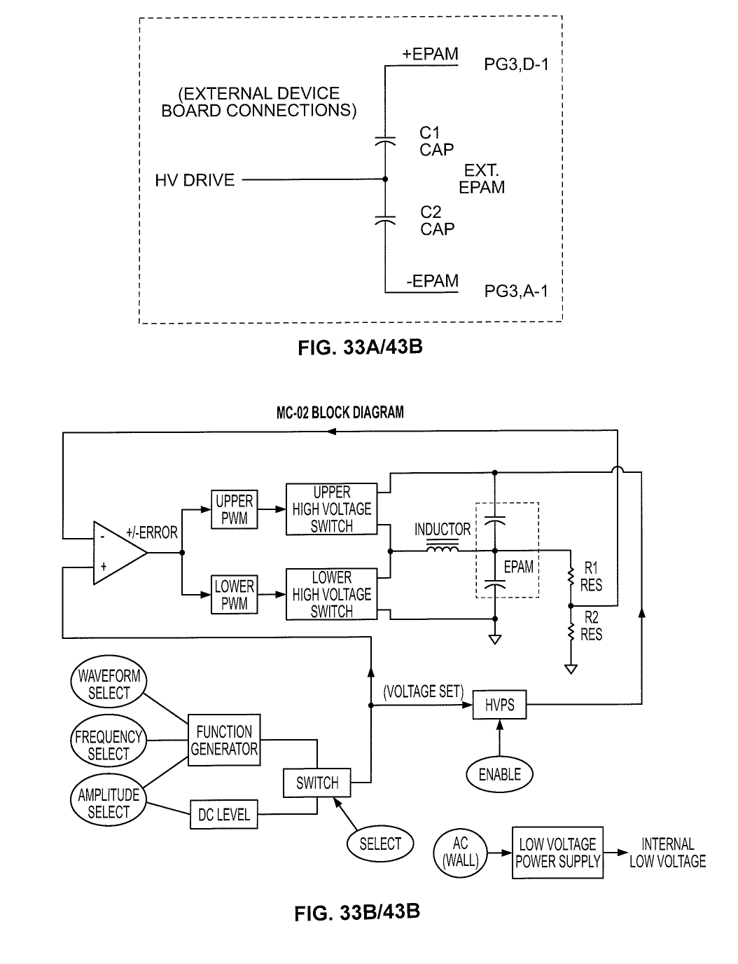

FIG. 31A illustrates a graph of delaying activation of an electroactive polymer transducer to produce the bi-stable effect. As illustrated, line 101 shows the passive stiffness curve of the electroactive polymer transducer as it is deflected but where activation of the transducer is delayed. Line 102 shows the active stiffness curve of the electroactive polymer transducer once activated. Line 103 shows the force profile of the electroactive polymer transducer as it moves along the passive stiffness curve, then when actuated, the stiffness drops to the active stiffness curve 102. In one example, the electroactive polymer transducer is activated somewhere at the middle of the stroke.

The profile of line 103 is very close to a similar profile tracking stiffness of a rubber dome or metal flexure bi-stable mechanism. As shown, EAP actuators are suitable to simulate the force profile of the rubber dome. The difference between passive and active curve will be the main contributor to the feeling, meaning the higher the gap, the higher the chance and the more powerful sensation would be.

The shape of the curve and mechanism to achieve a desired curve or response can be independent of the actuator type. Additionally, the activation response of any type of actuator (e.g., diaphragm actuator, thickness mode, hybrid, etc.) can be delayed to provide the desired haptic effect. In such a case, the electroactive polymer transducer functions as a variable spring that changes the output reactive force by applying voltage. FIG. 31B illustrates additional graphs based on variations of the above described actuator using delays in activating the electroactive polymer transducer.

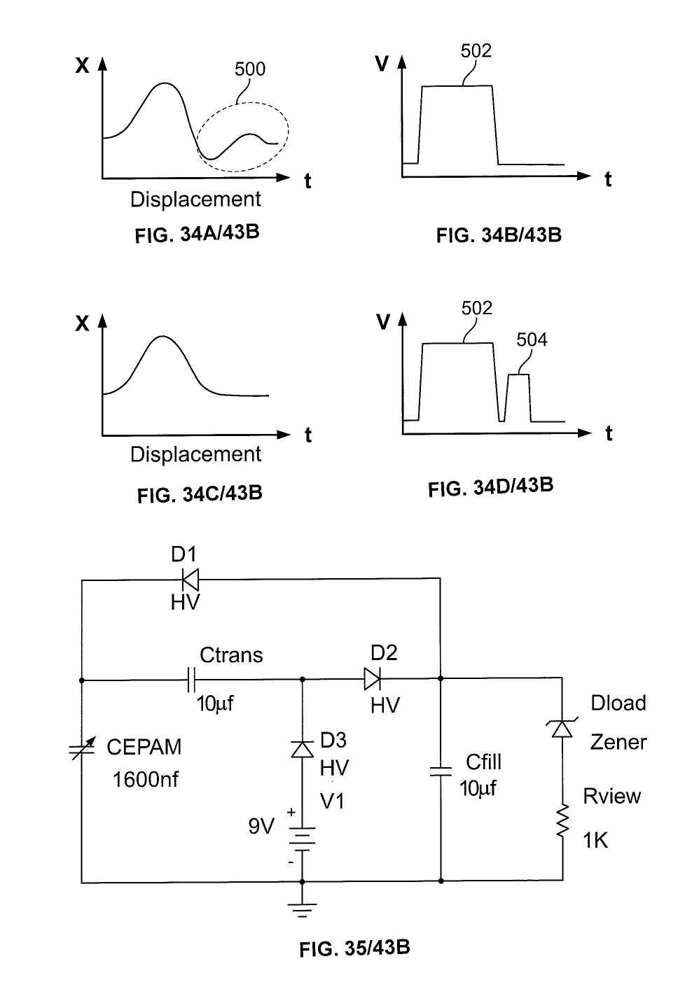

Another variation for driving an electroactive polymer transducer includes the use of stored wave form given a threshold input signal. The input signal can include an audio or other triggering signal. For example, the circuit shown in FIG. 32 illustrates an audio signal serving as a trigger for a stored waveform. Again, the system can use a triggering or other signal in place of the audio signal. This method drives the electroactive polymer transducer with one or more pre-determined waveforms rather than using simply driving the actuator directly from the audio signal. One benefit of this mode of driving the actuator is that the use of stored waveforms enables the generation of complex waveforms and actuator performance with minimal memory and complexity. Actuator performance can be enhanced by using a drive pulse optimized for the actuator (e.g. running at a preferred voltage or pulse width or at resonance) rather than using the analog audio signal. The actuator response can be synchronous with the input signal or can be delayed. In one example, a 0.25 v trigger threshold can be used as the trigger. This low-level signal can then generate one or more pulse waveforms. In another variation, this driving technique can potentially allow the use of the same input or triggering signal to have different output signals based on any number of conditions (e.g., such as the position of the user interface device, the state of the user interface device, a program being run on the device, etc.).

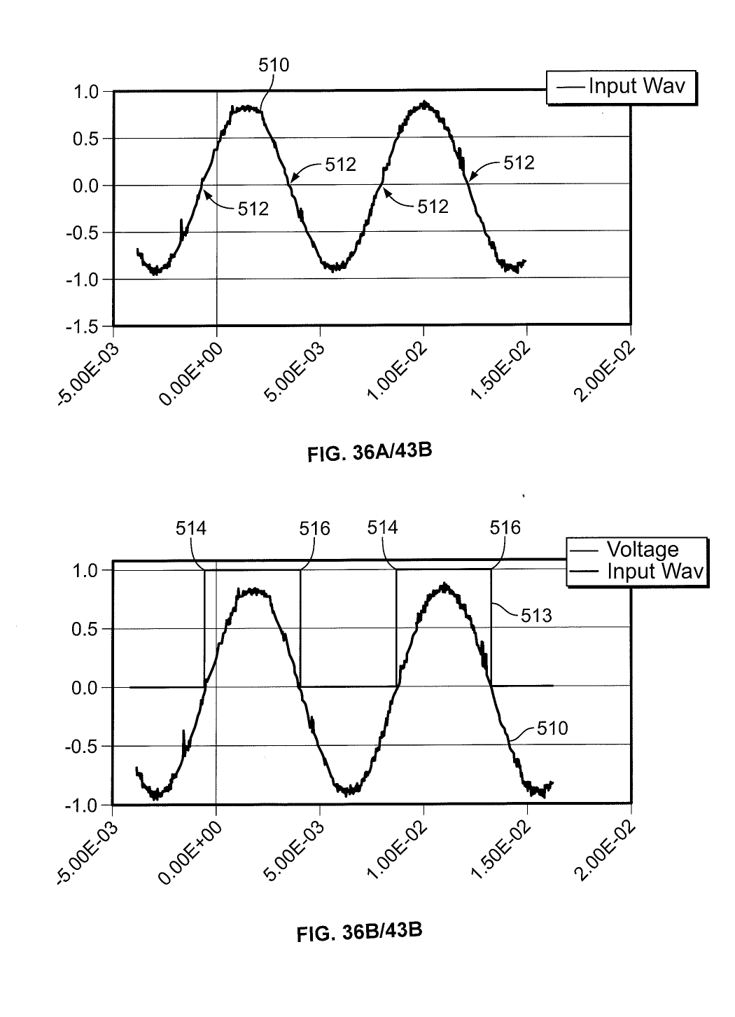

FIGS. 33A and 33B illustrate yet another variation for driving an electroactive polymer transducer by providing two-phase activation with a single drive circuit. As shown, of the three power leads in a two-phase transducer, one lead on one of the phases is held constant at high voltage, one lead on the other phase is grounded, and the third lead common to both phases is driven to vary in voltage from ground to high voltage. This enables the activation of one phase to occur simultaneously with the deactivation of the 2nd phase to enhance the snap-through performance of a two-phase actuator.

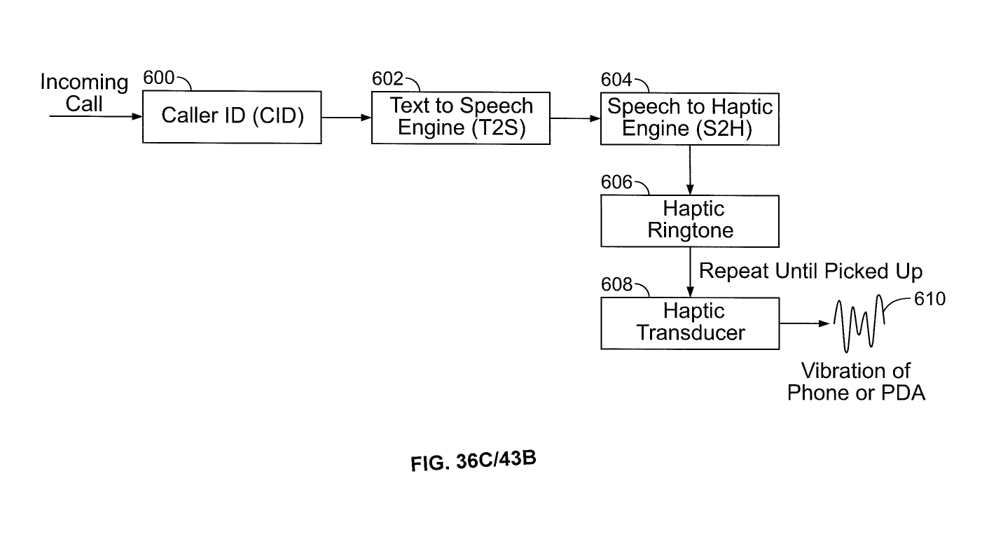

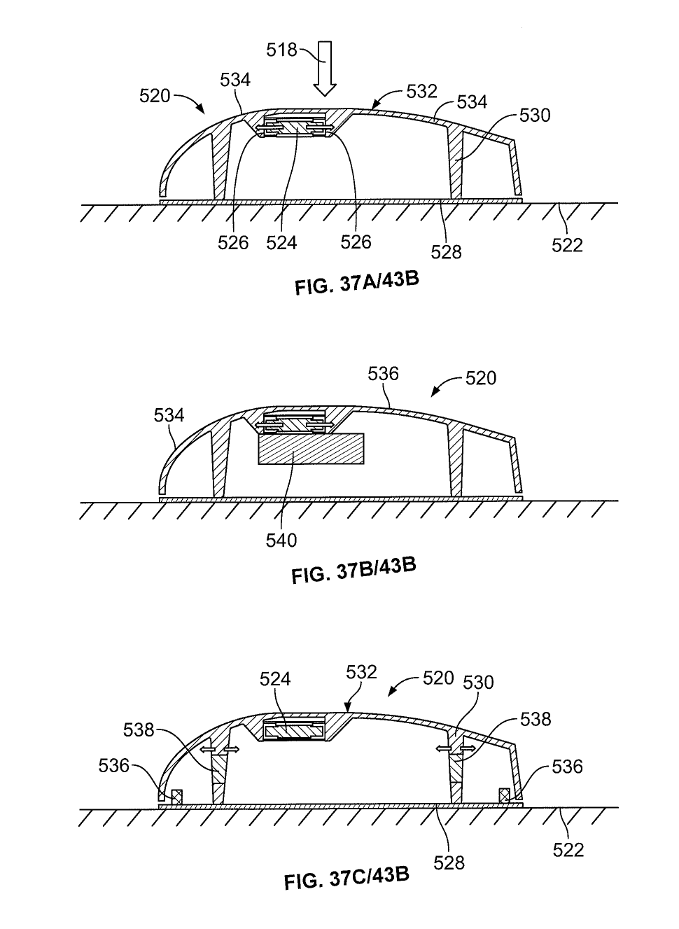

In another variation, a haptic effect on a user interface surface as described herein, can be improved by adjusting for the mechanical behavior of the user interface surface. For example, in those variations where an electroactive polymer transducer drives a touchscreen the haptic signal can eliminate undesired movement of the user interface surface after the haptic effect. When the device comprises a touch screen, typically movement of the screen (i.e., the user interface surface) occurs in a plane of the touchscreen or out-of-plan (e.g., a z-direction). In either case, the electroactive polymer transducer is driven by an impulse 502 to produce the haptic response as schematically illustrated in FIG. 34B. However, the resulting movement can be followed by a lagging mechanical ringing or oscillation 500 as shown in the graph of FIG. 34A illustrating a displacement of the user interface surface (e.g., the touchscreen). To improve the haptic effect, a method of driving the haptic effect can include the use of a complex waveform to provide electronic dampening to produce a realistic haptic effect. Such a waveform includes the haptic driving portion 502 as well as a dampening portion 504. In the case where the haptic effect comprises a “key-click” as described above, the electronic dampening waveform can eliminate or reduce the lagging effect to produce a more realistic sensation. For example, the displacement curves of FIGS. 34A and 34C illustrate displacement curves when trying to emulate a key click. However, any number of haptic sensations can be improved using electronic dampening of the sensation.

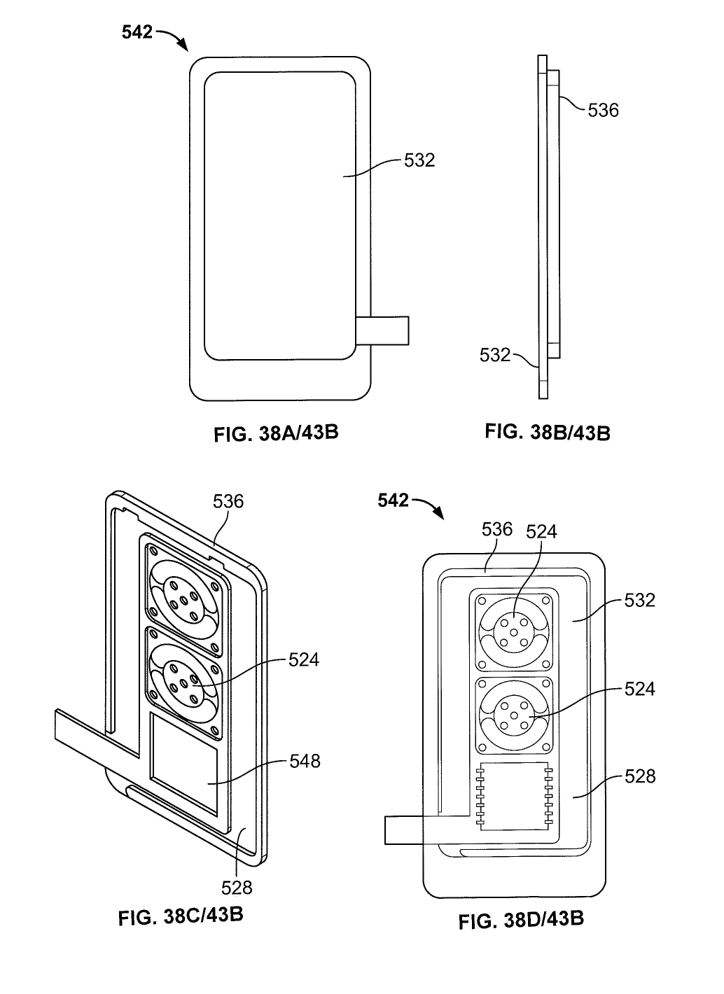

FIG. 35 illustrates an example of an energy generation circuit for powering an electroactive polymer transducer. Many electroactive polymer transducers require high voltage electronics to produce electricity. Simple, high-voltage electronics are needed that provide functionality and protection. A basic transducer circuit consists of a low voltage priming supply, a connection diode, an electroactive polymer transducer, a second connection diode and a high voltage collector supply. However, such a circuit may not be effective at capturing as much energy per cycle as desired and requires a relatively higher voltage priming supply.

FIG. 35 illustrates a simple power generation circuit design. One advantage of this circuit is in the simplicity of design. Only a small starting voltage (of approximately 9 volts) is necessary to get the generator going (assuming mechanical force is being applied). No control level electronics are necessary to control the transfer of high voltage into and out of the electroactive polymer transducer. A passive voltage regulation is achieved by zener diodes on the output of the circuit. This circuit is capable of producing high voltage DC power and can operate the electroactive polymer transducer at an energy density level around 0.04-0.06 joules per gram. This circuit is suitable for generating modest powers and demonstrating feasibility of electroactive polymer transducers. The illustrated circuit uses a charge transfer technique to maximize the energy transfer per mechanical cycle of an electroactive polymer transducer while still maintaining simplicity. Additional benefits include: allowing self priming with extremely low voltages (e.g., 9 volts); both variable frequency and variable stroke operation; maximizes energy transfer per cycle with simplified electronics (i.e. electronics that do not require control sequences); operates both in variable frequency and variable stroke applications; and provides over voltage protection to transducer.

### Drive Schemes

In one variation, the haptic response or effect can be tailored by the choice of the drive scheme, e.g. analog (as with the audio signal) or digital bursts or combinations of these.

In many cases, the system can limit power consumption using a circuit that cuts off or reduces voltage when the current draw is too high, e.g. at higher frequencies. In a first example, the 2nd stage cannot run unless the input stage of the converter is above a given voltage. When the 2nd stage initializes, the circuit causes the voltage on the first stage to drop and then drops out of the second stage if the input power is limited. At low frequencies, the haptic response follows the input signal. However, because high frequencies require more power, the response becomes clipped depending on the input power. Power consumption is one of the metrics needed to optimize the sub-assembly and drive design. Clipping the response in this manner conserves power.

In another variation, the drive scheme can employ amplitude modulation. For example, the actuator voltage can be driven at resonant frequency where the signal amplitude is scaled based on the input signal amplitude. This level is determined by the input signal, and the frequency is determined by the actuator design.

Filters or amplifiers can be used to enhance the frequencies in the input drive signal that leads to the highest performance of the actuators. This permits an increased sensitivity in the haptic response by the user and/or to accentuate the effect desired by the user. For example, the sub-assembly/system frequency response can be designed to match/overlap fast a fast Fourier transform taken of sound effects that are used as the drive input signal.

Another variation for producing a haptic effect involves the use of a roll-off filter. Such a filter allows attenuation of high frequencies that require a high power draw. To compensate for this attenuation, the sub-assembly can be designed to have its resonance at higher frequencies. The resonant frequency of the sub-assembly can be adjusted for example by changing the stiffness of the actuators (e.g. by changing the dielectric material, varying the thickness of the dielectric film, changing the type or thickness of the electrode material, changing the dimensions of the actuators), changing the number of cartridges in the actuator stack, changing the load or inertial mass on the actuators. Moving to thinner films or softer materials can move the cut-off frequency needed to meet a current/power limitation to higher frequencies. Clearly, adjustment of the resonance frequency can occur in any number of ways. The frequency response can also be tailored by using a mixture of actuator types.

Rather than using a simple follower circuit, a threshold can be used in the input drive signal to trigger a burst with an arbitrary waveform that requires less power. This waveform could be at a lower frequency and/or can be optimized with respect to the resonant frequency of the system—sub-assembly & housing—to enhance the response. In addition, the use of a delay time between triggers can also be used to control the power load.

### Zero-Crossing Power Control

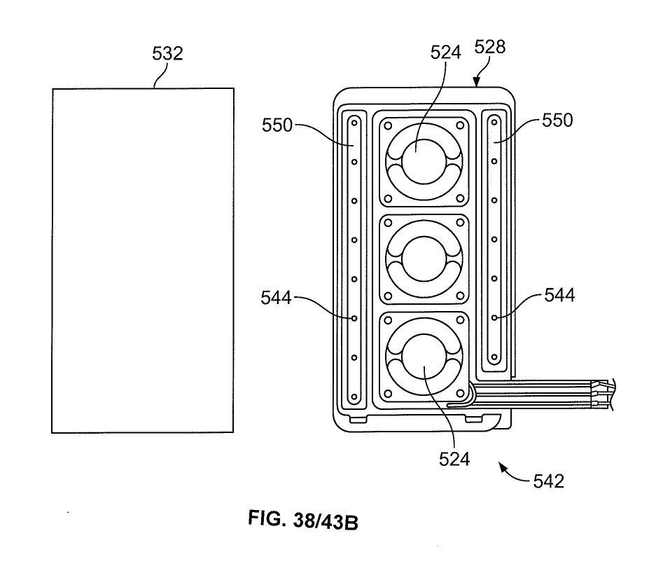

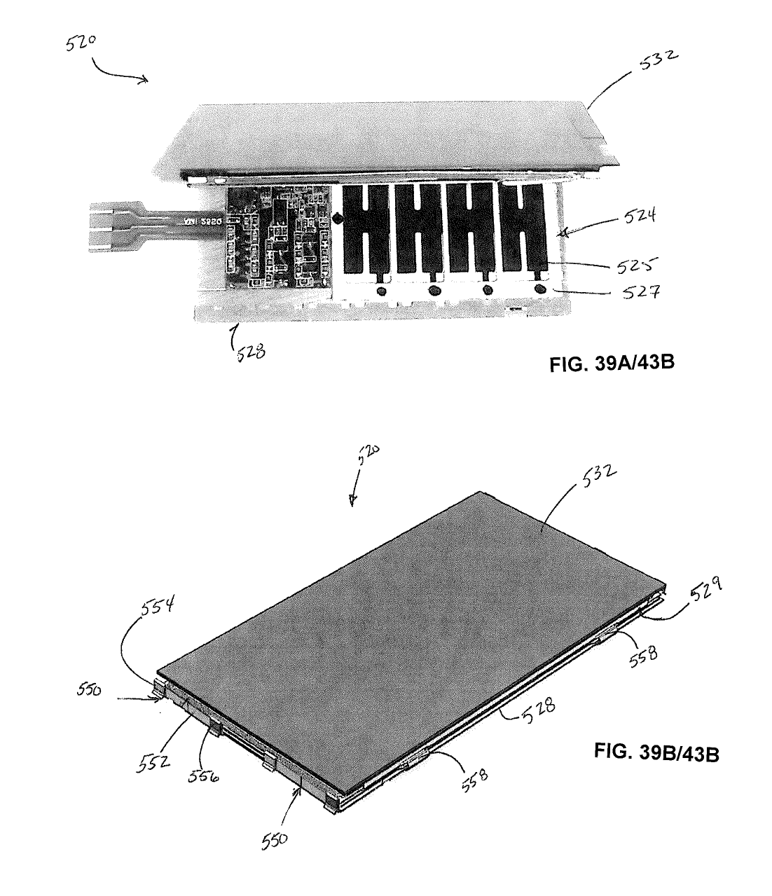

In another variation, a control circuit can monitor input audio waveforms and provide control for a high voltage circuit. In such a case, as shown in FIG. 36A, an audio waveform 510 is monitored for each transition through zero voltage value 512. With these zero crossings 512, a control circuit can indicate the crossing time value, and the voltage condition.

This control circuit changes high voltage based on zero crossing time and voltage swing direction. As shown in FIG. 36B, for zero crossing: positive swing, high voltage drive changes from zero volts to 1 kV (High Voltage Rail Value) at 514. For zero crossing: negative swing, high voltage drive changes from 1 kV to zero volts (Low Voltage Rail Value) at 516.

Such a control circuit allows actuation events to coincide with frequency of the audio signal 510. In addition, the control circuit can allow for filtering to eliminate higher frequency actuator events to maintain 40-200 Hz actuator response range. The square wave provides the highest actuation response for inertial drive designs and can be set by the limit of the power supply components. The charge up time can be adjusted to limit power supply requirements. To normalize actuation threes, the mechanical resonance frequency can be charged by a Triangle wave. While off resonant frequency actuations can be energized by a square wave.

FIG. 36C illustrates another variation of driving a haptic signal. In this example, haptic feedback can be converted from audio to tactile actuation. For example, a haptic signal 610 can be provided by automatically generating tactile ringtones 606 that uniquely identify callers based on caller ID 600 or other identifying data. In an additional variation, the process generates tactile ringtones 606 based on speech 602—so that little or no learning is required. For example, when a phone “says” “John Smith,” by buzzing at tactile frequencies “John Smith” (based on John's caller ID), the user can identify the caller based on the haptic ringtone.

In one variation, the haptic feedback is converted as follows: (Caller ID) 600->(Text to Speech) 602->(Audio to Tactile) 604, 606->(Output to tactile actuator) 608. For instance, when the device is a phone, the phone can ring or vibrate by providing a haptic vibration that identifies the callers name or other identification. A low frequency carrier (e.g. 100 Hz) can allow the device to distinguish a caller with a two syllable name from a multi-syllable name.

A simple speech-to-text transform involves: rectify and low-pass filter the speech signal at ˜10 Hz to get a loudness envelope L=f(t). This Loudness signal can be used to modulate the amplitude of a carrier vibration that is at a tactile frequency (e.g. around 100 Hz). This is basic amplitude modulation, and sufficient to distinguish the number of syllables in a caller's name, as well as which syllables are emphasized. Richer coding modulates both frequency and amplitude, and better exploits the fidelity of dielectric elastomer actuators. An infinite number of speech-to-text transforms are possible. Many would be suitable (e.g., AM, FM, Wavelet, Vocoder). Indeed, speech-to-text transforms designed to preserve speech information have already been developed for tactile aids that help deaf individuals read lips, for example the Tactaid and Tactilator.

### Housing

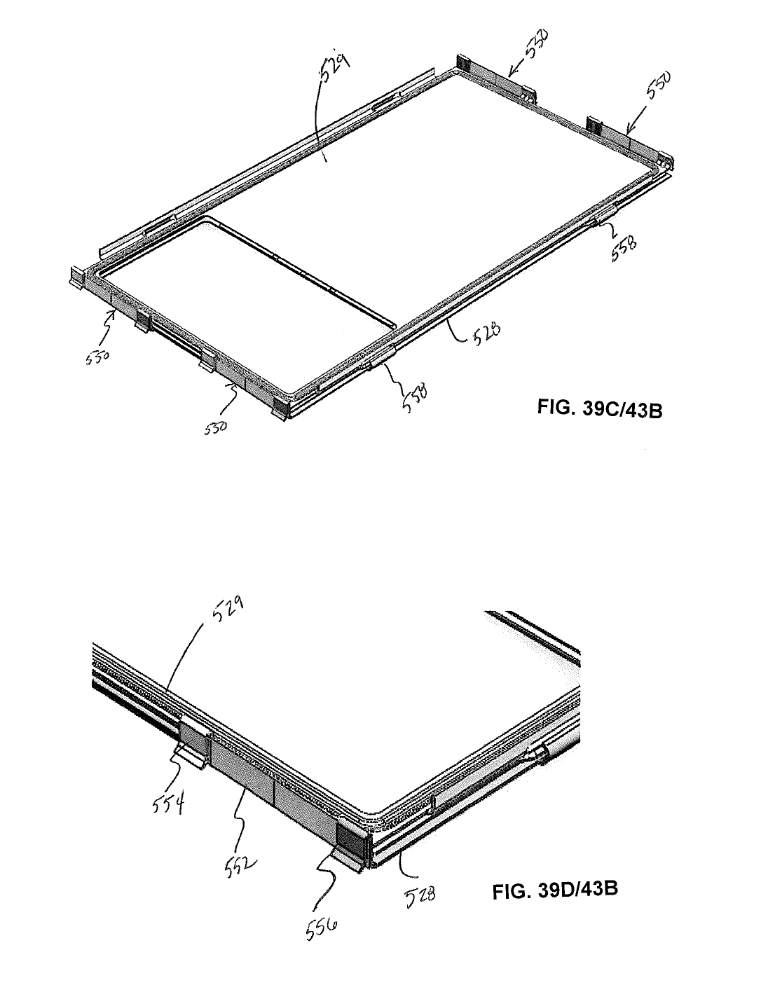

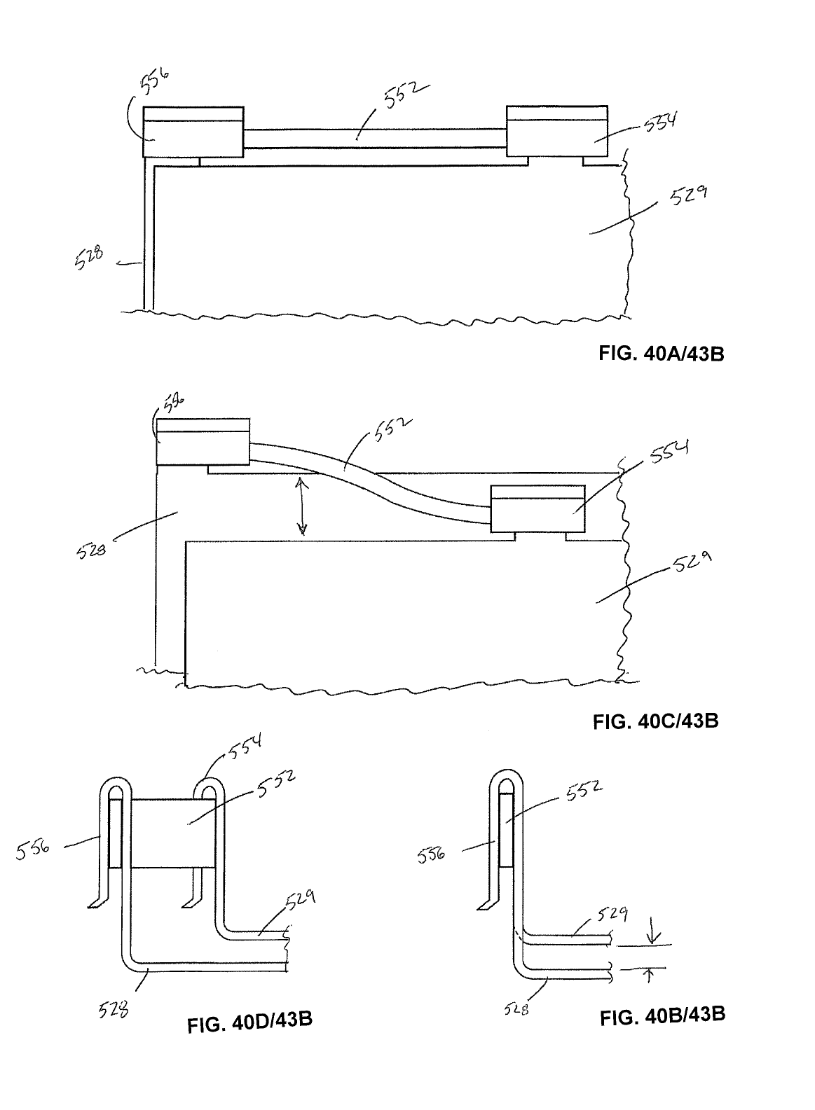

The present disclosure also includes configuring a device for improved or enhanced haptic feedback. As shown in FIG. 37A, when a user applied force 518 transfers through a rigid body of the device structure, the force increases the effect of friction between the device 520 and the ground 522 or other support surface. Although the device 520 depicted in FIGS. 37A to 37C is a computer peripheral (mouse), the principles applied herein can be incorporated in a variety of devices requiring feedback. For example, the device can include a button, a key, a gamepad, a display screen, a touch screen, a computer mouse, a keyboard, and other gaming controllers.

Turning back to FIG. 37A, the applied force 518 grounds the device 520 by pressing it against a support surface 522. This causes any haptic feedback force (as depicted by arrows 526) to work against a chassis 528 or housing 530. In other words, the haptic force 526 is dampened by the force 518 applied on a working surface 532 of the device 520. As a result, the actuator 524 only actuates any mass coupled thereto for generation of an inertial effect.

In order to provide a device 520 having an improved haptic effect, one or more surfaces 532 of the housing 530 or working surface 532 can be configured to enhance the haptic feedback force generated by the actuator 524. For example, sections 534 adjacent to the user interface surface 532 can be fabricated to transfer the haptic force as desired. For example, these sections can include softer coupling or fewer mounting points to improve the sensitivity of the response through the housing. In additional variations, the resonance of the sub-assembly can be matched or optimized with the resonance of the housing as well. In another variation, the housing geometry can be tailored to enhance a particular response, e.g. one or more sections 534 could be thinner, flexible, or configured to fold, to improve sensitivity or change its resonance.

For instance, improving the haptic feedback of the device 520 can be tailored by designing the casing to resonate differently in different locations, e.g. higher frequencies can be favored in some regions, near the fingertips 534 (as shown in FIG. 37B for example), while lower frequencies can be favored in other regions such as under the palm 536. Through the choice of the drive signal, the user feels a localized response.

In another variation, as shown in FIG. 37C, the device 534 includes one or more compliant mounts 534 that couple the housing 530 to a frame, base or chassis 528 that engages a support surface 522. The use of a compliant base mount 534 allows actuation energy of the actuator 524 to drive the housing 530 with a haptic force while the base 528 of the device 520 remains grounded. Such a compliant base mount 534 can be located anywhere on the device 520 to permit transfer of the haptic force from the actuator 524 to the relevant portion of the user interface surface 532. For example, one or more compliant mounts 538 can attach the top housing 530 to the base 528 around a perimeter of the device 520. FIG. 37C also illustrates the device 520 as optionally including one or more mechanical stops 536 to prevent failure or with packaging to reduce exposure of the inner workings of the device 520 to the environment.

In additional variations, the haptic response can be tailored through the design of the sub-assembly of the transducer. The use of fewer cartridges (or joined transducers) creates a less stiff system that can be run at lower frequencies.

Using more cartridges pushes the response to higher frequencies with a broader range of frequencies. The inertial mass can be chosen to move the resonant response to different frequency ranges. The sub-assembly can be driven at lower voltage with a stronger response if the drive frequency is close to the resonant frequency. For lower resonant frequencies, there will be a sharper cut-off in performance at higher drive frequencies.

For higher resonant frequencies, the response peak is broader and there is higher fidelity over a broader range of frequencies.

In some variations, the inertial mass can be replaced with a transformer circuit to reduce overall volume of the actuator module & drive circuit. For example, as shown in FIG. 37B, one or more batteries or capacitor storage can provide charge during times of peak load (Where such batteries or capacitors are represented by element 540. The structure 540 can comprise a weight, a power supply, a battery, a circuit board, and a capacitor of the user interface device. Using existing structures within the device 520 improves the overall form factor and space utilization of the actuator sub-assembly.

Another variation includes using an inductor as the inertial mass. In addition to the space-saving advantage, this can improve power efficiency (and lower current draw) through more efficient power conversion with the use of larger inductors than is possible with a minimally sized separate electronics circuit. This is particularly true for a resonant drive but also for the audio follower design.

In addition to, or as an alternative to the compliant gaskets described above, the systems can include any drive output mass and base mass. The drive output mass comprises the body of the device and the base mass comprises the base of the device. Driving the transducer creates vibration in both masses where one mass is used to supply feedback to the user.

To increase the haptic feedback, any member or configuration that reduces the friction between the transducer and base can be employed. For example, operating layers, including molded features like nubs or points that minimize the surface area and are made from materials have low friction coefficients for the mating surface (e.g. the underside of the display, touch screen, or backlight diffuser). The friction reducing material can comprise materials with a low coefficient of friction as well as moveable surface.

FIGS. 38A to 38E illustrate another example of a device 542 (in this example a handset unit) that employs a housing configured to enhance the haptic feedback force generated by actuators 524 located therein. FIG. 38A illustrates a user interface surface 532 of the device. FIG. 38B illustrates a side view of the user interface surface 532. In this example, the back side of the user interface surface comprises a stop surface 536 to limit excessive movement of the user interface surface 532 relative to a chassis, body or base 528 of the unit 542. FIG. 38C shows the base 528 of the unit 542 having actuators 524 as well as other components 548 of the unit. As noted above, the component 548 can optionally serve as a mass that allows the actuators to generate an inertial force. FIG. 38D illustrates the user interface surface 532 coupled to the base 528.

FIG. 38E shows another variation of a device 542 as having one or more bearings 544 located between the base 528 and the user interface surface 532. As illustrated, the bearings can optionally reside in a rail 550. Although the example device 542 illustrated includes two rails 550 along the length of the device 542, variations include one or more rails 550 located anywhere within the device so long as the rails reduce friction to allow for an enhanced haptic force generated by the actuators 524.

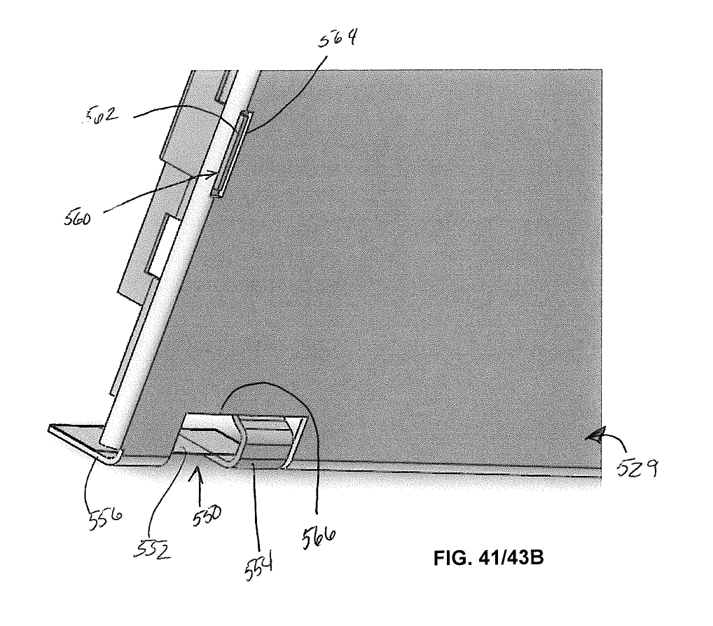

FIG. 39A illustrates a suspension assembly feature for use with the devices and assemblies described herein. The illustrated illustrates a disassembled haptic device 520 with a user interface 532 opened to expose a planar type actuator 524. The suspension assembly is omitted from FIG. 39A in order to illustrate the components of the device.

As shown, a planar type actuator 524 produces movement of the user interface 532 relative to another portion of the body of the device 520. In the illustrated example, the user interface 532 and bottom frame 528 move relative to each other. However, any number of variations are contemplated where any two components of the device move relative to one another (meaning that the user interface is not always required to be one of the moving components.) In addition, the exemplary device 520 is shown with a planar type actuator 524 that permits movement in an x-dimension and/or a y-dimension. However, any number of actuator types can be employed (e.g., actuators that move in a z/out-of-plane direction as well as actuators that move in an x-y-z direction.). The principles described herein regarding suspension assemblies can be applied to haptic feedback devices as well as other devices employing electroactive polymer transducers or other types of transducers. For example, the suspension designs can be employed in sensors, speakers and optical devices as well as in haptic devices.

FIG. 39B shows a device 520 having a number of suspension assemblies 550 that couple various components of the device 520 together. As described below, the suspension assemblies 550 can function to separate the components to allow relative movement and also to provide a spring or resistance force to counter movement of the components. For example. FIG. 39B shows the suspension assembly comprising a flexure member 552 coupled between a portion 554 of an actuation frame 529 and a portion 556 of a base frame 528. The actuation frame 529 can be any part of the device 520. In the illustrated example, the actuation frame 529 comprises a support structure for the user interface component 532. In additional variations, the actuation frame 529 can be part of the user interface component 532 or can actually comprise the user interface component itself 532.

As shown, the actuation frame 534 is coupled to the moveable part of the electroactive polymer actuator 524, in this case the electroactive polymer film 525. However, the frame can be coupled to any connector or coupling structure that is driven by the deflectable electroactive polymer film 525. The illustrated example also shows the base frame 528 being coupled to the electroactive actuator assembly 524. Typically, the frame can be attached to a housing 527 of the electroactive polymer actuator 524. Clearly, unless specifically claimed otherwise, variations of the device and methods can include actuation frames 529 that are coupled to the housing 528 of the electroactive polymer actuator as well as base frames that are coupled to the moveable part of the electroactive polymer actuator.

in FIG. 39C the user interface component as well as the electroactive polymer actuator and other components of the device are omitted for clarity in showing the actuation frame 529 coupled to a base frame 528 using a number of suspension assemblies 550. Although the illustrated example shows four assemblies, any number of assemblies can be used depending upon the particular application.

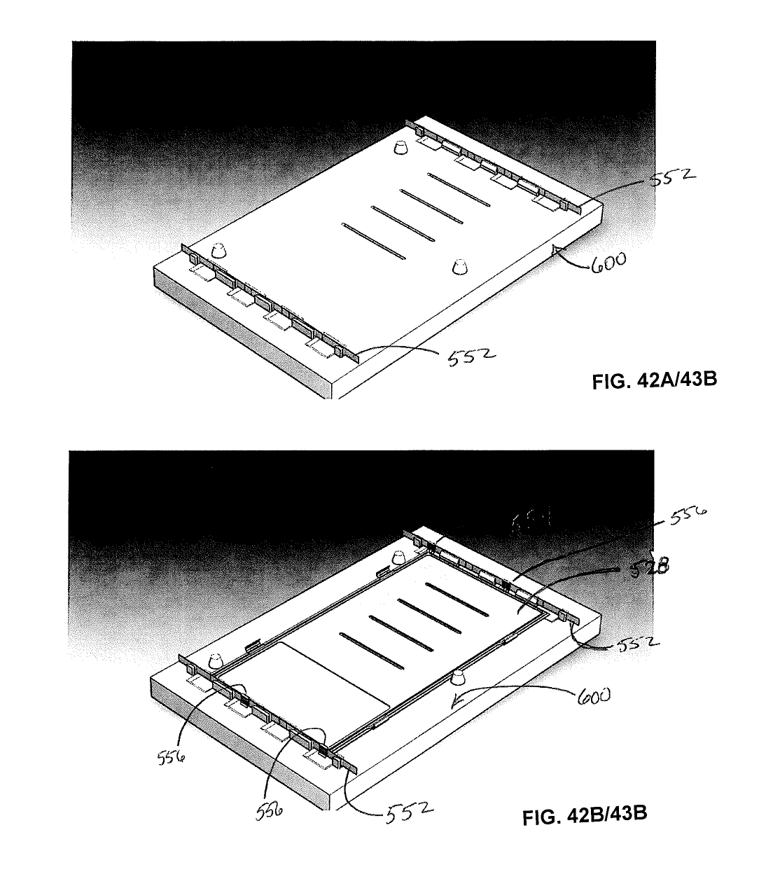

FIG. 39D provides a magnified view of one of the suspension assemblies 550. As shown, the assemblies 550 in this variation include portions or tabs 554 and 556 of the actuation frame 529 and base frame 528 respectively that are out of the plane of movement of the frames. The tabs 554 and 556 can be welded or otherwise affixed to a flexure member 552. The flexure member 552 serves as a mechanical flexure that couples the frames to permit controlled movement. The flexure member 552 can be fabricated from any material such as a metal alloy (e.g., stainless steel), a polymeric material, or a composite material. Optionally, the flexure member 552 can comprise a rectangular shape so that the member 552 bends in a single plane. However, unless specifically limited, the suspension assembly can include flexure members having a variety of shapes. For example, the illustrated flexure member 552 comprises a planar bar shape. This shape permits flexing of the member and movement of the attached components in a planar direction (see FIG. 40C).

The suspension assemblies described herein can serve dual functions of separating or suspending the moveable components and/or provide a return force or resistive force to counter the relative movement between components. FIGS. 40A to 40D illustrate a schematic top view of an example of a suspension assembly. FIG. 40A illustrates the suspension assembly in a rest position, namely prior to displacement of either an actuation frame 529 and/or a base frame 528. FIG. 40B provides a conceptual side view of the suspension assembly shown in FIG. 40A. As illustrated, the flexure member 552 maintains a vertical separation between the base frame 528 and the actuation frame 529. This spacing allows for improved movement between the frames without the need for additional bearing surfaces between frames. However, variations of the devices can include the use of one or more bearing surfaces. The actuation frame 554 and base frame 556 can also include any number of features to facilitate relative movement. For example, as shown, the frames 554 and 556 can include nesting type protrusions and slots 558 allowing for the frames 554 and 556 to move relative to one another.

FIG. 40C shows the assembly of FIG. 40A when the frames 528 and 529 are displaced relative to one another. It should be noted that the degree of displacement shown is for illustration purposes. Upon displacement the flexure member 552 enters a mechanically stressed or deformed condition as a result of the opposing forces of the tabs 554 and 556. FIG. 40D illustrates a side view of the suspension assembly of FIG. 40C. Again, the suspension assembly can maintain a separation between the frames 528 and 529 when in the displaced configuration.

In some variations, the flexure member 552 can be configured or selected to dampen or limit movement of the frames 528 and 529 to less than the maximum displacement of the electroactive polymer actuator. Such an option can extend a life of the actuator by limiting the displacement of the actuator within a desired range.

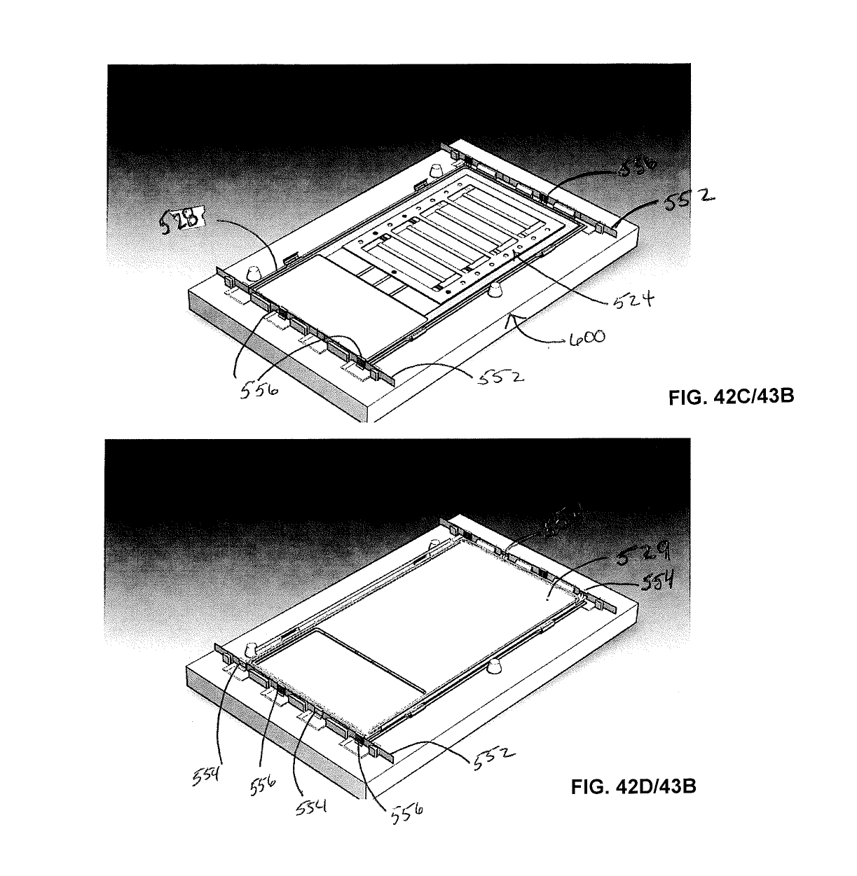

FIG. 41 shows a partial bottom view of a base frame 528 having additional aspects to control motion of variations of devices as described herein. In this variation, the base frame 528 and actuation frame 528 include a mating stop assembly 560. As shown, the stop assembly 560 includes a projection 562 and slot 564 that are nested together to allow for sliding movement between the structures. In this example, the projection 562 of the stop assembly 560 is coupled to or is part of the actuation frame while the slot 564 can be formed into the base frame 528. Variations of the system include a reversed configuration where the slot is on the actuation tray and the projection is on the base tray. In any case, the stop assembly 560 limits movement of the trays using the clearance between the projection 562 and slot 564. As a result, the movement of the trays can be configured to be less than the maximum of the actuation. This stop mechanism can prevent damage to the actuator by preventing the actuator from moving beyond its maximum range of displacement.

Additional variations of the stop assembly can include any number of alterations from that shown in FIG. 41. For example. In alternate variations, a protrusion can be nested within a slot or other keyway to prevent the need for creating a slot through the entire base frame. FIG. 41 also illustrates the bottom frame 529 including a notch 566. The notch 566 can accommodate any number of cables or can allow for movement of the tab portion 554 of the actuation frame.

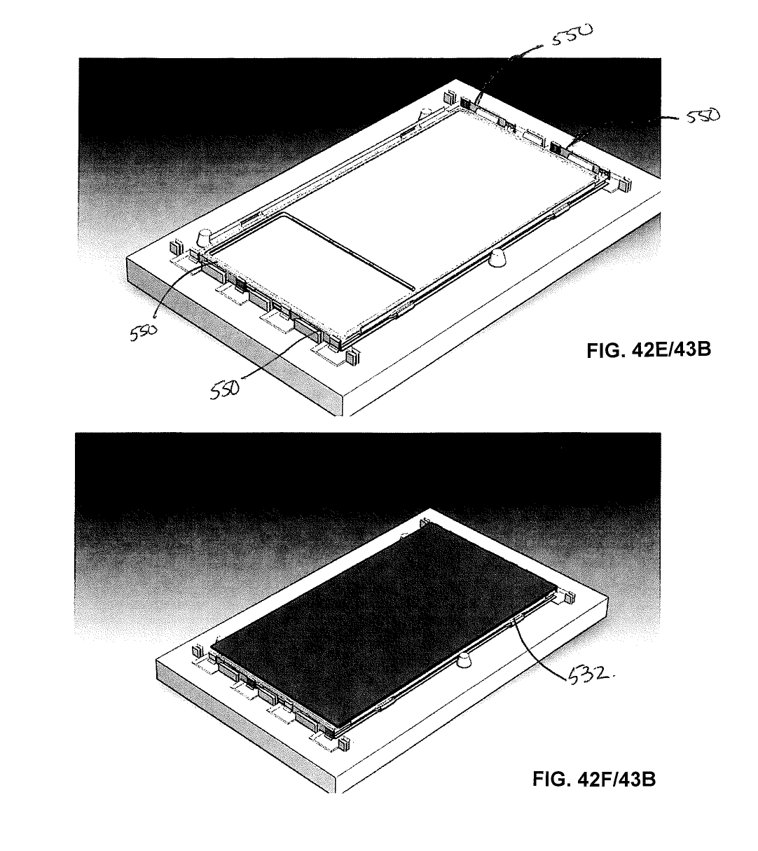

FIGS. 42A to 42F illustrate one example of assembling a suspension assembly with moving components for eventual placement into a device. FIG. 42A illustrates a strip of material used as a flexure member 552 positioned onto a fixture 600. Although the flexure member can comprise any number of shapes and sizes as well as materials, one variation of flexure member comprises a stainless steel material. Next, as shown in FIG. 42B, the process involves positioning a base frame 528 onto the fixture 600 and aligning the base frame 529 so that a portion 556 engages (or can engage) the flexure material 552. In the illustrated example, the base frame 528 includes tabs 556 that are pre-formed (or pre-bent) and are positioned over the flexure material 552. Alternatively, the tabs 556 can be bent or secured about the flexure material 552 after positioning of the base frame 528. In alternate variations, a portion 556 of the base frame 528 is simply affixed to the flexure material 552 without any bending (e.g., as shown in FIG. 41), Any number of processes can be used to affix the base frame 528 to the flexure material 552. For example, the tabs 556 can be welded to the flexure material 552. In such a case, an electrode can be positioned between the tab 556 and flexure material 552.

FIG. 42C illustrates the process after positioning of an electroactive polymer actuator 524 onto the base frame 528. For purposes of illustration, the electroactive polymer actuator 524 is shown without a power supply or other circuitry. Next, as shown in FIG. 421), an actuation frame 529 is positioned over the electroactive polymer actuator (not shown in FIG. 42D) and aligned so that a portion of the actuation frame (in this case tabs 554) engage the flexure material 552. The tabs 554 can be affixed to the flexure material in any number of ways as discussed herein.

FIG. 42E shows the state of the assembly process after the flexure material 552 is trimmed. In the example shown, trimming the flexure material 552 creates four discrete suspension assemblies 550 coupling the base and actuation frames together. FIG. 42F illustrates the step of coupling a user interface surface 532 onto the actuation frame. The assembly can then be placed in a housing or other covering. Although not shown, the assembly can include any number of bearing surfaces, such as those discussed herein, to assist in movement of the components.

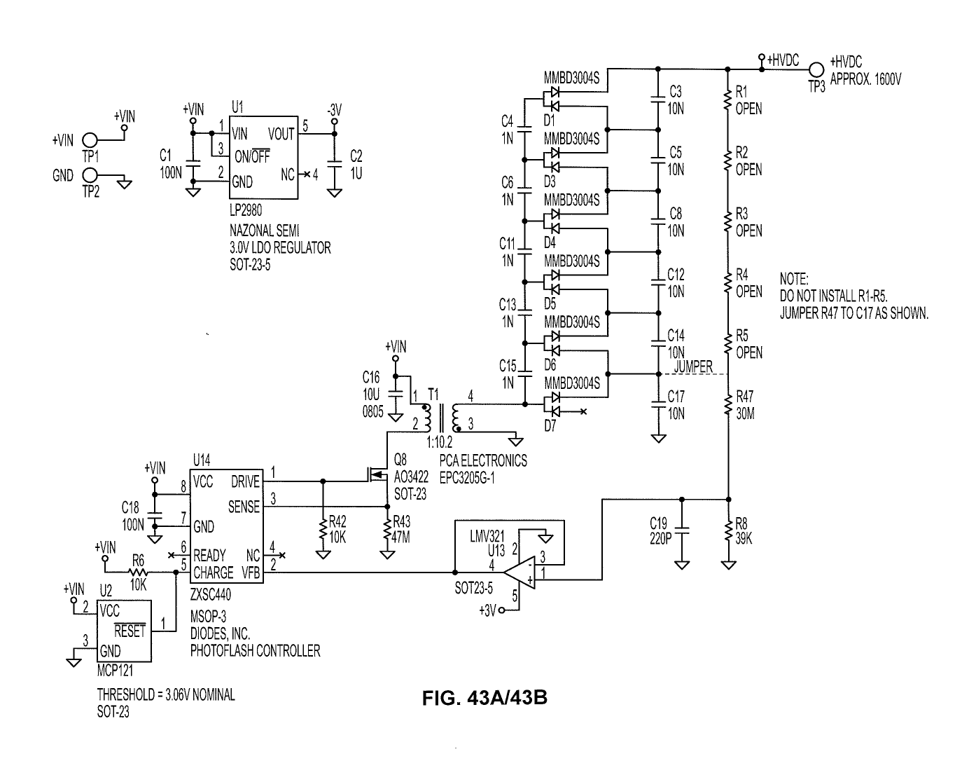

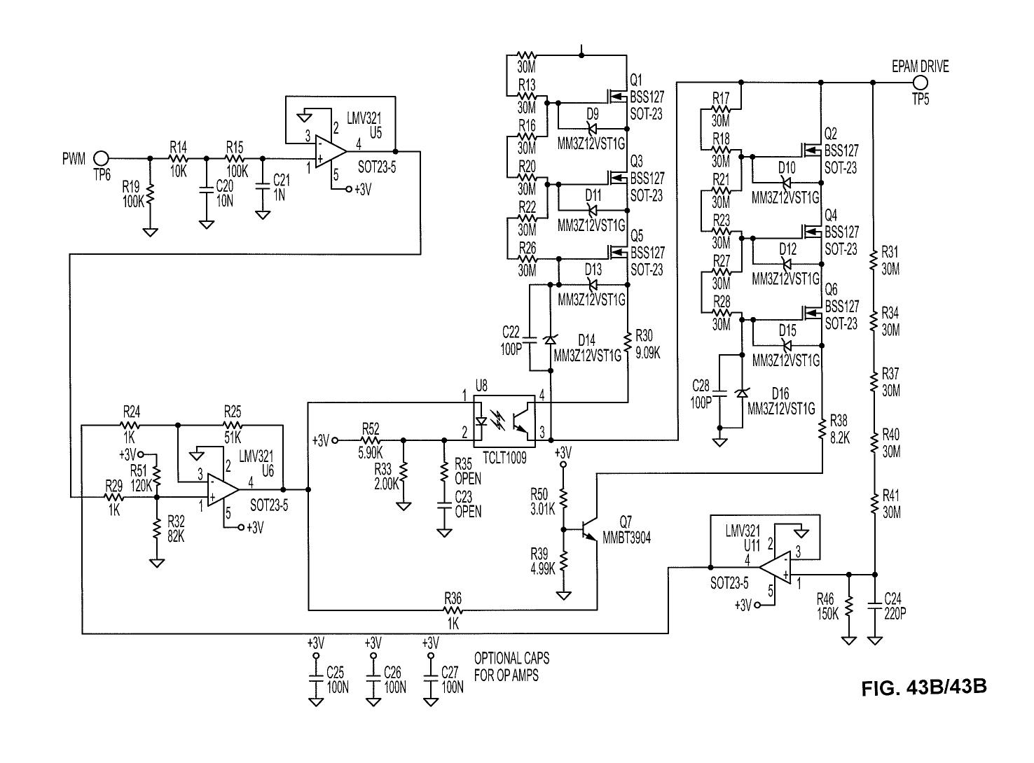

The circuit technology used to drive haptic electronics can be selected to optimize the footprint of the circuit (i.e. reduce the size of the circuit), increase the efficiency of the haptic actuator, and potentially reduce costs. The following Figures identify examples of such circuit diagrams. FIG. 43A illustrates one example comprising a power supply for a photoflash controller. FIG. 43B illustrates a second example circuit comprising a push-pull metal-oxide-semiconductor field-effect transistor (MOSFET) array with closed loop feedback.

As for other details of the present invention, materials and alternate related configurations may be employed as within the level of those with skill in the relevant art. The same may hold true with respect to method-based aspects of the invention, in terms of additional acts as commonly or logically employed. In addition, though the invention has been described in reference to several examples, optionally incorporating various features, the invention is not to be limited to that which is described or indicated as contemplated with respect to each variation of the invention. Various changes may be made to the invention described and equivalents (whether recited herein or not included for the sake of some brevity) may be substituted without departing from the true spirit and scope of the invention. Any number of the individual parts or subassemblies shown may be integrated in their design. Such changes or others may be undertaken or guided by the principles of design for assembly.

Also, it is contemplated that any optional feature of the inventive variations described may be set forth and claimed independently, or in combination with any one or more of the features described herein. Reference to a singular item, includes the possibility that there are plural of the same items present. More specifically, as used herein and in the appended claims, the singular forms “a,” “an,” “said,” and “the” include plural referents unless the specifically stated otherwise. In other words, use of the articles allow for “at least one” of the subject item in the description above as well as the claims below. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation. Without the use of such exclusive terminology, the term “comprising” in the claims shall allow for the inclusion of any additional element—irrespective of whether a given number of elements are enumerated in the claim, or the addition of a feature could be regarded as transforming the nature of an element set forth n the claims. Stated otherwise, unless specifically defined herein, all technical and scientific terms used herein are to be given as broad a commonly understood meaning as possible while maintaining claim validity.

Although the invention has been described in detail in the foregoing for the purpose of illustration, it is to be understood that such detail is solely for that purpose and that variations can be made therein by those skilled in the art without departing from the spirit and scope of the invention except as it may be limited by the claims.

What is claimed is:

1. A device for providing haptic feedback to a user, the device comprising:
a base frame;
at least one electroactive polymer actuator coupled to the base frame, the electroactive polymer actuator having an electroactive polymer film adapted to move in response to an activation signal being applied to the electroactive polymer transducer to provide the haptic feedback;
an actuation frame coupled to the electroactive polymer film, such that movement of the electroactive polymer film causes movement of the actuation frame; and
at least one mechanical flexure member coupling a portion of the base frame to a portion of the actuation frame such that the flexure member suspends the actuation frame relative to the base frame and allows relative movement between the base frame and the actuation frame.

2. The feedback device according to claim 1, wherein the mechanical flexure member comprises a plurality of separate mechanical flexure members.

3. The feedback device according to claim 1 further comprising a user interface component, the where actuation frame is coupled to or forms a part of the user interface component.

4. The user interface device according to claim 3, wherein the user interface component comprises an interface device selected from the group consisting of a button, a key, a gamepad, a display screen, a touch screen, a computer mouse, a keyboard, and a gaming controller.

5. The feedback device according to claim 1, wherein the mechanical member comprises a planar bar.

6. The feedback device according to claim 1, wherein the mechanical flexure member is configured to limit relative movement between the base frame and the actuation frame in a plane parallel to the base frame.

7. The feedback device according to claim 1, wherein a first portion of the mechanical flexure member is rigidly affixed to the base frame and a second portion of the mechanical flexure member is rigidly affixed to the actuation frame, and such that an unconstrained third portion of the mechanical flexure member being located between the first and second portions deflects in response to relative movement between the base frame and the actuation frame.

8. The feedback device according to claim 7, wherein the unconstrained third portion of the mechanical flexure member limits movement of the electroactive polymer film to less than a maximum displacement of the electroactive polymer film.

9. The feedback device according to claim 1, wherein the actuation frame includes at least one actuation tab and the base frame includes at least one base tab, where the actuation tab and base tab are non-planar with the actuation frame and base frame and where at least one mechanical flexure member is secured between the actuation tab and the base tab.

10. The feedback device according to claim 1 further comprising a stop assembly, the stop assembly comprising a projection on the base frame and a slot in the actuation frame, where the slot is configured to receive the projection and where the slot is sized larger than the projection to limit movement of the base frame.

11. The feedback device according to claim 1 further comprising a stop assembly, the stop assembly comprising a projection on the actuation frame and a slot in the base frame, where the slot is configured to receive the projection and where the slot is sized larger than the projection to limit movement of the base frame.

12. The user interface device of claim 1, where the activation signal produces a haptic feedback force from the electroactive polymer that is associated with the output signal.

13. The user interface device according to claim 1, wherein the at least one electroactive polymer actuator comprises an inertial mass to produces the haptic feedback force.

14. The user interface device according to claim 1, wherein the at least one electroactive polymer actuator is coupled to a structure of the user interface device such that upon displacement the electroactive polymer actuator moves the structure to generate an inertial force.

15. The user interface device according to claim 13, wherein the structure comprises a structure selected from a weight, a power supply, a battery, a circuit board and a capacitor of the user interface device.

16. The user interface device according to claim 1 further comprising at least one bearing between the actuation frame and the base frame where the bearing reduces friction therebetween.

17. The user interface device according to claim 15, wherein the at least one bearing comprises a plurality of bearings mounted in a guide rail.

18. The user interface device according to claim 15, wherein at least two guide rails are positioned respectively along a first and second side of a user interface component.

19. A method of manufacturing a feedback device, the method comprising:
affixing an electroactive polymer transducer to a first frame, where the electroactive polymer transducer includes an electroactive polymer film configured to displace upon the application of a voltage to provide the feedback;
coupling the electroactive polymer film to a second frame; and
suspending the first frame relative to the second frame by affixing the first frame to a first portion of a mechanical flexure member and affixing the second frame to a second portion of the mechanical flexure member, where a third portion of the mechanical flexure member is unconstrained and deflects to allow relative movement of the first and second portions.

20. The method according to claim 19, wherein suspending the first frame relative to the second frame comprises affixing the first and second frames to a plurality of discrete mechanical flexure members.

21. The method of claim 20, where the first or second frame comprises a user interface component.

22. The method according to claim 21, wherein the user interface component comprises an interface device selected from the group consisting of a button, a key, a gamepad, a display screen, a touch screen, a computer mouse, a keyboard, and a gaming controller.

23. The method according to claim 19, wherein suspending the first frame relative to the second frame comprises affixing a first portion of a planar bar to the first frame and affixing a second portion of a planar bar to the second frame, where the planar bar facilitates parallel movement of the first and second frames.

24. The method according to claim 19, wherein the third portion of the mechanical flexure member is selected to deflect by an amount that prevents the electroactive polymer film from reaching a maximum displacement.

25. The method according to claim 19 further comprising creating a first stop surface in the first frame and creating a second stop surface on the second frame such that the first and second stop surfaces interfere to limit movement of the first frame relative to the second frame to prevent the electroactive polymer film from reaching a maximum displacement.

26. A method for controlling displacement between moveable components in a device, the method comprising:
providing a device having:
a first frame component suspended relative to a second frame component by a mechanical flexure which allows for relative movement between the first and second frame components, the first frame component and second frame component having a rest position and a displaced position;
an electroactive polymer transducer having an electroactive polymer film configured to displace upon application of a voltage, where the electroactive polymer transducer is coupled to the first frame component and where the electroactive polymer film is coupled to the second frame component;
activating the electroactive transducer to cause displacement of the electroactive polymer film, where displacement of the electroactive polymer film results movement of the first and second frame components to the displaced position creating a mechanical stress in the mechanical flexure;
reducing the signal to the electroactive transducer to allow the stress in the mechanical flexure to assist returning the first frame component and second frame component towards the rest position while maintaining a suspension between the first and second frames.

27. The method according to claim 26, wherein suspending the first frame relative component to the second frame component comprises affixing the first and second frames to a plurality of discrete mechanical flexures.

28. The method according to claim 26, wherein the first or second frame components comprise or are part of a user interface component.

29. The method according to claim 28, wherein the user interface component comprises an interface device selected from the group consisting of a button, a key, a gamepad, a display screen, a touch screen, a computer mouse, a keyboard, and a gaming controller.
